(19) United States
(12) Patent Application Publication
(10) Pub. No.: US 2025/0006580 A1
(43) Pub. Date: Jan. 2, 2025

(54) SEMICONDUCTOR DEVICE

(71) Applicant: ROHM CO., LTD., Kyoto-shi (JP)

(72) Inventor: Yuki NAKANO, Kyoto-shi (JP)

(73) Assignee: ROHM CO., LTD., Kyoto-shi (JP)

(21) Appl. No.: 18/884,144

(22) Filed: Sep. 13, 2024

Related U.S. Application Data
(63) Continuation of application No. PCT/JP2022/043800, filed on Nov. 28, 2022.

(30) Foreign Application Priority Data
Mar. 14, 2022 (JP) 2022-039205

(51) Int. Cl. H01L 23/31; H01L 23/29

(52) U.S. Cl. CPC H01L 23/3192; H01L 23/293

(57) ABSTRACT

A semiconductor device including a chip having a main surface, a first inorganic film including an insulator and covering the main surface, a second inorganic film including an insulator and covering the first inorganic film, at least one through hole formed in the second inorganic film, and an organic film embedded in the through hole and covering the second inorganic film.

### CROSS-REFERENCE TO RELATED APPLICATIONS

The present application is a bypass continuation of International Patent Application No. PCT/JP2022/043800, filed on Nov. 28, 2022, which claims priority to Japanese Patent Application No. 2022-039205, filed on Mar. 14, 2022, the entire disclosures of these applications are incorporated herein by reference.

### BACKGROUND

### 1. Field of the Disclosure

The present disclosure relates to a semiconductor device.

### 2. Description of the Related Art

US2019/0080976A1 discloses a semiconductor device including a semiconductor substrate, an interlayer insulating layer, an inorganic protective layer, and an organic protective layer. The interlayer insulating layer covers the semiconductor substrate. The inorganic protective layer covers the interlayer insulating layer. The organic protective layer covers the inorganic protective layer.

### BRIEF DESCRIPTION OF THE DRAWINGS

FIG. 1 is a plan view of a semiconductor device according to a first embodiment.

FIG. 2 is a cross-sectional view taken along II-II line illustrated in FIG. 1.

FIG. 3 is an enlarged plan view illustrating an inner portion of a chip.

FIG. 4 is a cross-sectional view taken along IV-IV line illustrated in FIG. 3.

FIG. 5 is a plan view illustrating a layout example of a gate electrode and a source electrode.

FIG. 6 is a plan view illustrating a layout example of a second inorganic film.

FIG. 7 is an enlarged cross-sectional view illustrating a peripheral edge portion of the chip.

FIG. 8A is a schematic diagram illustrating a first layout example of a through hole.

FIG. 8B is a schematic diagram illustrating a second layout example of the through hole.

FIG. 8C is a schematic diagram illustrating a third layout example of the through hole.

FIG. 8D is a schematic diagram illustrating a fourth layout example of the through hole.

FIG. 8E is a schematic diagram illustrating a fifth layout example of the through hole.

FIG. 8F is a schematic diagram illustrating a sixth layout example of the through hole.

FIG. 8G is a schematic diagram illustrating a seventh layout example of the through hole.

FIG. 8H is a schematic diagram illustrating an eighth layout example of the through hole.

FIG. 8I is a schematic diagram illustrating a ninth layout example of the through hole.

FIG. 8J is a schematic diagram illustrating a tenth layout example of the through hole.

FIG. 8K is a schematic diagram illustrating an eleventh layout example of the through hole.

FIG. 8L is a schematic diagram illustrating a twelfth example layout of the through hole.

FIG. 8M is a schematic diagram illustrating a thirteenth layout example of the through hole.

FIG. 8N is a schematic diagram illustrating a fourteenth layout example of the through hole.

FIG. 8O is a schematic diagram illustrating a fifteenth layout example of the through hole.

FIG. 8P is a schematic diagram illustrating a sixteenth layout example of the through hole.

FIG. 8Q is a schematic diagram illustrating a seventeenth layout example of the through hole.

FIG. 8R is a schematic diagram illustrating an eighteenth layout example of the through hole.

FIG. 8S is a schematic diagram illustrating a nineteenth layout example of the through hole.

FIG. 8T is a schematic diagram illustrating a twentieth layout example of the through hole.

FIG. 9 is a diagram illustrating a semiconductor device according to a second embodiment.

FIG. 10 is a diagram illustrating a semiconductor device according to a third embodiment.

FIG. 11 is a diagram illustrating a semiconductor device according to a fourth embodiment.

FIG. 12 is a diagram illustrating a semiconductor device according to a fifth embodiment.

FIG. 13 is a diagram illustrating a semiconductor device according to a sixth embodiment.

FIG. 14 is a diagram illustrating a semiconductor device according to a seventh embodiment.

FIG. 15 is a diagram illustrating a semiconductor device according to an eighth embodiment.

FIG. 16 is a plan view illustrating a layout example of the second inorganic film illustrated in FIG. 15.

FIG. 17 is an enlarged cross-sectional view illustrating a peripheral edge portion of a chip illustrated in FIG. 15.

FIG. 18 is a plan view illustrating semiconductor device according to a ninth embodiment.

FIG. 19 is a cross-sectional view taken along XIX-XIX line illustrated in FIG. 18.

FIG. 20 is a plan view illustrating a layout example of a first polarity electrode.

FIG. 21 is a plan view illustrating a layout example of the second inorganic film.

FIG. 22 is an enlarged cross-sectional view illustrating a peripheral edge portion of a chip.

FIG. 23 is a diagram illustrating a semiconductor device according to a tenth embodiment.

FIG. 24 is a diagram illustrating a semiconductor device according to an eleventh embodiment.

FIG. 25 is a diagram illustrating a semiconductor device according to a twelfth embodiment.

FIG. 26 is a diagram illustrating a semiconductor device according to a thirteenth embodiment.

FIG. 27 is a diagram illustrating a semiconductor device according to a fourteenth embodiment.

FIG. 28 is a diagram illustrating a semiconductor device according to a fifteenth embodiment.

FIG. 29 is a diagram illustrating a semiconductor device according to a sixteenth embodiment.

FIG. 30 is a plan view illustrating a layout example of the second inorganic film illustrated in FIG. 29.

FIG. 31 is an enlarged cross-sectional view illustrating a peripheral edge portion of a chip illustrated in FIG. 29.

FIG. 32 is a cross-sectional view illustrating a modified example of the chip.

FIG. 33 is a cross-sectional view illustrating a modified example of the chip.

### DETAILED DESCRIPTION OF THE PREFERRED EMBODIMENTS

Hereinafter, embodiments will be described in detail with reference to the accompanying drawings. The accompanying drawings are schematic views and are not strictly illustrated, and scales and the like thereof do not always match. Also, identical reference symbols are given to corresponding structures among the accompanying drawings, and duplicate descriptions thereof shall be omitted or simplified. For the structures whose description has been omitted or simplified, the description given before the omission or simplification shall be applied.

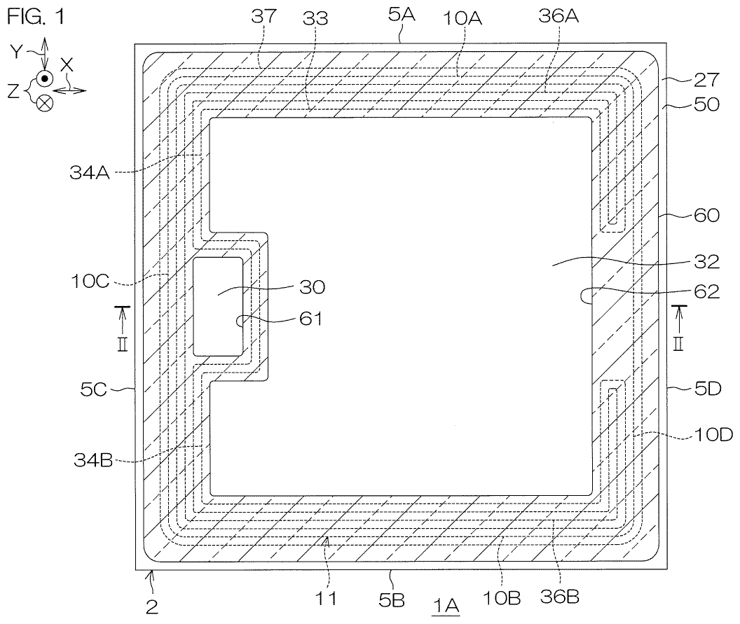

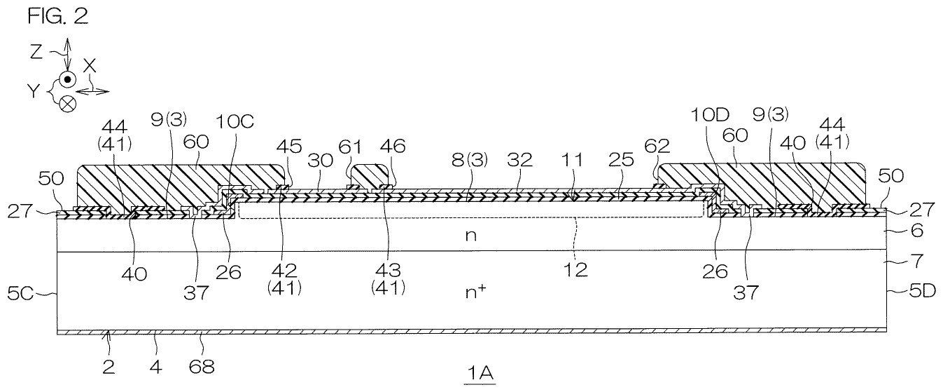

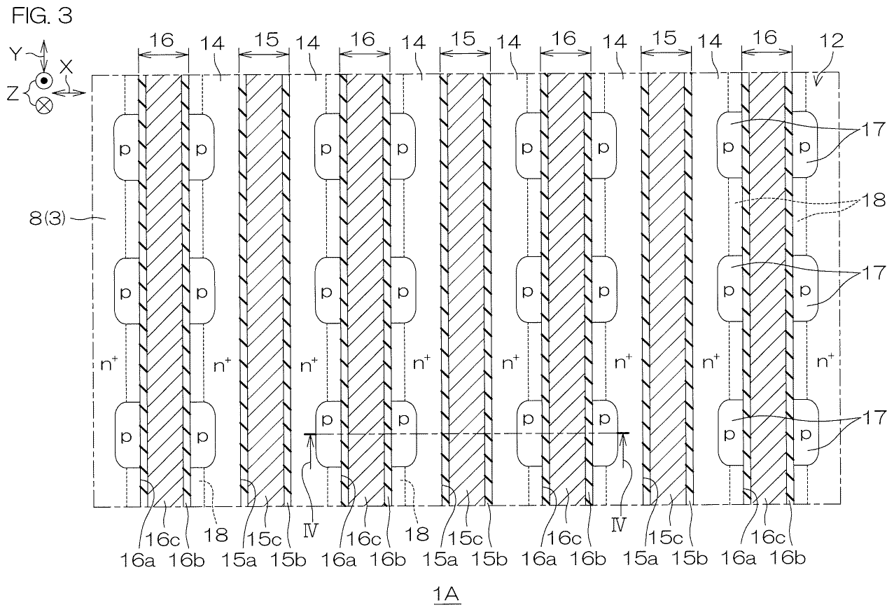

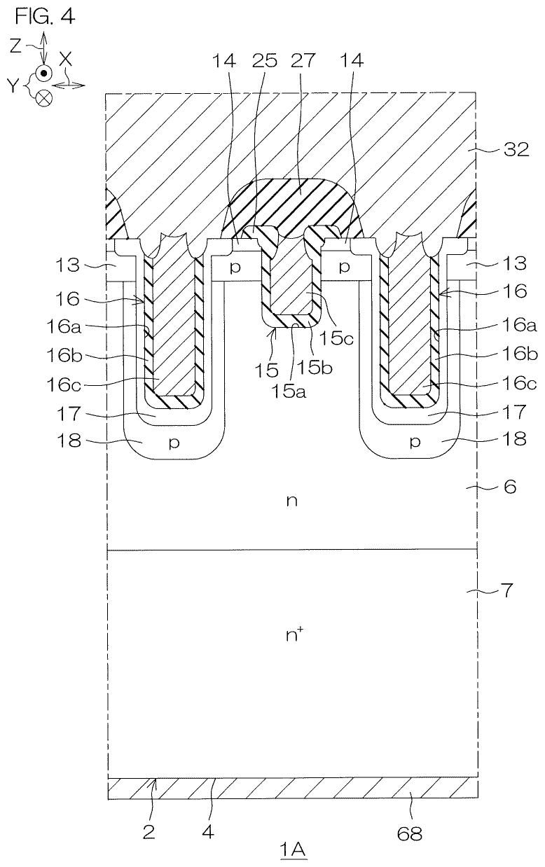

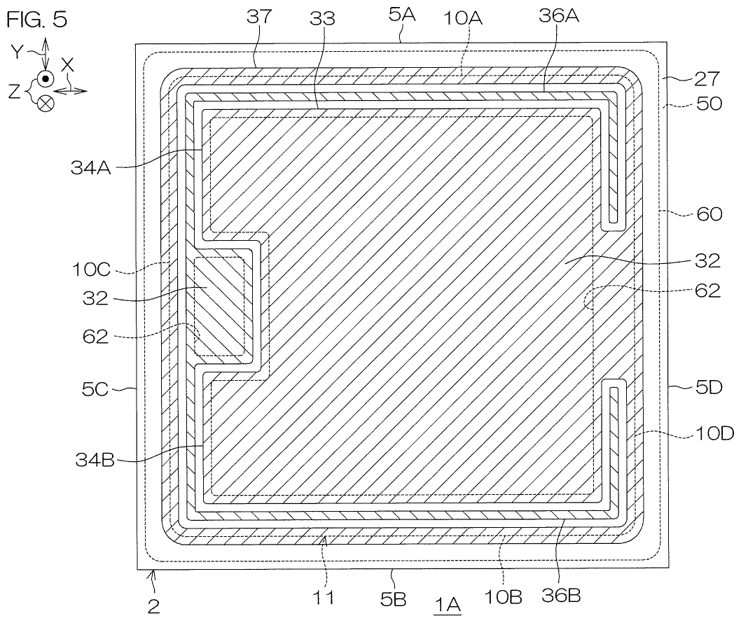

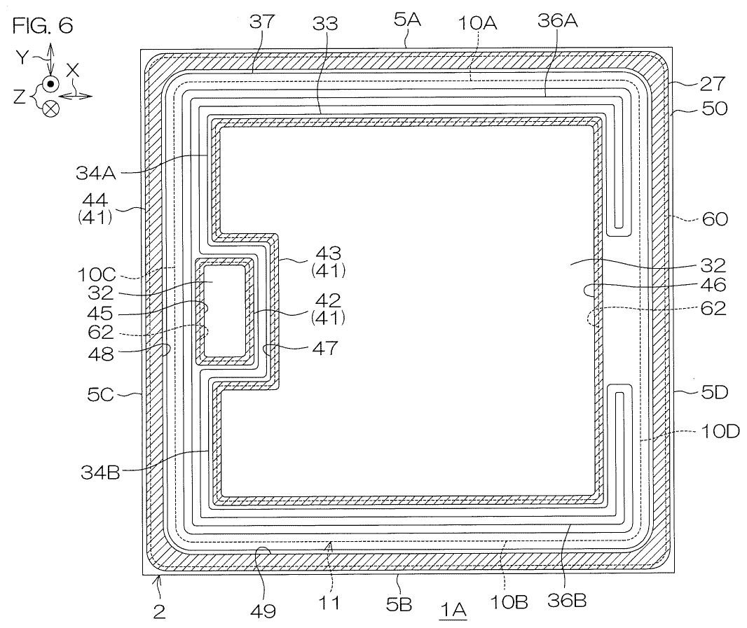

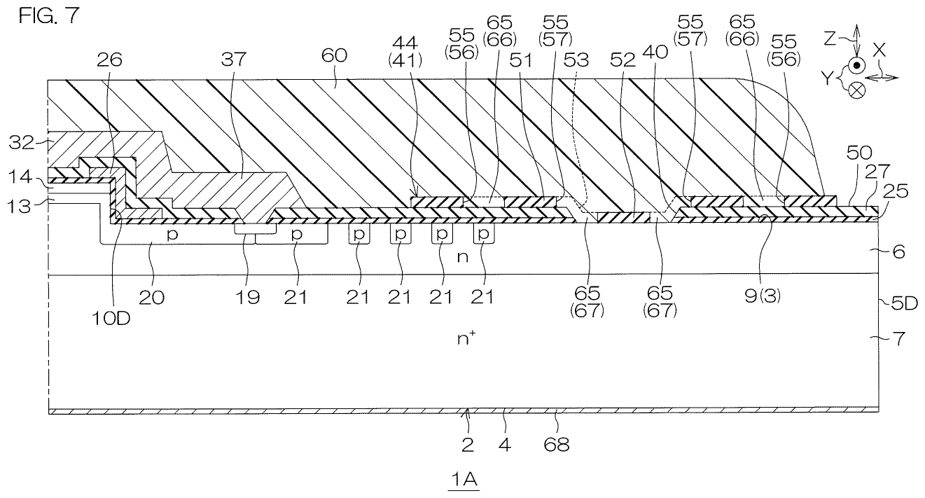

FIG. 1 is a plan view of a semiconductor device 1A according to a first embodiment. FIG. 2 is a cross-sectional view taken along II-II line illustrated in FIG. 1. FIG. 3 is an enlarged plan view illustrating an inner portion of a chip 2. FIG. 4 is a cross-sectional view taken along IV-IV line illustrated in FIG. 3. FIG. 5 is a plan view illustrating a layout example of a gate electrode 30 and a source electrode 32. FIG. 6 is a plan view illustrating a layout example of a second inorganic film 41. FIG. 7 is an enlarged cross-sectional view illustrating a peripheral edge portion of the chip 2.

With reference to FIG. 1 to FIG. 7, the semiconductor device 1A in this embodiment includes the chip 2 including a single crystal of a wide bandgap semiconductor and being formed in a hexahedral shape (specifically, a rectangular parallelepiped shape). That is, the semiconductor device 1A is a “wide bandgap semiconductor device.”

The chip 2 may be referred to as a “semiconductor chip” or a “wide bandgap semiconductor chip.” The wide bandgap semiconductor is a semiconductor having a bandgap exceeding a bandgap of an Si (Silicon). Examples of the wide bandgap semiconductors include GaN (gallium nitride), SiC (silicon carbide) and C (diamond).

In this embodiment, the chip 2 is an “SiC chip” including a hexagonal SiC single crystal as an example of the wide bandgap semiconductor. That is, the semiconductor device 1A is an “SiC semiconductor device.” The hexagonal SiC single crystal has a plurality of polytypes including a 2H (Hexagonal)-SiC single crystal, a 4H-SiC single crystal, and a 6H-SiC single crystal. In this embodiment, an example is provided in which the chip 2 includes a 4H-SiC single crystal, but the chip 2 may be other polytypes.

The chip 2 has a first main surface 3 on one side, a second main surface 4 on the other side, and first to fourth side surfaces 5A to 5D connecting the first main surface 3 and the second main surface 4. The first main surface 3 and the second main surface 4 are formed in a quadrangular shape when viewed in a plan view from the normal direction Z (hereinafter simply referred to as “plan view”). The normal direction Z is also a thickness direction of the chip 2. The first main surface 3 and the second main surface 4 are preferably formed by a c-plane of an SiC single crystal.

In this case, it is preferable that the first main surface 3 is formed by a silicon surface of the SiC single crystal, and the second main surface 4 is formed by a carbon surface of the SiC single crystal. The first main surface 3 and the second main surface 4 may have an off angle inclined at a predetermined angle in a predetermined off direction with respect to the c-plane. The off direction is preferably an a-axis direction ([11-20] direction) of the SiC single crystal. The off angle may be greater than 0° and equal to or less than 10°. The off angle is preferably 5° or less. The second main surface 4 may include a ground surface having grinding marks, or may include a smooth surface having no grinding marks.

The first side surface 5A and the second side surface 5B extend in a first direction X along the first main surface 3 and face a second direction Y that intersects with the first direction X (specifically, perpendicular to the first direction X). The third side surface 5C and the fourth side surface 5D extend in the second direction Y and face each other in the first direction X.

The first direction X may be an m-axis direction ([1-100] direction) of the SiC single crystal, and the second direction Y may be an a-axis direction of the SiC single crystal. As a matter of course, the first direction X may be the a-axis direction of the SiC single crystal, and the second direction Y may be the m-axis direction of the SiC single crystal. The first to fourth side surfaces 5A to 5D may include ground surfaces having grinding marks, or may include smooth surfaces having no grinding marks.

The chip 2 may have a thickness of 5 μm or more and 200 μm or less in the normal direction Z. The thickness of the chip 2 may be 150 μm or less, 100 μm or less, 80 μm or less, 50 μm or less, or 40 μm or less. The first to fourth side surfaces 5A to 5D may each have a length of 0.5 mm or more and 10 mm or less in a plan view. The lengths of the first to fourth side surfaces 5A to 5D are preferably 1 mm or more.

It is particularly preferable that the lengths of the first to fourth side surfaces 5A to 5D are 2 mm or more. That is, the chip 2 preferably has a planar area of 1 mm square or more (preferably 2 mm square or more) and a thickness of 100 μm or less (preferably 50 μm or less) in a cross-sectional view. In this embodiment, the lengths of the first to fourth side surfaces 5A to 5D are set in the range of 4 mm or more and 6 mm or less.

The semiconductor device 1A includes an n-type (first conductivity type) first semiconductor region 6 formed in a region (surface layer portion) on the first main surface 3 side in the chip 2. The first semiconductor region 6 is formed in a layer shape extending along the first main surface 3, and is exposed from the first main surface 3 and the first to fourth side surfaces 5A to 5D. In this embodiment, the first semiconductor region 6 includes an epitaxial layer (specifically, an SiC epitaxial layer).

The first semiconductor region 6 may have a thickness of 1 μm or more and 50 μm or less in the normal direction Z. The thickness of the first semiconductor region 6 is preferably 3 μm or more and 30 μm or less. It is particularly preferable that the thickness of the first semiconductor region 6 be 5 μm or more and 25 μm or less.

The semiconductor device 1A includes an n-type second semiconductor region 7 formed in a region (surface layer portion) on the second main surface 4 side in the chip 2. The second semiconductor region 7 is formed in a layer shape extending along the second main surface 4, and is exposed from the second main surface 4 and the first to fourth side surfaces 5A to 5D. The second semiconductor region 7 has a higher n-type impurity concentration than that of the first semiconductor region 6 and is electrically connected to the first semiconductor region 6.

In this embodiment, the second semiconductor region 7 includes a semiconductor substrate (specifically, an SiC semiconductor substrate). That is, the chip 2 has a layered structure including a semiconductor substrate and an epitaxial layer. The second semiconductor region 7 may have a thickness of 1 μm or more and 200 μm or less in the normal direction Z. The thickness of the second semiconductor region 7 may be 150 μm or less, 100 μm or less, 50 μm or less, or 40 μm or less.

The second semiconductor region 7 may have a thickness of 5 μm or more. The thickness of the second semiconductor region 7 is preferably 10 μm or more. By using the second semiconductor region 7 having a relatively small thickness, a resistance value (for example, on-resistance) caused by the second semiconductor region 7 can be reduced. The second semiconductor region 7 has a thickness that exceeds the thickness of the first semiconductor region 6 in this embodiment.

The semiconductor device 1A includes an active surface 8 formed in the first main surface 3, an outer surface 9, and first to fourth connecting surfaces 10A to 10D. The active surface 8, the outer surface 9, and the first to fourth connecting surfaces 10A to 10D define a mesa portion 11 (plateau) on the first main surface 3. The active surface 8 may be referred to as a “first surface portion,” the outer surface 9 may be referred to as a “second surface portion,” and the first to fourth connecting surfaces 10A to 10D may be referred to as “connecting surface portions.” The active surface 8, the outer surface 9, and the first to fourth connecting surfaces 10A to 10D (that is, the mesa portion 11) may be considered as constituent components of the chip 2 (first main surface 3).

The active surface 8 is formed at an interval inward from the peripheral edge of the first main surface 3 (the first to fourth side surfaces 5A to 5D). The active surface 8 has a flat surface extending in the first direction X and the second direction Y. In this embodiment, the active surface 8 is formed in a quadrangular shape having four sides parallel to the first to fourth side surfaces 5A to 5D in a plan view.

The outer surface 9 is located outside the active surface 8 and is recessed from the active surface 8 in the thickness direction of the chip 2 (toward the second main surface 4). Specifically, the outer surface 9 is recessed to a depth less than the thickness of the first semiconductor region 6 so as to expose the first semiconductor region 6. The outer surface 9 extends in a strip shape along the active surface 8 in a plan view, and is formed in a ring shape (specifically, a quadrangular ring shape) surrounding the active surface 8. The outer surface 9 has a flat surface extending in the first direction X and the second direction Y, and is formed substantially parallel to the active surface 8. The outer surface 9 is continuous with the first to fourth side surfaces 5A to 5D.

The first to fourth connecting surfaces 10A to 10D extend in the normal direction Z and connect the active surface 8 and the outer surface 9. The first connecting surface 10A is located on the first side surface 5A side, the second connecting surface 10B is located on the second side surface 5B side, the third connecting surface 10C is located on the third side surface 5C side, and the fourth connecting surface 10D is located on the fourth side surface 5D side. The first connecting surface 10A and the second connecting surface 10B extend in the first direction X and face each other in the second direction Y. The third connecting surface 10C and the fourth connecting surface 10D extend in the second direction Y and face each other in the first direction X.

The first to fourth connecting surfaces 10A to 10D may extend substantially perpendicularly between the active surface 8 and the outer surface 9 so as to define the mesa portion 11 having a quadrangle columnar shape. The first to fourth connecting surfaces 10A to 10D may be inclined obliquely downward from the active surface 8 toward the outer surface 9 so as to define the mesa portion 11 having a truncated quadrangular pyramid shape. Thus, the semiconductor device 1A includes the mesa portion 11 formed in the first semiconductor region 6 on the first main surface 3. The mesa portion 11 is formed only in the first semiconductor region 6 and is not formed in the second semiconductor region 7.

The semiconductor device 1A includes, as an example of a device structure, a MISFET (Metal Insulator Semiconductor Field Effect Transistor) structure 12 formed in the active surface 8 (first main surface 3). In FIG. 2, the MISFET structure 12 is illustrated in simplified form by dashed lines. A specific structure of the MISFET structure 12 will be described below with reference to FIG. 3 and FIG. 4.

The MISFET structure 12 includes a p-type (second conductivity type) body region 13 formed in a surface layer portion of the active surface 8. The body region 13 is formed at an interval from the bottom portion of the first semiconductor region 6 toward the active surface 8. The body region 13 is formed in a layer shape extending along the active surface 8. The body region 13 may be exposed from a portion of the first to fourth connecting surfaces 10A to 10D.

The MISFET structure 12 includes an n-type source region 14 formed in a surface layer portion of the body region 13. The source region 14 has a higher n-type impurity concentration than that of the first semiconductor region 6. The source region 14 is formed at an interval from the bottom portion of the body region 13 toward the active surface 8. The source region 14 is formed in a layer shape extending along the active surface 8. The source region 14 may be exposed from the entire active surface 8. The source region 14 may be exposed from a portion of the first to fourth connecting surfaces 10A to 10D. The source region 14 forms a channel in the body region 13 between the first semiconductor region 6 and the source region 14.

The MISFET structure 12 includes a plurality of gate structures 15 formed in the active surface 8. The plurality of gate structures 15 are arranged at intervals in the first direction X in a plan view, and are each formed in a strip shape extending in the second direction Y. The plurality of gate structures 15 penetrate the body region 13 and the source region 14 to the first semiconductor region 6. The plurality of gate structures 15 control the inversion and the non-inversion of the channel in the body region 13.

In this embodiment, each gate structure 15 includes a gate trench 15a, a gate insulating film 15b, and a gate embedded electrode 15c. The gate trench 15a is formed in the active surface 8 and defines a wall surface of the gate structure 15. The gate insulating film 15b covers a wall surface of the gate trench 15a. The gate embedded electrode 15c is embedded in the gate trench 15a with the gate insulating film 15b therebetween, and faces the channel with the gate insulating film 15b therebetween.

The MISFET structure 12 includes a plurality of source structures 16 formed in the active surface 8. The plurality of source structures 16 are each arranged in a region between a pair of adjacent gate structures 15 on the active surface 8. The plurality of source structures 16 are each formed in a strip shape extending in the second direction Y in a plan view. The plurality of source structures 16 penetrate the body region 13 and the source region 14 to the first semiconductor region 6. The plurality of source structures 16 have a depth that exceeds the depth of the gate structure 15. Specifically, the plurality of source structures 16 have a depth approximately equal to the depth of the outer surface 9.

Each source structure 16 includes a source trench 16a, a source insulating film 16b, and a source embedded electrode 16c. The source trench 16a is formed in the active surface 8 and defines a wall surface of the source structure 16. The source insulating film 16b covers a wall surface of the source trench 16a. The source embedded electrode 16c is embedded in the source trench 16a with the source insulating film 16b interposed therebetween.

The MISFET structure 12 includes a plurality of p-type contact regions 17 each formed in a region along the plurality of source structures 16 inside the chip 2. The plurality of contact regions 17 have a higher p-type impurity concentration than that of the body region 13. Each contact region 17 covers a sidewall and a bottom wall of each source structure 16 and is electrically connected to the body region 13.

The MISFET structure 12 includes a plurality of p-type well regions 18 formed in a region along the plurality of source structures 16 inside the chip 2. Each well region 18 may have a p-type impurity concentration higher than that of the body region 13 and lower than that of the contact region 17. Each well region 18 covers the corresponding source structure 16 with the corresponding contact region 17 therebetween. Each well region 18 covers a sidewall and a bottom wall of the corresponding source structure 16 and is electrically connected to the body region 13 and the contact region 17.

With reference to FIG. 7, the semiconductor device 1A includes a p-type outer contact region 19 formed in a surface layer portion of the outer surface 9. The outer contact region 19 has a p-type impurity concentration that exceeds the p-type impurity concentration of the body region 13. The outer contact region 19 is formed at an interval from the peripheral edge of the active surface 8 and the peripheral edge of the outer surface 9 in a plan view, and is formed in a strip shape extending along the active surface 8.

In this embodiment, the outer contact region 19 is formed in a ring shape (specifically, a quadrangular ring shape) surrounding the active surface 8 in a plan view. The outer contact region 19 is formed at an interval from the bottom portion of the first semiconductor region 6 to the outer surface 9. The outer contact region 19 is located on the bottom portion side of the first semiconductor region 6 with respect to the bottom walls of the plurality of gate structures 15 (source structures 16).

The semiconductor device 1A includes a p-type outer well region 20 formed in the surface layer portion of the outer surface 9. The outer well region 20 has a p-type impurity concentration lower than the p-type impurity concentration of the outer contact region 19. It is preferable that the p-type impurity concentration of the outer well region 20 be approximately equal to the p-type impurity concentration of the well region 18. The outer well region 20 is formed in a region between the peripheral edge of the active surface 8 and the outer contact region 19 in a plan view, and is formed in a strip shape extending along the active surface 8.

In this embodiment, the outer well region 20 is formed in a ring shape (specifically, a quadrangular ring shape) surrounding the active surface 8 in a plan view. The outer well region 20 is formed at an interval from the bottom portion of the first semiconductor region 6 to the outer surface 9. The outer well region 20 may be formed deeper than the outer contact region 19. The outer well region 20 is located on the bottom portion side of the first semiconductor region 6 with respect to the bottom walls of the plurality of gate structures 15 (source structures 16).

The outer well region 20 is electrically connected to the outer contact region 19. In this embodiment, the outer well region 20 extends from the outer contact region 19 toward the first to fourth connecting surfaces 10A to 10D, and covers the first to fourth connecting surfaces 10A to 10D. The outer well region 20 is electrically connected to the body region 13 in the surface layer portion of the active surface 8.

The semiconductor device 1A includes at least one (preferably 2 or more and 20 or less) p-type field region 21 formed in the surface layer portion of the outer surface 9 in a region between the peripheral edge of the outer surface 9 and the outer contact region 19. In this embodiment, the semiconductor device 1A includes five field regions 21. The plurality of field regions 21 reduce an electric field within the chip 2 in the outer surface 9. The number, the width, the depth, the p-type impurity concentration, and the like of the field regions 21 are determined in an arbitrary manner and can take various values depending on an electric field to be relaxed.

The plurality of field regions 21 are arranged at intervals from the outer contact region 19 side to the peripheral edge side of the outer surface 9. The plurality of field regions 21 are formed in strip shapes extending along the active surface 8 in a plan view. In this embodiment, the plurality of field regions 21 are formed in a ring shape (specifically, a quadrangular ring shape) surrounding the active surface 8 in a plan view. As a result, each of the plurality of field regions 21 is formed as a field limiting ring (FLR) region.

The plurality of field regions 21 are formed at intervals from the bottom portion of the first semiconductor region 6 to the outer surface 9. The plurality of field regions 21 are located on the bottom portion side of the first semiconductor region 6 with respect to the bottom walls of the plurality of gate structures 15 (source structures 16). The plurality of field regions 21 may be formed deeper than the outer contact region 19. The innermost field region 21 may be connected to the outer contact region 19.

The semiconductor device 1A includes a main surface insulating film 25 that covers the first main surface 3. The main surface insulating film 25 may include at least one of a silicon oxide film, a silicon nitride film, and a silicon oxynitride film. In this embodiment, the main surface insulating film 25 has a single-layer structure including a silicon oxide film. It is particularly preferable that the main surface insulating film 25 includes a silicon oxide film including an oxide of the chip 2.

The main surface insulating film 25 covers the active surface 8, the outer surface 9, and the first to fourth connecting surfaces 10A to 10D. The main surface insulating film 25 is continuous with the gate insulating film 15b and the source insulating film 16b, and covers the active surface 8 so as to expose the gate embedded electrode 15c and the source embedded electrode 16c. The main surface insulating film 25 covers the outer surface 9 and the first to fourth connecting surfaces 10A to 10D so as to cover the outer contact region 19, the outer well region 20, and the plurality of field regions 21.

The main surface insulating film 25 may be continuous with the first to fourth side surfaces 5A to 5D. In this case, an outer wall of the main surface insulating film 25 may include a ground surface having grinding marks. The outer wall of the main surface insulating film 25 may form one ground surface together with the first to fourth side surfaces 5A to 5D. As a matter of course, the outer wall of the main surface insulating film 25 may include a smooth surface without grinding marks. The outer wall of the main surface insulating film 25 may be formed at an interval inward from the peripheral edge of the outer surface 9 and expose the first semiconductor region 6 from the peripheral edge portion of the outer surface 9.

The semiconductor device 1A includes a sidewall structure 26 formed on a main surface insulating film 25 so as to cover at least one of the first to fourth connecting surfaces 10A to 10D on the outer surface 9. In this embodiment, the sidewall structure 26 is formed in a ring shape (quadrature ring shape) surrounding the active surface 8 in a plan view.

The sidewall structure 26 may have a portion that extends over the active surface 8. The sidewall structure 26 may include an inorganic insulator or polysilicon. The sidewall structure 26 may be a sidewall wiring electrically connected to the source structure 16.

The semiconductor device 1A includes a first inorganic film 27 including an insulator and being formed on the main surface insulating film 25. The first inorganic film 27 may be referred to as a “first inorganic insulating film,” a “base insulating film,” an “intermediate insulating film,” or an “interlayer insulating film.” The first inorganic film 27 may include at least one of a silicon oxide film, a silicon nitride film, and a silicon oxynitride film. In this embodiment, the first inorganic film 27 includes a silicon oxide film.

The first inorganic film 27 covers the active surface 8, the outer surface 9, and the first to fourth connecting surfaces 10A to 10D with the main surface insulating film 25 interposed therebetween. Specifically, the first inorganic film 27 covers the active surface 8, the outer surface 9, and the first to fourth connecting surfaces 10A to 10D via the sidewall structure 26. The first inorganic film 27 covers the MISFET structure 12 on the active surface 8 side, and covers the outer contact region 19, the outer well region 20, and the plurality of field regions 21 on the outer surface 9 side.

In this embodiment, the first inorganic film 27 is continuous with the first to fourth side surfaces 5A to 5D. An outer wall of the first inorganic film 27 may include a ground surface having grinding marks. The outer wall of the first inorganic film 27 may form one ground surface together with the first to fourth side surfaces 5A to 5D. As a matter of course, the outer wall of the first inorganic film 27 may include a smooth surface without grinding marks. The outer wall of the first inorganic film 27 may be formed at an interval inward from the peripheral edge of the outer surface 9 and expose the first semiconductor region 6 from the peripheral edge portion of the outer surface 9.

The semiconductor device 1A includes the gate electrode 30 arranged on the first main surface 3 (first inorganic film 27). The gate electrode 30 is arranged in an inner portion of the first main surface 3 at an interval from the peripheral edge of the first main surface 3. The gate electrode 30 is arranged on the active surface 8 in this embodiment.

Specifically, the gate electrode 30 is arranged in a region on the peripheral edge portion of the active surface 8 close to a central portion of the third connecting surface 10C (third side surface 5C). In this embodiment, the gate electrode 30 is formed in a quadrangular shape in a plan view. As a matter of course, the gate electrode 30 may be formed in a polygonal shape other than a quadrangular shape, a circular shape, or an elliptical shape in a plan view.

The gate electrode 30 preferably has a planar area of 25% or less of the first main surface 3. The planar area of the gate electrode 30 may be 10% or less of the first main surface 3. The gate electrode 30 may have a thickness of 0.5 μm or more and 15 μm or less. The gate electrode 30 is preferably thicker than the first inorganic film 27. The gate electrode 30 may include at least one of a Ti film, a TiN film, a W film, an A1 film, a Cu film, an A1 alloy film, a Cu alloy film, and a conductive polysilicon film.

The gate electrode 30 may include at least one of a pure Cu film (a Cu film having a purity of 99% or more), a pure A1 film (an A1 film having a purity of 99% or more), an AlCu alloy film, an AlSi alloy film, and an AlSiCu alloy film. In this embodiment, the gate electrode 30 has a laminated structure including a Ti film and an A1 alloy film (an AlSiCu alloy film in this embodiment) laminated in this order from the chip 2 side.

The semiconductor device 1A includes the source electrode 32 arranged on the first main surface 3 (first inorganic film 27) at an interval from the gate electrode 30. The source electrode 32 is arranged in the inner portion of the first main surface 3 at an interval from the peripheral edge of the first main surface 3. The source electrode 32 is arranged on the active surface 8 in this embodiment. In this embodiment, the source electrode 32 includes a body electrode portion 33 and at least one (in this embodiment, a plurality of) drawer electrode portions 34A and 34B.

The body electrode portion 33 is arranged in a region on the fourth side surface 5D (fourth connecting surface 10D) side at an interval from the gate electrode 30 in a plan view, and faces the gate electrode 30 in the first direction X. In this embodiment, the body electrode portion 33 is formed in a polygonal shape (specifically, a quadrangular shape) having four sides parallel to the first to fourth side surfaces 5A to 5D in a plan view.

The plurality of drawer electrode portions 34A and 34B include a first drawer electrode portion 34A on one side (the first side surface 5A side) and a second drawer electrode portion 34B on the other side (the second side surface 5B side). The first drawer electrode portion 34A is drawn from the body electrode portion 33 to a region located on one side (the first side surface 5A side) of the gate electrode 30 in the second direction Y in a plan view, and faces the gate electrode 30 in the second direction Y.

The second drawer electrode portion 34B is drawn from the body electrode portion 33 to a region located on the other side (the second side surface 5B side) of the gate electrode 30 in the second direction Y in a plan view, and faces the gate electrode 30 in the second direction Y. That is, the plurality of drawer electrode portions 34A and 34B sandwich the gate electrode 30 from both sides in the second direction Y in a plan view.

The source electrode 32 (body electrode portion 33 and drawer electrode portions 34A and 34B) penetrates the first inorganic film 27 and the main surface insulating film 25, and is electrically connected to the plurality of source structures 16, the source region 14, and the plurality of well regions 18. As a matter of course, the source electrode 32 may include only the body electrode portion 33 without having the drawer electrode portions 34A and 34B.

The source electrode 32 has a planar area larger than the planar area of the gate electrode 30. The planar area of the source electrode 32 is preferably 50% or more of the first main surface 3. It is particularly preferable that the planar area of the source electrode 32 be 75% or more of the first main surface 3. The source electrode 32 may have a thickness of 0.5 μm or more and 15 μm or less. The source electrode 32 is preferably thicker than the first inorganic film 27. The source electrode 32 may include at least one of a Ti film, a TiN film, a W film, an A1 film, a Cu film, an A1 alloy film, a Cu alloy film, and a conductive polysilicon film.

The source electrode 32 preferably includes at least one of a pure Cu film (a Cu film having a purity of 99% or more), a pure A1 film (an A1 film having a purity of 99% or more), an AlCu alloy film, an AlSi alloy film, and an AlSiCu alloy film. In this embodiment, the source electrode 32 has a laminated structure including a Ti film and an A1 alloy (an AlSiCu alloy film in this embodiment) laminated in this order from the chip 2 side. The source electrode 32 preferably includes the same conductive material as the gate electrode 30.

The semiconductor device 1A includes at least one (in this embodiment, a plurality of) gate wirings 36A, 36B drawn from the gate electrode 30 onto the first main surface 3 (first inorganic film 27). The plurality of gate wirings 36A, 36B preferably include the same conductive material as the gate electrode 30. In this embodiment, the plurality of gate wirings 36A, 36B cover the active surface 8 but do not cover the outer surface 9. The plurality of gate wirings 36A, 36B are drawn to a region between the peripheral edge of the active surface 8 and the source electrode 32 in a plan view, and extend in a strip shape along the source electrode 32.

Specifically, the plurality of gate wirings 36A, 36B include a first gate wiring 36A and a second gate wiring 36B. The first gate wiring 36A is drawn from the gate electrode 30 to a region on the first side surface 5A side in a plan view. The first gate wiring 36A has a portion extending in a strip shape in the second direction Y along the third side surface 5C, and a portion extending in a strip shape in the first direction X along the first side surface 5A. The second gate wiring 36B is drawn from the gate electrode 30 to a region on the second side surface 5B side in a plan view. The second gate wiring 36B has a portion extending in a strip shape in the second direction Y along the third side surface 5C, and a portion extending in a strip shape in the first direction X along the second side surface 5B.

The plurality of gate wirings 36A, 36B intersect (specifically, perpendicularly intersect) both ends of the plurality of gate structures 15 at the peripheral edge portion of the active surface 8 (first main surface 3). The plurality of gate wirings 36A, 36B penetrate the first inorganic film 27 and are electrically connected to the plurality of gate structures 15. The plurality of gate wirings 36A, 36B may be directly connected to the plurality of gate structures 15, or may be electrically connected to the plurality of gate structures 15 via a conductive film.

The semiconductor device 1A includes a source wiring 37 drawn out from the source electrode 32 onto the first main surface 3 (first inorganic film 27). The source wiring 37 preferably contains the same conductive material as the source electrode 32. The source wiring 37 is formed in a strip shape extending along the peripheral edge of the active surface 8 in a region closer to the outer surface 9 than the plurality of gate wirings 36A, 36B. In this embodiment, the source wiring 37 is formed in a ring shape (specifically, a quadrangular ring shape) surrounding the gate electrode 30, the source electrode 32, and the plurality of gate wirings 36A, 36B in a plan view.

The source wiring 37 covers the sidewall structure 26 with the first inorganic film 27 interposed therebetween, and is drawn out from the active surface 8 side to the outer surface 9 side. It is preferable that the source wiring 37 covers the entire sidewall structure 26. The source wiring 37 has a portion that penetrates the first inorganic film 27 and the main surface insulating film 25 on the outer surface 9 side and is connected to the outer surface 9 (specifically, the outer contact region 19). The source wiring 37 may penetrate the first inorganic film 27 and be electrically connected to the sidewall structure 26.

The semiconductor device 1A includes at least one (a single or a plurality of) base through holes 40 formed in the first inorganic film 27 in a portion covering the outer surface 9 (the peripheral edge portion of the first main surface 3). The single or the plurality of base through holes 40 are formed at intervals from the peripheral edge of the active surface 8 and the peripheral edge of the outer surface 9 in a plan view, and penetrate the main surface insulating film 25 and expose the outer surface 9 (the peripheral edge portion of the first main surface 3).

The single or the plurality of base through holes 40 are formed at intervals from the gate electrode 30 and the source electrode 32 toward the peripheral edge of the outer surface 9. That is, the single or the plurality of base through holes 40 are formed around the gate electrode 30 and around the source electrode 32. Specifically, the single or the plurality of base through holes 40 are formed at intervals from the source wiring 37 to the peripheral edge side of the outer surface 9. That is, the single or the plurality of base through holes 40 are formed around the source wiring 37.

It is preferable that the single or the plurality of base through holes 40 are formed at intervals on the peripheral edge side of the outer surface 9 from the plurality of field regions 21 (the outermost field region 21). That is, it is preferable that the single or the plurality of base through holes 40 are formed around the field region 21. It is preferable that an opening edge portion of the single or the plurality of base through holes 40 is formed in a curved shape.

The number and the layout of the base through holes 40 are determined in an arbitrary manner. For example, at least one of the base through holes 40 may be formed in the first inorganic film 27 so as to surround the active surface 8 in a plan view. That is, at least one of the base through holes 40 may be formed in the first inorganic film 27 so as to surround the gate electrode 30, the source electrode 32, the gate wirings 36A, 36B, and the source wiring 37 in a plan view.

The form in which at least one of the base through holes 40 surrounds the active surface 8 may include a form in which a single base through hole 40 having an end or endless shape faces the active surface 8 from a plurality of directions. Also, the form in which at least one of the base through holes 40 surrounds the active surface 8 may include a form in which a plurality of base through holes 40 having an end or endless shape face the active surface 8 from a plurality of directions.

The plurality of directions are preferably four directions. The four directions are four normal directions of the first to fourth side surfaces 5A to 5D. That is, the four directions are one side in the first direction X, the other side in the first direction X, one side in the second direction Y, and the other side in the second direction Y. The four directions can also be defined by four crystal directions of the SiC single crystal. For example, the four crystal directions are one direction in the a-axis direction (for example, a [11-20] direction), another direction in the a-axis direction (for example, a [−1-120] direction), one direction in the m-axis direction (for example, a [−1100] direction), and another direction in the m-axis direction (for example, a [1-100] direction).

At least one of the base through holes 40 may be formed in a polygonal shape, such as a triangular shape, a quadrangular shape, a hexagonal shape, or an octagonal shape, in a plan view. At least one of the base through holes 40 may be formed in a circular shape in a plan view. At least one of the base through holes 40 may be formed in a strip shape, a rectangular shape, an elliptical shape, or an oval shape extending in either the first direction X or the second direction Y in a plan view. At least one of the base through holes 40 may be formed in a strip shape, a rectangular shape, an elliptical shape, or an oval shape extending in a direction intersecting the first direction X and the second direction Y in a plan view.

At least one of the base through holes 40 may have a portion (side) extending in the first direction X and/or a portion (side) extending in the second direction Y. At least one of the base through holes 40 may have a portion (side) extending in a direction intersecting the first direction X and the second direction Y. At least one of the base through holes 40 may be formed in a C-shape, an L-shape, a T-shape, or a cross shape in a plan view.

At least one of the base through holes 40 may be formed in a ring shape on the side of the active surface 8 in a plan view. That is, at least one of the base through holes 40 may be formed in a small ring shape that does not surround the active surface 8 in a plan view. In this case, at least one of the base through holes 40 may be formed in a polygonal ring shape, such as a triangular ring shape, a quadrangular ring shape, a hexagonal ring shape, or an octagonal ring shape, in a plan view. Furthermore, at least one of the base through holes 40 may be formed in a circular ring shape in a plan view.

Also, at least one of the base through holes 40 may be formed in a band ring shape, a rectangular ring shape, an elliptical ring shape, or an oval ring shape extending in either the first direction X or the second direction Y in a plan view. At least one of the base through holes 40 may be formed in a band ring shape, a rectangular ring shape, an elliptical ring shape, or an oval ring shape extending in a direction intersecting the first direction X and the second direction Y in a plan view.

As a matter of course, at least one of the base through holes 40 may be formed in a large ring shape surrounding the active surface 8 in a plan view. In this case, at least one of the base through holes 40 may be formed in a ring shape (for example, a quadrangular ring shape) extending along the first inorganic film 27. As a matter of course, as long as the size of the first inorganic film 27 allows, at least one of the base through holes 40 may be formed in a polygonal ring shape, a circular ring shape, an elliptical ring shape, or an oval ring shape.

The plurality of base through holes 40 may be formed at intervals in the first direction X. The plurality of base through holes 40 may be formed at intervals in the second direction Y. The plurality of base through holes 40 may be formed at intervals in the first direction X and the second direction Y. The plurality of base through holes 40 may be formed at intervals in a direction intersecting the first direction X and the second direction Y.

The plurality of base through holes 40 extending in a stripe pattern in the first direction X may be formed. The plurality of base through holes 40 extending in a stripe pattern in the second direction Y may be formed. The plurality of base through holes 40 extending in a stripe pattern in the first direction X and the plurality of base through holes 40 extending in a stripe pattern in the second direction Y may coexist adjacent to each other in the first direction X or the second direction Y. That is, at least one of the base through holes 40 extending in the first direction X and at least one of the base through holes 40 extending in the second direction Y may be formed adjacent to each other in the first direction X or the second direction Y.

As a matter of course, the lattice-shaped base through hole 40 may be formed that integrally includes the plurality of base through holes 40 extending in a stripe pattern in the first direction X and a plurality of base through holes 40 extending in a stripe pattern in the second direction Y. That is, the base through holes 40 extending in the first direction X and the second direction Y in a mesh (lattice) shape may be formed. As a matter of course, the base through holes 40 extending in a direction intersecting the first direction X and the second direction Y in a mesh (lattice) shape may be formed.

In the above description of the base through hole 40, the first direction X may be the a-axis direction of the SiC single crystal, and the second direction Y may be the m-axis direction of the SiC single crystal. As a matter of course, in the above description of the base through hole 40, the first direction X may be the m-axis direction of the SiC single crystal, and the second direction Y may be the a-axis direction of the SiC single crystal. The layout of the single or the plurality of base through holes 40 may be determined from the perspective of stress occurring along the crystallographic direction of the SiC single crystal. That is, by adjusting the layout of the single or the plurality of base through holes 40, it is possible to suppress bias in the stress in a specific direction (crystal direction).

The semiconductor device 1A may include a layout in which at least two of the above-mentioned plurality of layouts of the base through holes 40 are combined. In this embodiment, the semiconductor device 1A includes at least one of the base through holes 40 formed in a strip shape extending along the peripheral edge of the outer surface 9 (peripheral edge of the first main surface 3) in a plan view. In this embodiment, the base through hole 40 is formed in a ring shape (specifically, a quadrangular ring shape) surrounding the active surface 8 in a plan view. The base through hole 40 has an inner wall portion on the active surface 8 side and an outer wall portion on the peripheral edge side of the outer surface 9.

The base through hole 40 preferably has a width greater than the thickness of the first inorganic film 27. The width of the base through hole 40 is a width in a direction perpendicular to the extension direction of the base through hole 40. The width of the base through hole 40 may be 1 μm or more and 15 μm or less, and the width of the base through hole 40 is preferably 2 μm or more and 10 μm or less. It is particularly preferable that the width of the base through hole 40 is 5 μm or less.

The semiconductor device 1A includes a second inorganic film 41 including an insulator and covering the first inorganic film 27. The second inorganic film 41 may be referred to as a “second inorganic insulating film,” an “upper insulating film,” or a “passivation film.” The second inorganic film 41 may include at least one of a silicon oxide film, a silicon nitride film, and a silicon oxynitride film. The second inorganic film 41 preferably contains an insulator different from that of the first inorganic film 27. The second inorganic film 41 preferably includes a silicon nitride film.

The second inorganic film 41 may have a thickness equal to or greater than the thickness of the first inorganic film 27, or may have a thickness less than the thickness of the first inorganic film 27. The thickness of the second inorganic film 41 is preferably less than the thickness of the gate electrode 30 (source electrode 32). The second inorganic film 41 may have a thickness of 0.1 μm or more and 5 μm or less. The thickness of the second inorganic film 41 is preferably 1 μm or more and 2.5 μm or less. The thickness of the second inorganic film 41 is preferably less than half the width of the base through hole 40.

The second inorganic film 41 selectively covers the active surface 8 and the outer surface 9. In this embodiment, the second inorganic film 41 includes a gate covering portion 42, a source covering portion 43, and an outer covering portion 44. The gate covering portion 42 may be referred to as a “first covering portion,” the source covering portion 43 may be referred to as a “second covering portion,” and the outer covering portion 44 may be referred to as a “third covering portion.”

The gate covering portion 42 covers the gate electrode 30. In this embodiment, the gate covering portion 42 covers only the gate electrode 30, and exposes the source electrode 32, the gate wirings 36A, 36B, and the source wiring 37. The gate covering portion 42 is arranged on the gate electrode 30 at an interval inward from the peripheral edge of the gate electrode 30, and exposes the peripheral edge portion of the gate electrode 30.

Specifically, the gate covering portion 42 exposes the electrode sidewall of the gate electrode 30. The gate covering portion 42 defines a gate opening 45 that is formed in a strip shape extending along the peripheral edge of the gate electrode 30 in a plan view, and exposes the inner portion of the gate electrode 30. In this embodiment, the gate opening 45 is formed in a quadrangular shape in a plan view.

The source covering portion 43 covers the source electrode 32. In this embodiment, the source covering portion 43 covers only the source electrode 32, and exposes the gate electrode 30, the gate wirings 36A, 36B, and the source wiring 37. The source covering portion 43 is arranged on the source electrode 32 at an interval inward from the peripheral edge of the source electrode 32, and exposes the peripheral edge portion of the source electrode 32.

Specifically, the source covering portion 43 exposes the electrode sidewall of the source electrode 32. The source covering portion 43 is formed in a strip shape extending along the peripheral edge portion of the source electrode 32 in a plan view, and defines a source opening 46 that exposes the inner portion of the source electrode 32. In this embodiment, the source opening 46 is formed in a polygonal shape that follows the peripheral edge of the source electrode 32 in a plan view. The source covering portion 43 defines a first exposed portion 47 (first removed portion) in the region between the gate covering portion 42 and the source covering portion 43, which exposes the first inorganic film 27, the electrode side wall of the gate electrode 30, and the electrode side wall of the source electrode 32.

The outer covering portion 44 covers the first inorganic film 27 on the outer surface 9 (the peripheral edge portion of the first main surface 3). In this embodiment, the outer covering portion 44 covers the first inorganic film 27 at an interval from the peripheral edge of the active surface 8 (first to fourth connecting surfaces 10A to 10D) and the peripheral edge of the outer surface 9 (first to fourth side surfaces 5A to 5D). Specifically, the outer covering portion 44 is arranged on the first inorganic film 27 in the outer surface 9 at an interval from the gate electrode 30, the source electrode 32, the gate wirings 36A, 36B, and the source wiring 37. That is, the outer covering portion 44 does not cover the metal (electrode).

The outer covering portion 44 defines a second exposed portion 48 (second removed portion) in the region between the gate covering portion 42 and the outer covering portion 44, which exposes the electrode sidewall of the gate electrode 30, the gate wirings 36A, 36B, and the source wiring 37. The second exposed portion 48 also exposes a step between the active surface 8 and the outer surface 9 (that is, the sidewall structure 26). The second exposed portion 48 is connected to the first exposed portion 47.

The outer covering portion 44 defines a third exposed portion 49 (third removed portion) in the region between the source covering portion 43 and the outer covering portion 44, which exposes the electrode sidewall of the source electrode 32, the gate wirings 36A, 36B, and the source wiring 37. The third exposed portion 49 also exposes a step between the active surface 8 and the outer surface 9 (that is, the sidewall structure 26). The third exposed portion 49 is connected to the first exposed portion 47 and the second exposed portion 48.

The outer covering portion 44 is formed in a strip shape extending along the peripheral edge of the outer surface 9 (the peripheral edge of the first main surface 3) in a plan view. In this embodiment, the outer covering portion 44 is formed in a ring shape (specifically, a quadrangular ring shape) surrounding the active surface 8 in a plan view. The outer covering portion 44 has an inner edge portion on the active surface 8 side and an outer edge portion on the peripheral edge side of the outer surface 9.

The inner edge portion of the outer covering portion 44 is preferably located closer to the active surface 8 than the outermost field region 21. That is, it is preferable that the outer covering portion 44 is arranged so as to overlap at least one field region 21. It is preferable that the outer covering portion 44 faces at least one field region 21 with the first inorganic film 27 interposed therebetween. As a matter of course, the inner edge portion of the outer covering portion 44 may be located closer to the active surface 8 than the innermost field region 21. That is, the outer covering portion 44 may be arranged so as to overlap the entire field region 21.

The outer edge portion of the outer covering portion 44 is formed at an interval inward from the peripheral edge of the outer surface 9, and defines a dicing street 50 between the outer covering portion 44 and the peripheral edge of the outer surface 9. The dicing street 50 is formed in a strip shape extending along the peripheral edge of the outer surface 9 (first to fourth side surfaces 5A to 5D) in a plan view. In this embodiment, the dicing street 50 is formed in a ring shape (specifically, a quadrangular ring shape) surrounding the inner portion (active surface 8) of the first main surface 3 in a plan view. In this embodiment, the dicing street 50 exposes the first inorganic film 27.

As a matter of course, when the main surface insulating film 25 and the first inorganic film 27 expose the outer surface 9, the dicing street 50 may also expose the outer surface 9. The dicing street 50 may have a width of 1 μm or more and 200 μm or less. The width of the dicing street 50 is a width in a direction perpendicular to the direction in which the dicing street 50 extends. The width of the dicing street 50 is preferably 5 μm or more and 50 μm or less.

The outer covering portion 44 enters the base through hole 40 from above the first inorganic film 27 and is directly connected to the outer surface 9 (peripheral edge portion of the first main surface 3) within the base through hole 40. The outer covering portion 44 has a width greater than the width of the base through hole 40. The outer covering portion 44 enters the base through hole 40 from above the first inorganic film 27 via the inner wall portion of the base through hole 40 and is drawn out onto the first inorganic film 27 via the outer wall portion of the base through hole 40. As a result, the outer covering portion 44 covers both the inner wall portion and the outer wall portion of the base through hole 40.

In this embodiment, the outer covering portion 44 includes the first portion 51 and a second portion 52. The first portion 51 is a portion that covers the first inorganic film 27 outside the base through hole 40. The first portion 51 has a first upper surface located on the outer surface 9 side with respect to the active surface 8. The second portion 52 is a portion that covers the outer surface 9 inside the base through hole 40. The second portion 52 has a second upper surface located on the outer surface 9 side with respect to the first upper surface. That is, the second portion 52 defines a recessed portion 53 (stepped portion) recessed toward the outer surface 9 between the second portion 52 and the first portion 51.

The semiconductor device 1A includes at least one (single or a plurality of) through holes 55 formed in the outer covering portion 44 (second inorganic film 41). Even if the single through hole 55 is formed in a plan view, if the plurality of through holes 55 appear in a cross-sectional view, it is considered that the plurality of through holes 55 are formed in the cross-sectional view.

Even if the single through hole 55 is formed in a plan view, if the plurality of through holes 55 can be regarded as being integrated, it may be considered as the plurality of through holes 55 being formed. Conversely, even if the plurality of through holes 55 are formed in a plan view, if the plurality of through holes 55 can be considered as being integrated, it may be considered as the single through hole 55 being formed.

The single or the plurality of through holes 55 are formed at intervals from the gate electrode 30 and the source electrode 32 toward the peripheral edge of the outer surface 9. That is, the single or the plurality of through holes 55 are formed around the gate electrode 30 and around the source electrode 32. Specifically, the single or the plurality of through holes 55 are formed at intervals from the source wiring 37 to the peripheral edge side of the outer surface 9.

That is, the single or the plurality of through holes 55 are formed around the source wiring 37. The single or the plurality of through holes 55 are preferably formed at intervals on the peripheral edge side of the outer surface 9 from the plurality of field regions 21 (the outermost field region 21). That is, it is preferable that the single or the plurality of through holes 55 are formed around the field region 21.

The through holes 55 are classified into a first-type through hole 56 and a second-type through hole 57, based on an object to be exposed observed in the cross section. The first-type through hole 56 is formed in the outer covering portion 44 so as to expose only the first inorganic film 27 in a cross-sectional view. The first-type through hole 56 is formed in the first portion 51 of the second inorganic film 41.

One or more first-type through holes 56 may be formed only in the region on the active surface 8 side with respect to the base through hole 40. The one or more first-type through holes 56 may be formed only on the outer surface 9 at the peripheral edge region with respect to the base through hole 40. The plurality of first-type through holes 56 may be formed in a region on the active surface 8 side with respect to the base through hole 40 and in a region on the peripheral edge side of the outer surface 9 with respect to the base through hole 40.

The second-type through hole 57 is formed in the outer covering portion 44 so as to expose the outer surface 9. The second-type through hole 57 is formed at least in the second portion 52 of the outer covering portion 44. The second-type through hole 57 may be formed in the outer covering portion 44 through the wall portion of the base through hole 40 so as to expose both the outer surface 9 and the first inorganic film 27. That is, the second-type through hole 57 may be formed in the first portion 51 and the second portion 52 of the outer covering portion 44.

The second-type through hole 57 may pass through either or both of the inner wall portion of the base through hole 40 and the outer wall portion of the base through hole 40. That is, the second-type through hole 57 may expose a portion of the base through hole 40 in a cross-sectional view, or may expose the entire area of the base through hole 40 in a cross-sectional view.

The semiconductor device 1A may include either or both of the first-type through hole 56 and the second-type through hole 57 in one cross section. The semiconductor device 1A may include only the first-type through hole 56 in any first cross section, and may include only the second-type through hole 57 in any second cross section different from the first cross section.

The semiconductor device 1A may include both the first-type through hole 56 and the second-type through hole 57 in the first cross section, and may include only the first-type through hole 56 in the second cross section. The semiconductor device 1A may include both the first-type through hole 56 and the second-type through hole 57 in the first cross section, and may include only the second-type through hole 57 in the second cross section.

Whether the through hole 55 belongs to either the first-type through hole 56 or the second-type through hole 57 is determined by an object to be exposed of the through hole 55 in any cross section, and the layout of the through holes 55 (the number, the planar shape, the size, and the like) is determined in an arbitrary manner. The layout of the through holes 55 will be described below. The description of the layout of the through holes 55 also applies to the layout of the first-type through holes 56 and the layout of the second-type through hole 57.

At least one of the through holes 55 is preferably formed in the outer covering portion 44 so as to surround the active surface 8 in a plan view. That is, at least one of the through holes 55 may be formed in the first inorganic film 27 so as to surround the gate electrode 30, the source electrode 32, the gate wirings 36A, 36B, and the source wiring 37 in a plan view.

An aspect in which at least one of the through holes 55 surrounds the active surface 8 may include an aspect in which the single through hole 55 having an end or endless shape faces the active surface 8 from a plurality of directions. Also, An aspect in which at least one of the through holes 55 surrounds the active surface 8 may include an aspect in which the plurality of through holes 55 having an end or endless shape face the active surface 8 from a plurality of directions.

The plurality of directions are preferably four directions. The four directions are four normal directions of the first to fourth side surfaces 5A to 5D. That is, the four directions are one side in the first direction X, the other side in the first direction X, one side in the second direction Y, and the other side in the second direction Y. The four directions can also be defined by four crystal directions of the SiC single crystal. The four crystal directions may be one direction in the a-axis direction (for example, a [11-20] direction), another direction in the a-axis direction (for example, a [−1-120] direction), one direction in the m-axis direction (for example, a [−1100] direction), and another direction in the m-axis direction (for example, a [1-100] direction).

At least one of the through holes 55 may be formed in a polygonal shape, such as a triangular shape, a quadrangular shape, a hexagonal shape, or an octagonal shape, in a plan view. At least one of the through holes 55 may be formed in a circular shape in a plan view. At least one of the through holes 55 may be formed in a strip shape, a rectangular shape, an elliptical shape, or an oval shape extending in either the first direction X or the second direction Y in a plan view. At least one of the through holes 55 may be formed in a strip shape, a rectangular shape, an elliptical shape, or an oval shape extending in a direction intersecting the first direction X and the second direction Y in a plan view.

At least one of the through holes 55 may have a portion (side) extending in the first direction X and/or a portion (side) extending in the second direction Y. At least one of the through holes 55 may have a portion (side) extending in a direction intersecting the first direction X and the second direction Y. At least one of the through holes 55 may be formed in a C-shape, an L-shape, a T-shape, or a cross shape in a plan view.

At least one of the through holes 55 may be formed in a ring shape on a side of the active surface 8 in a plan view. That is, at least one through hole 55 may be formed in a small ring shape that does not surround the active surface 8 in a plan view. In this case, at least one through hole 55 may be formed in a polygonal ring shape, such as a triangular ring shape, a square ring shape, a hexagonal ring shape, or an octagonal ring shape, in a plan view. At least one of the through holes 55 may be formed in a circular ring shape in a plan view.

At least one of the through holes 55 may be formed in a band ring shape, a rectangular ring shape, an elliptical ring shape, or an oval ring shape extending in either the first direction X or the second direction Y in a plan view. Also, at least one through hole 55 may be formed in a band ring shape, a rectangular ring shape, an elliptical ring shape, or an oval ring shape extending in a direction intersecting the first direction X and the second direction Y in a plan view.

As a matter of course, at least one through hole 55 may be formed in a large ring shape surrounding the active surface 8 in a plan view. In this case, at least one through hole 55 may be formed in a ring shape (for example, a quadrangular ring shape) extending along the outer covering portion 44. As a matter of course, as long as the size of the outer covering portion 44 allows, the at least one through hole 55 may be formed in a polygonal ring shape, a circular ring shape, an elliptical ring shape, or an oval ring shape.

The plurality of through holes 55 may be formed at intervals in the first direction X. The plurality of through holes 55 may be formed at intervals in the second direction Y. The plurality of through holes 55 may be formed at intervals in the first direction X and the second direction Y. The plurality of through holes 55 may be formed at intervals in a direction intersecting the first direction X and the second direction Y.

The plurality of through holes 55 extending in a stripe pattern in the first direction X may be formed. The plurality of through holes 55 extending in a stripe pattern in the second direction Y may be formed. The plurality of through holes 55 extending in a stripe pattern in the first direction X and the plurality of through holes 55 extending in a stripe pattern in the second direction Y may coexist adjacent to each other in the first direction X or the second direction Y. That is, at least one through hole 55 extending in the first direction X and at least one through hole 55 extending in the second direction Y may be formed adjacent to each other in the first direction X or the second direction Y.

As a matter of course, the lattice-shaped through hole 55 may be formed that integrally includes a plurality of through holes 55 extending in a stripe pattern in the first direction X and the plurality of through holes 55 extending in a stripe pattern in the second direction Y. That is, the through holes 55 extending in the first direction X and the second direction Y in a mesh (lattice) pattern may be formed. As a matter of course, the through holes 55 extending in a direction intersecting the first direction X and the second direction Y in a mesh (lattice) shape may be formed.

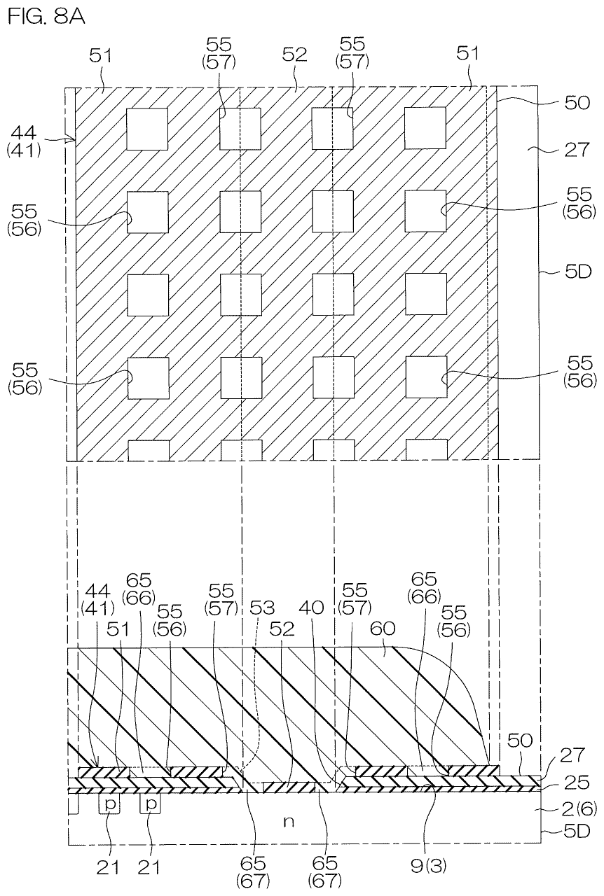

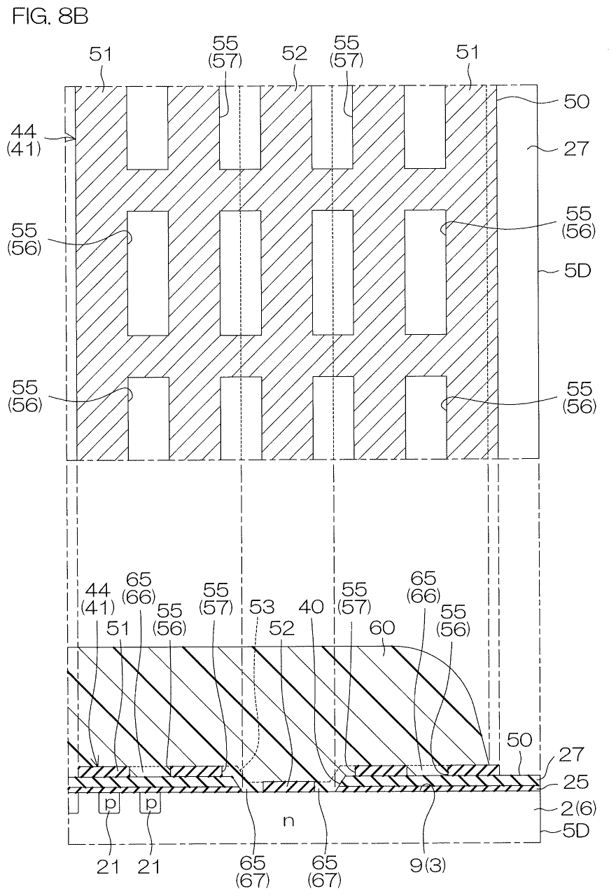

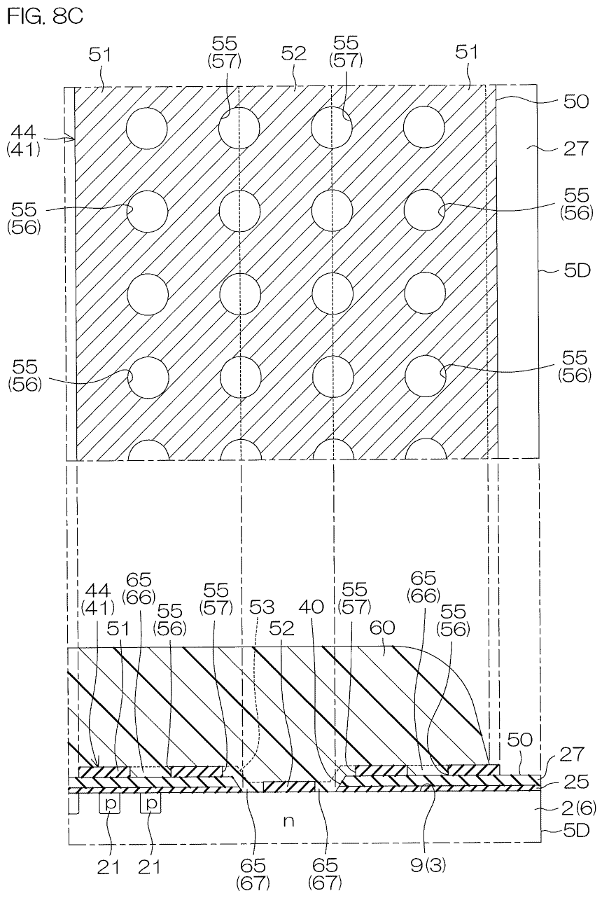

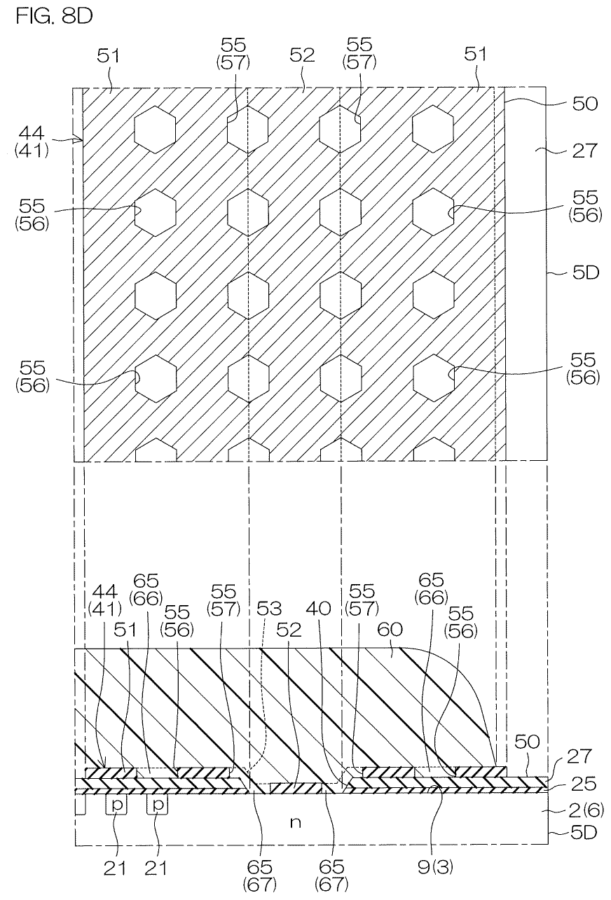

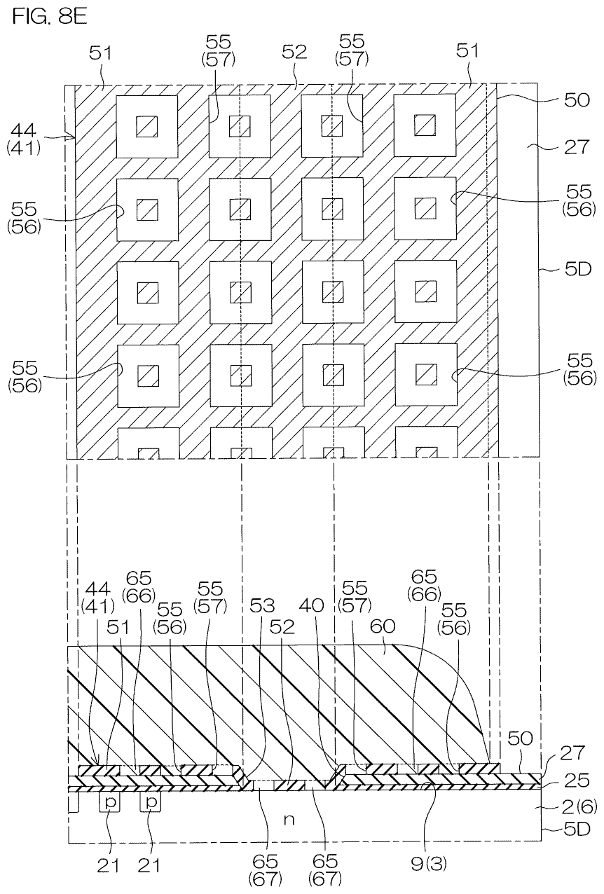

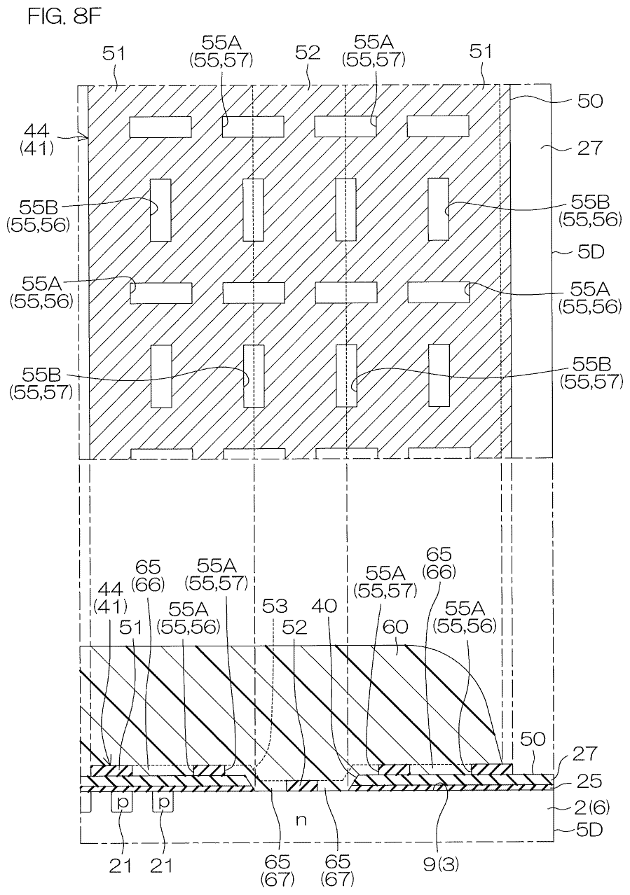

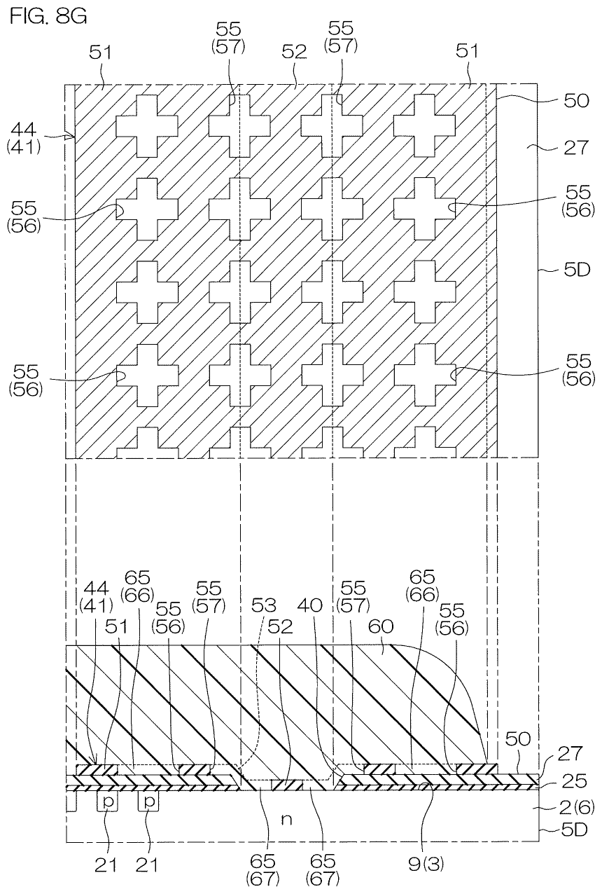

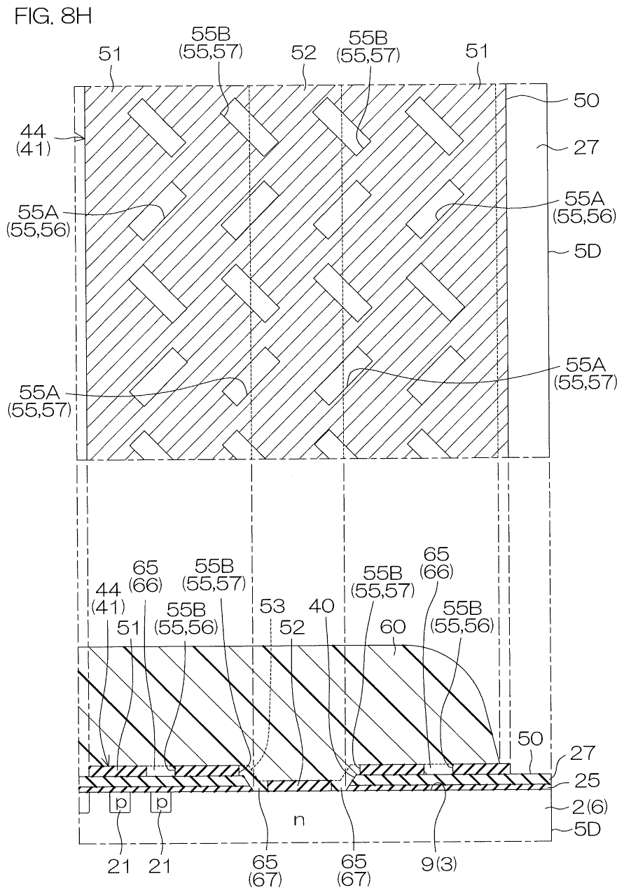

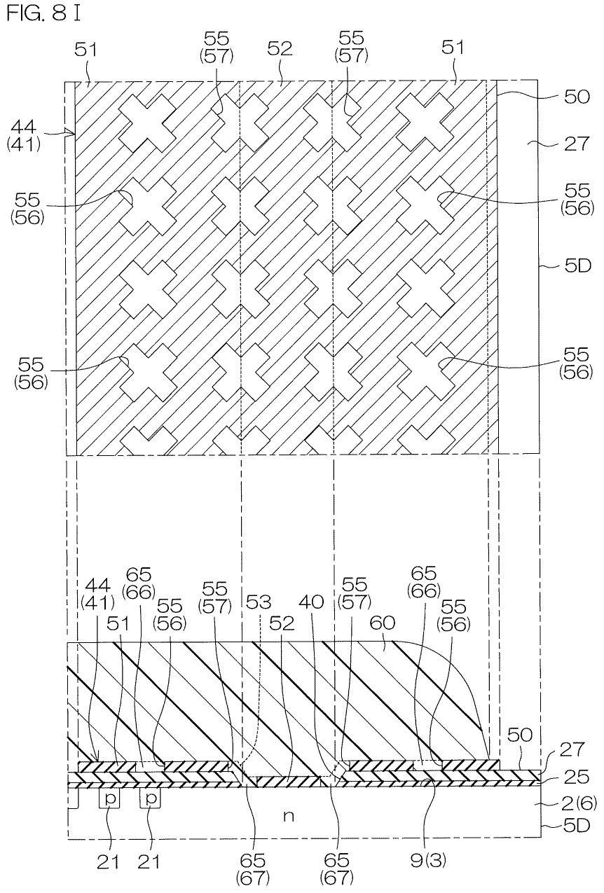

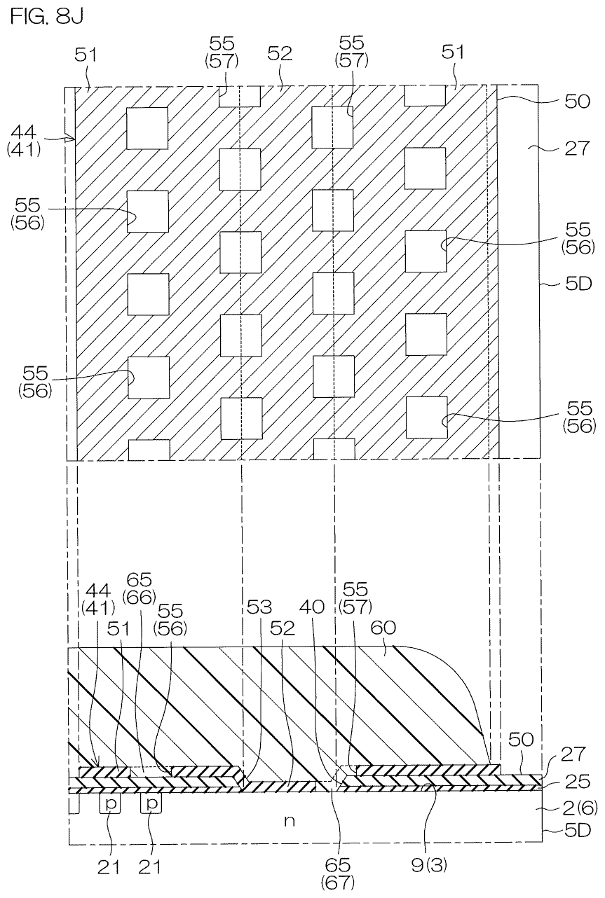

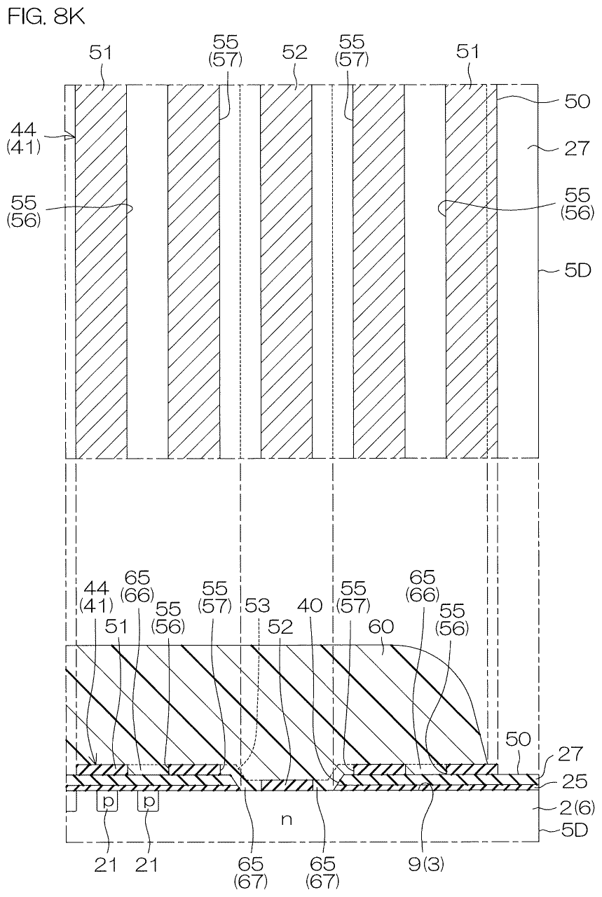

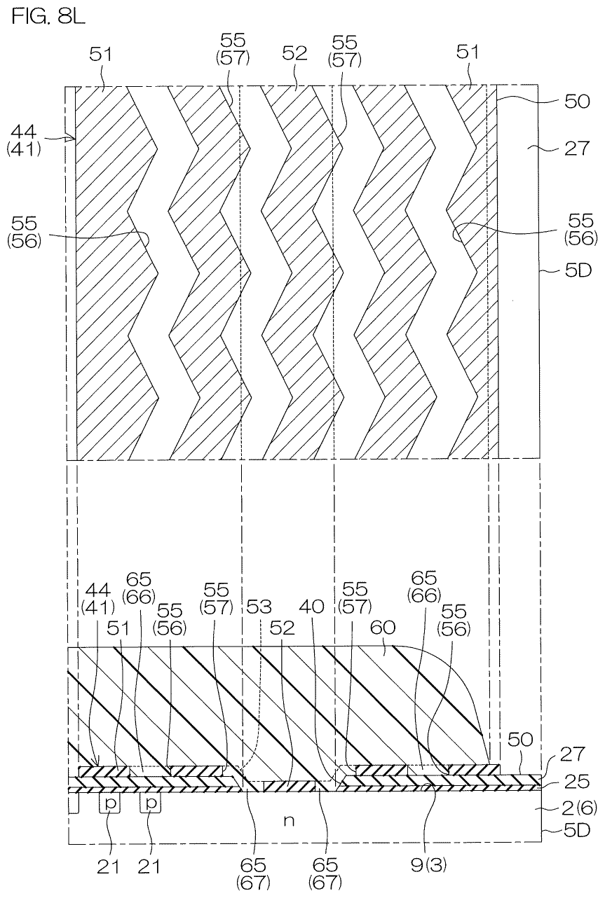

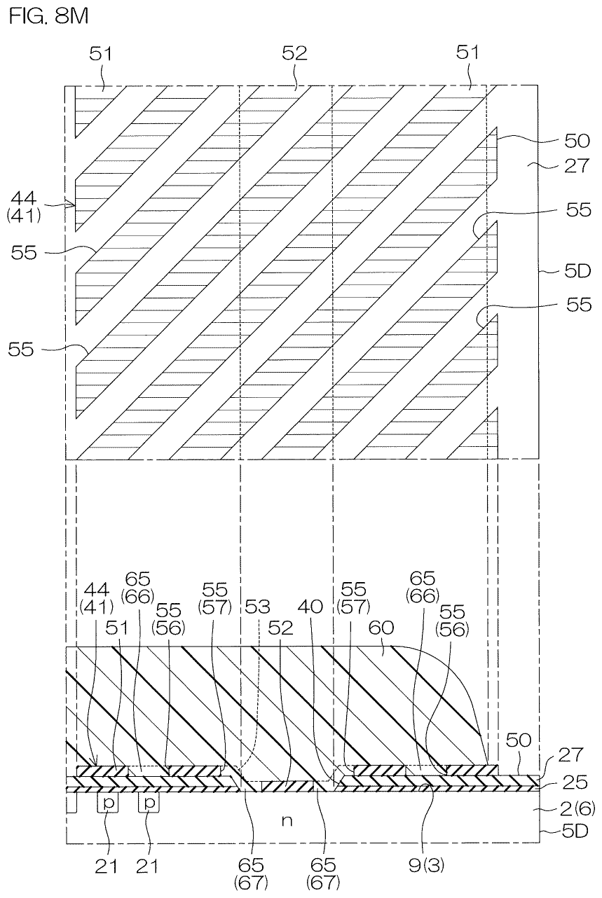

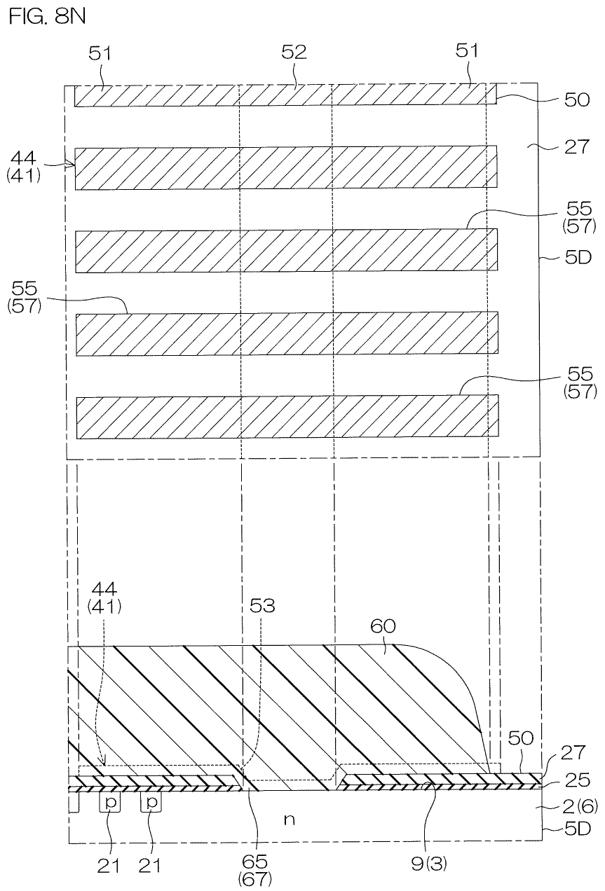

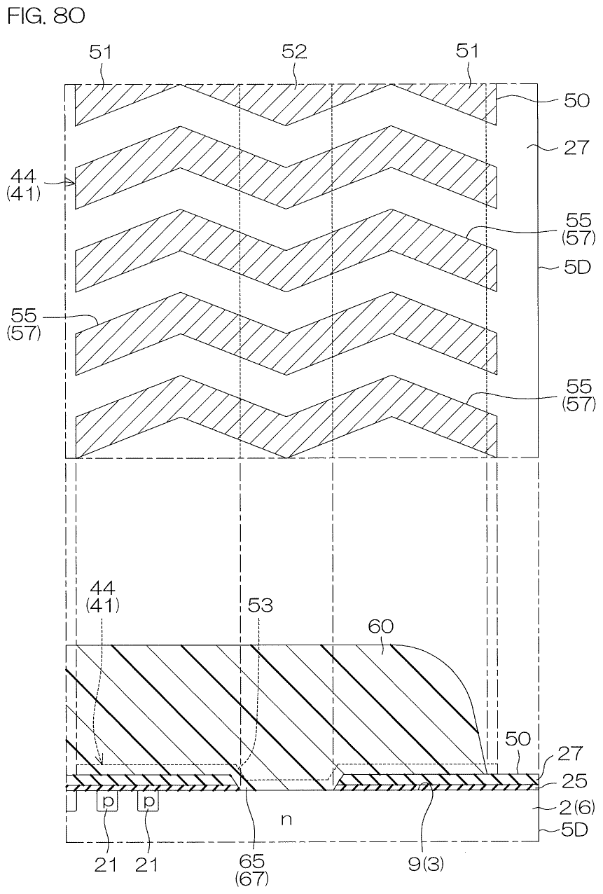

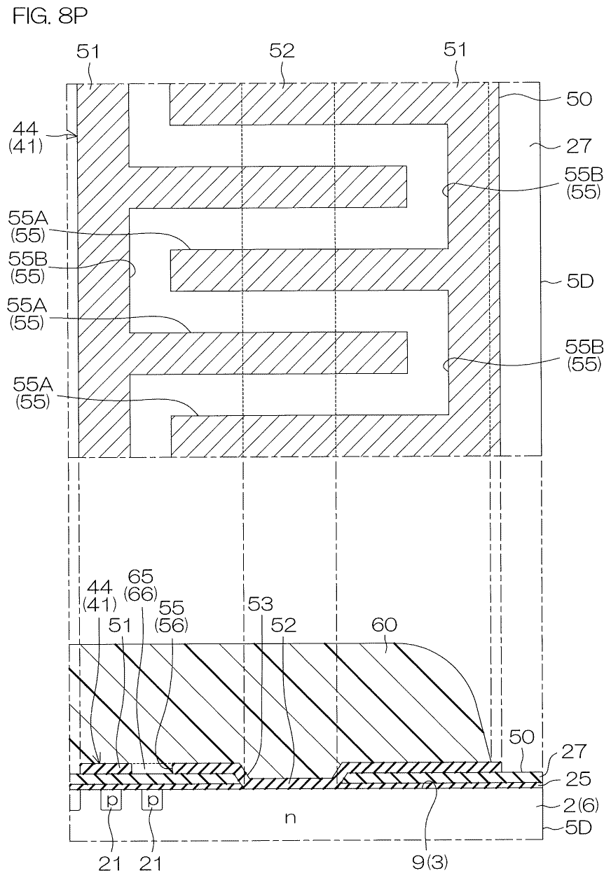

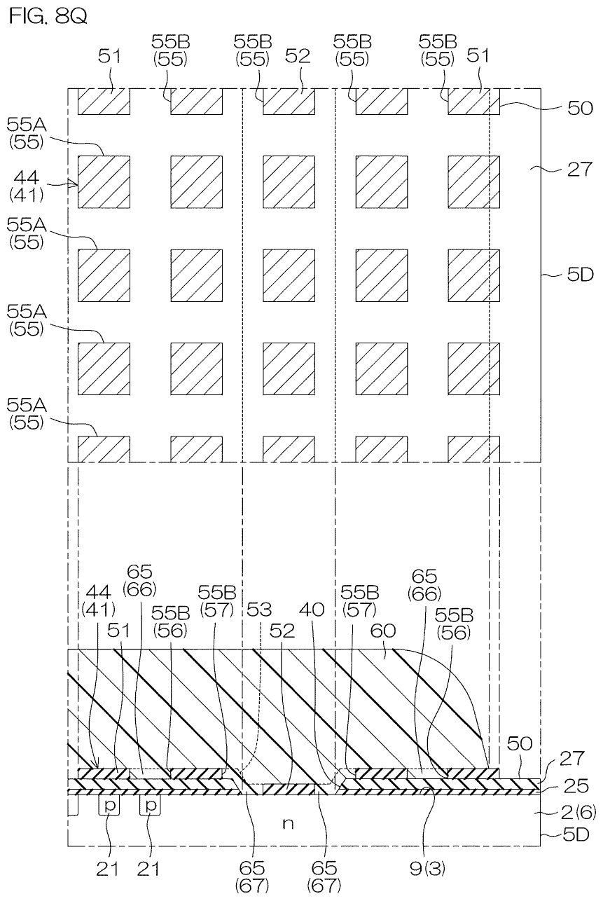

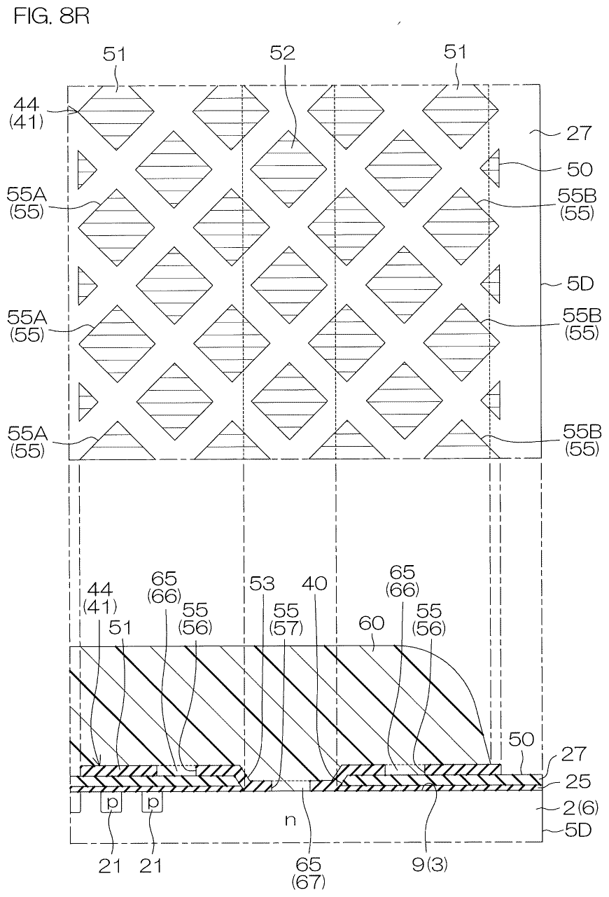

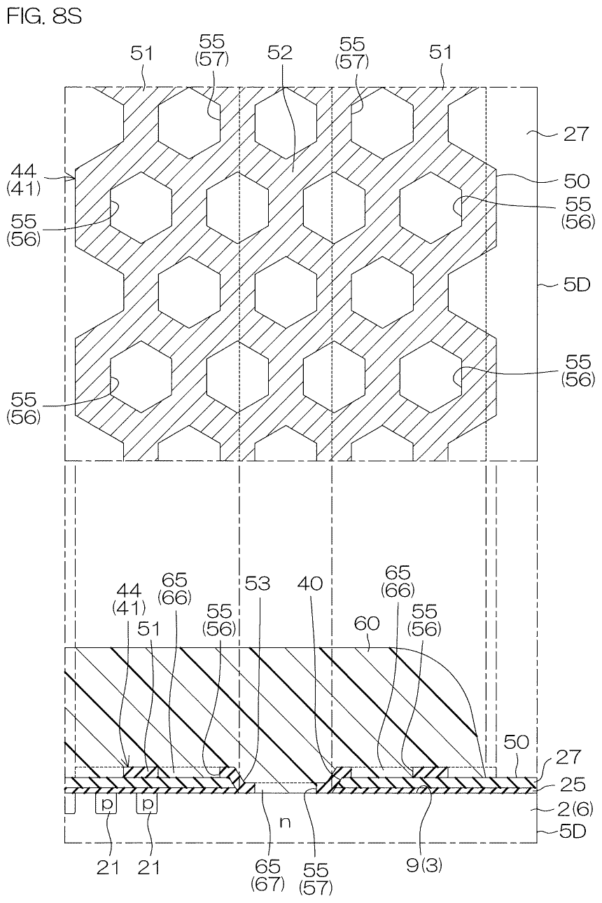

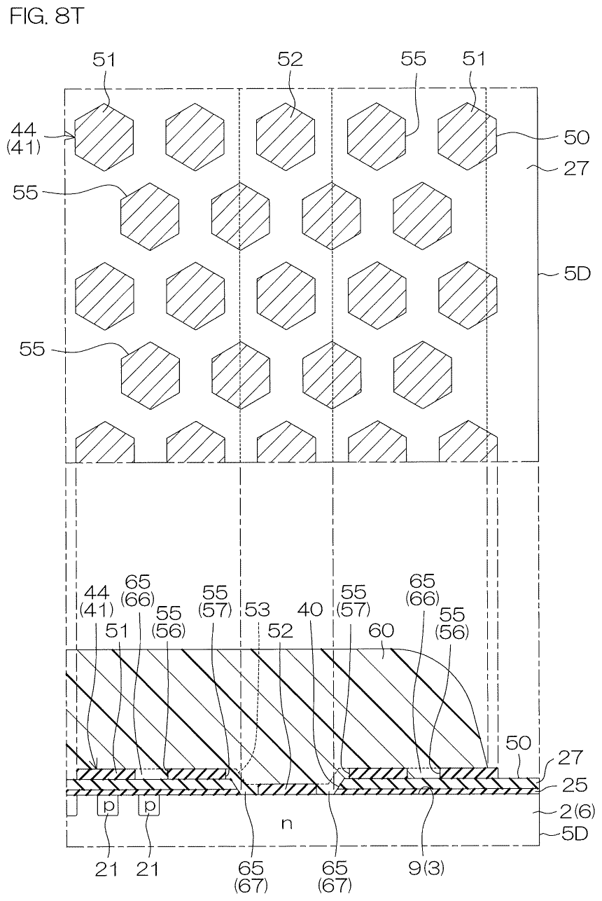

The semiconductor device 1A may include a layout that combines at least two of the plurality of layouts of the through holes 55 described above. With reference to FIG. 8A to FIG. 8T, first to twentieth layout examples having features extracted from the layout of the through holes 55 described above are illustrated below.

FIG. 8A to FIG. 8T are schematic diagrams illustrating first to twentieth layout examples of the through hole 55. The first to twentieth layout examples are all illustrative examples of the layout of the through holes 55, and the layout of the through holes 55 is not limited to the first to twentieth layout examples. The semiconductor device 1A may include a layout in which at least two of the first to twentieth layout examples are combined.

With reference to FIG. 8A (first layout example), the plurality of through holes 55 may be arranged in a matrix at intervals in the first direction X and the second direction Y in a plan view. In this case, it is preferable that the plurality of through holes 55 are formed in a matrix in a plurality of portions extending along the first to fourth side surfaces 5A to 5D of the outer covering portion 44 in a plan view, and surround the active surface 8 from a plurality of directions. In this example, each of the plurality of through holes 55 is formed in a quadrangular shape in a plan view.

As a matter of course, with reference to FIG. 8B (second layout example), the plurality of through holes 55 may each be formed in a strip shape extending along the outer covering portion 44 in a plan view. With reference to FIG. 8C (third layout example), the plurality of through holes 55 may each be formed in a circular shape in a plan view.

With reference to FIG. 8D (fourth layout example), the plurality of through holes 55 may each be formed in a polygonal shape (here, a hexagonal shape) other than a quadrangle in a plan view. With reference to FIG. 8E (fifth layout example), the plurality of through holes 55 may be formed in a ring shape that does not surround the active surface 8 on the sides of the active surface 8 in a plan view.

Also, with reference to FIG. 8F (sixth layout example), the plurality of through holes 55 may include at least one (in this example, a plurality of) first through holes 55A extending in the first direction X in a plan view and at least one (in this example, a plurality of) second through holes 55B extending in the second direction Y. The plurality of first through holes 55A and the plurality of second through holes 55B may be arranged at intervals in the first direction X and the second direction Y in any layout.

The plurality of first through holes 55A may be arranged in a line in the first direction X and face each other in the first direction X. The plurality of first through holes 55A may be arranged in a line in the second direction Y and face each other in the second direction Y. The plurality of second through holes 55B may be arranged in a line in the first direction X and face each other in the first direction X. The plurality of second through holes 55B may be arranged in a line in the second direction Y and face each other in the second direction Y.

As a matter of course, the plurality of first through holes 55A and the plurality of second through holes 55B may be arranged alternately in the first direction X and face each other in the first direction X. Also, the plurality of first through holes 55A and the plurality of second through holes 55B may be arranged alternately in the second direction Y and face each other in the second direction Y.

Also, with reference to FIG. 8G (seventh layout example), the plurality of through holes 55 may each have a portion (side) extending in the first direction X and a portion (side) extending in the second direction Y in a plan view. In this example, each through hole 55 is formed in a cross shape in a plan view. As a matter of course, each through hole 55 may be formed in a C-shape, an L-shape, or a T-shape in a plan view.

With reference to FIG. 8H (eighth layout example), the plurality of through holes 55 may each extend in a direction intersecting the first direction X and the second direction Y in a plan view. For example, the plurality of through holes 55 may include the plurality of first through holes 55A extending in a first intersecting direction and the plurality of second through holes 55B extending in a second intersecting direction. The first intersecting direction is a direction intersecting the first direction X and the second direction Y (the same applies below). The second intersecting direction is a direction intersecting the first direction X, the second direction Y, and the first intersecting direction (the same applies below).

The first intersecting direction is a direction that extends at an inclination angle of 0°<θ<90° when the coordinate axes of the first direction X and the second direction Y are set. The first intersecting direction preferably extends at an inclination angle of 30°<θ<60° (more preferably at an inclination angle of) 45°±5°. On the other hand, the second intersecting direction is a direction extending at an inclination angle of 90°<θ<180°. The second intersecting direction preferably extends at an inclination angle of 120°<θ<150° (more preferably at an inclination angle of) 135°±5°. It is particularly preferable that the second intersecting direction is a direction perpendicular to the first intersecting direction.

The plurality of first through holes 55B may be arranged in a line in the first direction X and face each other in the first direction X. The plurality of first through holes 55A may be arranged in a line in the second direction Y and face each other in the second direction Y. The plurality of second through holes 55B may be arranged in a line in the first direction X and face each other in the first direction X. The plurality of second through holes 55B may be arranged in a line in the second direction Y and face each other in the second direction Y.

As a matter of course, the plurality of first through holes 55A and the plurality of second through holes 55B may be arranged alternately in the first direction X and face each other in the first direction X. Also, the plurality of first through holes 55A and the plurality of second through holes 55B may be arranged alternately in the second direction Y and face each other in the second direction Y. As a matter of course, the plurality of through holes 55 may be configured by only the plurality of first through holes 55A or the plurality of second through holes 55B.

With reference to FIG. 8I (ninth layout example), each of the plurality of through holes 55 may have a portion extending in a first intersecting direction and a portion extending in a second intersecting direction in a plan view. In this example, each through hole 55 is formed in a cross shape intersecting the first direction X and the second direction Y in a plan view. As a matter of course, each through hole 55 may be formed in a C-shape, an L-shape, or a T-shape intersecting the first direction X and the second direction Y in a plan view.

FIG. 8A to FIG. 8I described above illustrate an example in which a plurality of through holes 55 are arranged in a matrix in a plan view. However, with reference to FIG. 8J (tenth layout example), the plurality of through holes 55 may be arranged in a staggered manner in the first direction X and the second direction Y at intervals.

That is, in this example, the semiconductor device 1A includes a plurality of groups each including the plurality of through holes 55 arranged in a line in the second direction Y and being spaced apart in the first direction X. The plurality of through holes 55 belonging to one group are arranged so as to be shifted in the second direction Y with respect to the plurality of through holes 55 belonging to the other group. The plurality of through holes 55 belonging to one group face, in the first direction X, a region between the plurality of through holes 55 belonging to the other group.

As a matter of course, the semiconductor device 1A may include a plurality of groups each including the plurality of through holes 55 arranged in a line in the first direction X and being spaced apart in the second direction Y. In this case, the plurality of through holes 55 belonging to one group are arranged so as to be shifted in the first direction X with respect to the plurality of through holes 55 belonging to the adjacent group.

With reference to FIG. 8K (eleventh layout example), the plurality of through holes 55 may be arranged at intervals from the active surface 8 to the peripheral end side of the outer surface 9 in a plan view, and may be formed in a stripe shape extending along the outer covering portion 44. In this case, the plurality of through holes 55 may be formed in an endless or ended state surrounding the active surface 8 from a plurality of directions (for example, four directions).

With reference to FIG. 8L (twelfth layout example), similar to the eleventh layout example, the plurality of through holes 55 are formed in a stripe pattern extending along the outer covering portion 44 in a plan view. In this example, the plurality of through holes 55 are formed in a zigzag shape in a plan view, each having a portion extending in a first intersecting direction and a portion extending in a second intersecting direction.

With reference to FIG. 8M (thirteenth layout example), similar to the eleventh layout example, the plurality of through holes 55 are formed in a stripe pattern extending along the outer covering portion 44 in a plan view. In this example, the plurality of through holes 55 are formed in a stripe pattern extending in a direction intersecting the extension direction of the outer covering portion 44. The plurality of through holes 55 may extend in a first intersecting direction or a second intersecting direction. As a matter of course, the plurality of through holes 55 extending in a stripe pattern in the first intersecting direction and the plurality of through holes 55 extending in a stripe pattern in the second intersecting direction may be formed.

With reference to FIG. 8N (fourteenth layout example), the plurality of through holes 55 may be arranged at intervals in the extension direction of the outer covering portion 44 in a plan view, and may be formed in a stripe pattern extending in a direction intersecting the extension direction of the outer covering portion 44. In this example, the plurality of through holes 55 are perpendicular to the extension direction of the outer covering portion 44 (that is, the first direction X or the second direction Y).

With reference to FIG. 8O (fifteenth layout example), similar to the fourteenth layout example, the plurality of through holes 55 are formed in a stripe pattern extending in a direction intersecting the extension direction of the outer covering portion 44 in a plan view. In this example, the plurality of through holes 55 are formed in a zigzag shape, each having a portion extending in a first intersecting direction and a portion extending in a second intersecting direction.

With reference to FIG. 8P (sixteenth layout example), the single through hole 55 extending in a zigzag pattern along the extension direction of the outer covering portion 44 may be formed. The single through hole 55 is configured by the plurality of first through holes 55A and the plurality of second through holes 55B that are connected in a zigzag pattern.

The plurality of first through holes 55A are arranged at intervals in the extension direction of the outer covering portion 44 and are each formed in a strip shape extending in a direction intersecting (specifically, perpendicular to) the extension direction of the outer covering portion 44. The plurality of second through holes 55B each extend in the extension direction of the outer covering portion 44, and alternately connect one ends of a pair of first through holes 55A and the other ends of a pair of first through holes 55A along the extension direction of the outer covering portion 44.

With reference to FIG. 8Q (seventeenth layout example), the single through hole 55 in a mesh (lattice) shape extending in the first direction X and the second direction Y may be formed. The single through hole 55 includes the plurality of first through holes 55A and the plurality of second through holes 55B that are connected in a lattice pattern. The plurality of first through holes 55A are formed in a stripe pattern extending in the first direction X. The plurality of second through holes 55B are formed in a stripe pattern extending in the second direction Y so as to be connected to the plurality of first through holes 55A.

As a matter of course, with reference to FIG. 8R (eighteenth layout example), the single through hole 55 may be formed in a mesh (lattice) shape extending in a direction intersecting the first direction X and the second direction Y. The single through hole 55 includes the plurality of first through holes 55A and the plurality of second through holes 55B that are connected in a lattice pattern. The plurality of first through holes 55A are formed in a stripe pattern extending in the first intersecting direction. The plurality of second through holes 55B are formed in a stripe pattern extending in the second intersecting direction so as to be connected to the plurality of first through holes 55A.

With reference to FIG. 8S (nineteenth layout example), the plurality of through holes 55 each having a hexagonal shape in a plan view may be arranged in a honeycomb pattern. The honeycomb arrangement is also an example of a staggered arrangement. In this case, a portion extending in a hexagonal mesh pattern (hexagonal lattice pattern) in a plan view is formed in the outer covering portion 44. As a matter of course, with reference to FIG. 8T (twentieth layout example), the single through hole 55 extending in a hexagonal mesh pattern (hexagonal lattice pattern) in a plan view may be formed. In this case, a plurality of hexagonal portions arranged in a honeycomb pattern in a plan view are formed in the outer covering portion 44.

With reference to FIG. 8A to FIG. 8T, in the first to twentieth layout examples, the single or the plurality of through holes 55 are formed in a plan view. The single or the plurality of through holes 55 according to the first to twenty-first layout examples each include the first-type through hole 56 and the second-type through hole 57 in a cross-sectional view.

When the single through hole 55 is formed, the first-type through hole 56 is formed of a portion of the single through hole 55, and the second-type through hole 57 is formed of a portion of the single through hole 55. On the other hand, when the plurality of through holes 55 are formed, the first-type through hole 56 is formed of one through hole 55, and the second-type through hole 57 is formed of one through hole 55.

In the above description of the through hole 55, the first direction X may be the a-axis direction of the SiC single crystal, and the second direction Y may be the m-axis direction of the SiC single crystal. As a matter of course, in the above description of the through hole 55, the first direction X may be the m-axis direction of the SiC single crystal, and the second direction Y may be the a-axis direction of the SiC single crystal. The layout of the single or the plurality of through holes 55 may be determined in view of the stress generated along the crystallographic directions of the SiC single crystal. That is, by adjusting the layout of the single or the plurality of through holes 55, it is possible to suppress bias in the stress in a specific direction (crystal direction).

The semiconductor device 1A includes an organic film 60 that covers the second inorganic film 41. The organic film 60 may be called an “organic insulating film” or a “resin film.” The organic film 60 preferably contains a resin other than a thermosetting resin. The organic film 60 may be formed of a light-transmitting resin or a transparent resin. The organic film 60 is preferably made of a negative or positive type photosensitive resin film. The organic film 60 preferably includes at least one of a polyimide film, a polyamide film, and a polybenzoxazole film. In this s embodiment, the organic film 60 includes a polybenzoxazole film.

The organic film 60 preferably has a thickness less than the thickness of the chip 2. The thickness of the organic film 60 preferably exceeds the thickness of the first inorganic film 27. The thickness of the organic film 60 preferably exceeds the thickness of the second inorganic film 41. It is particularly preferable that the thickness of the organic film 60 exceeds the thickness of the gate electrode 30 (source electrode 32). The thickness of the organic film 60 may be 3 μm or more and 30 μm or less. The thickness of the organic film 60 is preferably 20 μm or less.

The organic film 60 is embedded in the first exposed portion 47, the second exposed portion 48, and the third exposed portion 49 of the second inorganic film 41, and covers the gate covering portion 42, the source covering portion 43, and the outer covering portion 44 of the second inorganic film 41. The organic film 60 covers the peripheral edge portion of the gate electrode 30, the peripheral edge portion of the source electrode 32, the plurality of gate wirings 36A, 36B, and the source wiring 37 in the first exposed portion 47, the second exposed portion 48, and the third exposed portion 49.

In this embodiment, the organic film 60 covers the electrode sidewall of the gate electrode 30, the electrode sidewall of the source electrode 32, the entire areas of the plurality of gate wirings 36A, 36B, and the entire area of the source wiring 37. The portion of the organic film 60 that covers the gate electrode 30 defines a gate pad opening 61 that exposes the inner portion of the gate electrode 30.

In this embodiment, the gate pad opening 61 is formed quadrangular shape in a plan view and communicates with the gate opening 45. The gate pad opening 61 may expose the inner edge portion of the gate covering portion 42. As a matter of course, the organic film 60 may cover the entire area of the gate covering portion 42.

The portion of the organic film 60 that covers the source electrode 32 defines a source pad opening 62 that exposes the inner portion of the source electrode 32. In this embodiment, the source pad opening 62 is formed in a polygonal shape along the peripheral edge of the source electrode 32 in a plan view, and communicates with the source opening 46. The source pad opening 62 may expose the inner edge portion of the source covering portion 43. As a matter of course, the organic film 60 may cover the entire area of the source covering portion 43.

The organic film 60 is embedded in all the through holes 55 (single or the plurality of through holes 55) on the outer surface 9 side (peripheral edge side of the first main surface 3) and covers the outer covering portion 44 of the second inorganic film 41. As a result, the organic film 60 has a single or a plurality of anchor portions 65 located in the single or the plurality of through holes 55. The single or the plurality of anchor portions 65 have a layout that matches the layout of the single or the plurality of through holes 55. The connection area of the organic film 60 to the second inorganic film 41 (outer covering portion 44) is increased by the anchor portion 65.

When the first-type through hole 56 exposing the first inorganic film 27 in a cross-sectional view is formed in the outer covering portion 44, the organic film 60 has a first-type anchor portion 66 that contacts the first inorganic film 27 and the outer covering portion 44 within the first-type through hole 56. When the second-type through hole 57 exposing the outer surface 9 (first main surface 3) in a cross-sectional view is formed in the outer covering portion 44, the organic film 60 has a second-type anchor portion 67 within the second-type through hole 57 that contacts the outer surface 9 (first main surface 3) and the outer covering portion 44.

When the second-type through hole 57 exposes the outer surface 9 (first main surface 3), the wall portion of the base through hole 40, and the first inorganic film 27, the second-type anchor portion 67 contacts the outer surface 9 (first main surface 3), the wall portion of the base through hole 40, the first inorganic film 27, and the outer covering portion 44 within the second-type through hole 57. When the second-type through hole 57 exposes the inner wall portion of the base through hole 40, the outer surface 9 (first main surface 3) and an outer wall portion of the base through hole 40, the second-type anchor portion 67 contacts the inner wall portion of the base through hole 40, the outer surface 9 (first main surface 3) and the outer wall portion of the base through hole 40. The second-type anchor portion 67 is connected to the outer surface 9 inside the base through hole 40 and simultaneously engages with a stepped portion between the outer surface 9 (first main surface 3) and the first inorganic film 27.

In this embodiment, the organic film 60 covers the first portion 51 and the second portion 52 of the outer covering portion 44, and also covers the recessed portion 53 defined by the first portion 51 and the second portion 52. That is, the organic film 60 enters the first-type through hole 56 from above the first portion 51 and covers the first inorganic film 27 inside the first-type through hole 56. The organic film 60 enters from above the first portion 51 into the recessed portion 53 and covers the second portion 52 within the recessed portion 53.

The organic film 60 enters into the base through hole 40 (second-type through hole 57) from above the second portion 52 within the recessed portion 53, and covers the outer surface 9 and the first inorganic film 27 within the base through hole 40 (second-type through hole 57). The connection area of the organic film 60 to the second inorganic film 41 (outer covering portion 44) is also increased by the recessed portion 53. In this embodiment, the connection area is increased by a step structure formed by the base through hole 40, the recessed portion 53, and the second-type through hole 57.

The outer edge portion of the organic film 60 is formed at an interval inward from the peripheral edge of the outer surface 9, and defines the dicing street 50 between the outer edge portion and the peripheral edge of the outer surface 9. In this embodiment, the outer edge portion of the organic film 60 exposes the outer edge portion of the second inorganic film 41. That is, the organic film 60 defines the dicing street 50 together with the second inorganic film 41. As a matter of course, the organic film 60 may cover the entire outer edge portion of the second inorganic film 41.

The semiconductor device 1A includes a drain electrode 68 (third main surface electrode) covering the second main surface 4. The drain electrode 68 is electrically connected to the second main surface 4. The drain electrode 68 forms an ohmic contact with the second semiconductor region 7 exposed from the second main surface 4. The drain electrode 68 may cover the entire second main surface 4 so as to be continuous with the peripheral edge of the chip 2 (first to fourth side surfaces 5A to 5D).

The drain electrode 68 may cover the second main surface 4 at an interval inward from the peripheral edge of the chip 2. The drain electrode 68 is configured so that a drain-source voltage of 500 V or more and 3000 V or less is applied between the drain electrode 68 and the source electrode 32. That is, the chip 2 is formed so that a voltage of 500 V or more and 3000 V or less is applied between the first main surface 3 and the second main surface 4.

As described above, the semiconductor device 1A includes the chip 2, the second inorganic film 41 (inorganic film), the through hole 55, and the organic film 60. The chip 2 includes the first main surface 3. The second inorganic film 41 includes an insulator and covers the first main surface 3. The through hole 55 is formed in the second inorganic film 41. The organic film 60 is embedded in the through holes 55 and covers the second inorganic film 41.

According to this structure, an adhesion region having an unevenness due to the through holes 55 is formed between the second inorganic film 41 and the organic film 60. This can improve the connection strength of the organic film 60 to the second inorganic film 41. As a result, even if stress occurs in the second inorganic film 41 or the organic film 60, peeling of the organic film 60 from the second inorganic film 41 can be suppressed.

Also, the uneven adhesion region can extend the intrusion path of moisture (water). As a result, it is possible to suppress the intrusion of moisture starting from the region between the second inorganic film 41 and the organic film 60, and therefore it is possible to suppress deterioration (including corrosion) caused by moisture. Therefore, it is possible to provide the semiconductor device 1A with improved reliability.

The through hole 55 preferably exposes the first main surface 3. According to this structure, it is possible to form the organic film 60 having a portion in contact with the first main surface 3 inside the through hole 55 and a portion in contact with the second inorganic film 41 outside the through hole 55.

Therefore, by utilizing the through holes 55 that expose the first main surface 3, the connection strength of the organic film 60 to the second inorganic film 41 can be improved and at the same time, the intrusion path of moisture can be extended. The second inorganic film 41 preferably includes a silicon nitride film (nitride film). This structure can provide an effect of improving the connection strength between the silicon nitride film and the organic film 60 and an effect of preventing the intrusion of moisture.

From another perspective, the semiconductor device 1A includes the chip 2, the first inorganic film 27, the second inorganic film 41, at least one through hole 55, and the organic film 60. The chip 2 includes the first main surface 3. The first inorganic film 27 includes an insulator and covers the first main surface 3. The second inorganic film 41 includes an insulator and covers the first inorganic film 27. The through hole 55 is formed in the second inorganic film 41. The organic film 60 is embedded in the through holes 55 and covers the second inorganic film 41.

According to this structure, an adhesion region having an unevenness due to the through holes 55 is formed between the second inorganic film 41 and the organic film 60. This can improve the connection strength of the organic film 60 to the second inorganic film 41. As a result, even if stress occurs in the second inorganic film 41 or the organic film 60, peeling of the organic film 60 from the second inorganic film 41 can be suppressed.

The uneven adhesion region also provides an extended intrusion path of moisture. As a result, it is possible to suppress the intrusion of moisture starting from the region between the second inorganic film 41 and the organic film 60, and therefore it is possible to suppress deterioration caused by moisture. Therefore, it is possible to provide the semiconductor device 1A with improved reliability.

At least one of the through holes 55 preferably includes the first-type through hole 56 that exposes the first inorganic film 27 in a cross-sectional view. According to this structure, it is possible to form the organic film 60 having a portion in contact with the first inorganic film 27 inside the first-type through hole 56 and a portion in contact with the second inorganic film 41 outside the first-type through hole 56. Therefore, the first-type through hole 56 can be used to improve the connection strength of the organic film 60 to the second inorganic film 41 and at the same time, the intrusion path of moisture can be extended.

At least one of the through holes 55 preferably includes the second-type through hole 57 that exposes the first main surface 3 in a cross-sectional view. According to this structure, it is possible to form the organic film 60 having a portion in contact with the first main surface 3 inside the second-type through hole 57 and a portion in contact with the second inorganic film 41 outside the second-type through hole 57. Therefore, the connection strength of the organic film 60 to the second inorganic film 41 can be improved by utilizing the second-type through hole 57, and at the same time, the intrusion path of moisture can be extended.

The second-type through hole 57 may expose the first main surface 3 and the first inorganic film 27 in a cross-sectional view. With this structure, it is possible to form the organic film 60 having a portion in contact with the first main surface 3 and the first inorganic film 27 inside the second-type through hole 57, and a portion in contact with the second inorganic film 41 outside the second-type through hole 57. Therefore, the connection strength of the organic film 60 to the second inorganic film 41 can be improved by utilizing the second-type through hole 57, and at the same time, the intrusion path of moisture can be extended.

The first inorganic film 27 preferably includes the base through hole 40 through which the first main surface 3 is exposed. In this case, it is preferable that the second inorganic film 41 includes the first portion 51 that covers the first inorganic film 27 outside the base through hole 40, and the second portion 52 that covers the first main surface 3 inside the base through hole 40. The organic film 60 preferably has a portion covering the first portion 51 and a portion covering the second portion 52.

According to this structure, an adhesion region having an unevenness due to the base through holes 40 is formed between the first main surface 3 and the second inorganic film 41 via the first inorganic film 27. This can improve the connection strength of the second inorganic film 41 to the first inorganic film 27 (first main surface 3). As a result, even if stress occurs in the second inorganic film 41 or the like, peeling of the second inorganic film 41 from the first inorganic film 27 can be suppressed. The uneven adhesion region also provides an extended intrusion path of moisture. As a result, it is possible to suppress the intrusion of moisture starting from the region between the first inorganic film 27 and the second inorganic film 41, and therefore it is possible to suppress deterioration (including corrosion) caused by moisture.

It is preferable that the second portion 52 has a front surface located on the first main surface 3 side with respect to the height position of the front surface of the first portion 51, and defines the recessed portion 53 (stepped portion) between the second portion 52 and the first portion 51. According to this structure, an adhesion region having an unevenness due to the recessed portion 53 and the through hole 55 is formed between the second inorganic film 41 and the organic film 60. This makes it possible to improve the connection strength of the organic film 60 to the second inorganic film 41 by utilizing the recessed portion 53 and the through hole 55, and at the same time, to extend the intrusion path of moisture. The second inorganic film 41 preferably has a thickness less than half the width of the base through hole 40.

At least one of the through holes 55 preferably includes the second-type through hole 57 that exposes the wall portion of the base through hole 40 in a cross-sectional view. According to this structure, it is possible to form the organic film 60 having a portion in contact with the wall portion of the base through hole 40 inside the second-type through hole 57 and a portion in contact with the second inorganic film 41 outside the second-type through hole 57. Therefore, by utilizing the second-type through hole 57 that exposes the wall portion of the base through hole 40, the connection strength of the organic film 60 to the second inorganic film 41 can be improved and at the same time, the intrusion path of moisture can be extended.

The semiconductor device 1A may include the plurality of through holes 55. According to this structure, then organic film 60 having a plurality of portions located within the plurality of through holes 55 can be formed. Therefore, the connection strength of the organic film 60 to the second inorganic film 41 can be improved by using the plurality of through holes 55, and at the same time, the intrusion path of moisture can be extended.

The plurality of through holes 55 may be formed in a stripe pattern in a plan view. According to this structure, the organic film 60 having portions that mesh with the second inorganic film 41 in a striped pattern via the plurality of through holes 55 can be formed. The plurality of through holes 55 may be arranged in a matrix or staggered pattern at intervals in the first direction X and the second direction Y. According to this structure, it is possible to form the organic film 60 having portions that mesh with the second inorganic film 41 in a matrix or staggered pattern via the plurality of through holes 55.

The semiconductor device 1A may include the through hole 55 having a portion extending in the first direction X and a portion extending in the second direction Y. According to this structure, the organic film 60 having a portion extending in the first direction X and a portion extending in the second direction Y within the through hole 55 can be formed. The semiconductor device 1A may include the through hole 55 extending in the first direction X and the through hole 55 extending in the second direction Y. With this structure, it is possible to form the organic film 60 having a portion extending in the first direction X within the through hole 55 extending in the first direction X, and a portion extending in the second direction Y within the through hole 55 extending in the second direction Y.

The semiconductor device 1A may include the through hole 55 extending in a direction intersecting the first direction X and the second direction Y. According to this structure, the organic film 60 having a portion extending in a direction intersecting the first direction X and the second direction Y within the through hole 55 can be formed.

The first direction X and the second direction Y may be defined by the extending directions of the first to fourth side surfaces 5A to 5D of the chip 2. The first direction X and the second direction Y may be defined by a crystallographic direction of the SiC single crystal. For example, the first direction X may be the a-axis direction of the SiC single crystal, and the second direction Y may be the m-axis direction of the SiC single crystal. As a matter of course, the first direction X may be the m-axis direction of the SiC single crystal, and the second direction Y may be the a-axis direction of the SiC single crystal.

The semiconductor device 1A may include a gate electrode 30 (first main surface electrode) arranged in the inner portion of the first main surface 3. In this case, it is preferable that at least one through hole 55 is formed around the gate electrode 30. This structure can improve the connection strength of the organic film 60 to the second inorganic film 41 around the gate electrode 30 and at the same time, the intrusion path of moisture can be extended. This makes it possible to protect the gate electrode 30 from external forces and moisture.

In this case, the second inorganic film 41 preferably has a gate covering portion 42 that partially covers the gate electrode 30. Also, the organic film 60 preferably has a portion that covers the gate electrode 30 with the gate covering portion 42 of the second inorganic film 41 sandwiched therebetween. This structure allows the gate electrode 30 to be adequately protected.

The gate covering portion 42 may expose the peripheral edge portion (electrode sidewall) of the gate electrode 30. This structure makes it possible to suppress peeling of the second inorganic film 41 caused by stress generated in the peripheral edge portion of the gate electrode 30. In this structure, the organic film 60 preferably covers the peripheral edge portion of the gate electrode 30.

The organic film 60 has physical properties that are softer than the second inorganic film 41. That is, the elastic modulus of the organic film 60 is smaller than the elastic modulus of the second inorganic film 41. Therefore, even if the organic film 60 covers the gate electrode 30, peeling of the organic film 60 due to stress generated in the gate electrode 30 is suppressed. This allows the gate electrode 30 to be appropriately protected by the organic film 60. The gate electrode 30 may cover an area of 25% or less of the first main surface 3 in a plan view.

The semiconductor device 1A may include the source electrode 32 (second main surface electrode) arranged in the inner portion of the first main surface 3. In this case, it is preferable that at least one through hole 55 is formed around the source electrode 32. This structure can improve the connection strength of the organic film 60 to the second inorganic film 41 around the source electrode 32 and at the same time, the intrusion path of moisture can be extended. This makes it possible to protect the source electrode 32 from external forces and moisture.

In this case, the second inorganic film 41 preferably has the source covering portion 43 that partially covers the source electrode 32. The organic film 60 preferably has a portion that covers the source electrode 32 with the source covering portion 43 of the second inorganic film 41 sandwiched therebetween. According to this structure, the source electrode 32 can be appropriately protected.

The source covering portion 43 may expose the peripheral edge portion (electrode sidewall) of the source electrode 32. This structure makes it possible to suppress peeling of the second inorganic film 41 caused by stress generated in the peripheral edge portion of the source electrode 32. In this structure, the organic film 60 preferably covers the peripheral edge portion of the source electrode 32. According to this structure, the organic film 60 can adequately protect the source electrode 32. The source electrode 32 may cover 50% or more of the area of the first main surface 3 in a plan view.

The second inorganic film 41 preferably includes the outer covering portion 44 that covers the first inorganic film 27 at the peripheral edge portion of the first main surface 3. In this case, the through holes 55 are preferably formed in the outer covering portion 44 of the second inorganic film 41. The organic film 60 preferably covers the gate covering portion 42, the source covering portion 43, and the outer covering portion 44 of the second inorganic film 41. The outer covering portion 44 does not preferably cover a metal. This structure can reliably prevent the outer covering portion 44 from peeling off due to stress generated in the metal.

The gate electrode 30 (source electrode 32) is preferably thicker than the first inorganic film 27. The second inorganic film 41 is preferably thinner than the gate electrode 30 (source electrode 32). The organic film 60 is preferably thinner than the chip 2. The organic film 60 is preferably thicker than the second inorganic film 41. The organic film 60 is preferably thicker than the gate electrode 30 (source electrode 32).

One or more through holes 55 are preferably formed in the second inorganic film 41 so as to surround the gate electrode 30 and the source electrode 32 in a plan view. That is, it is preferable that the one or more through holes 55 are formed in the second inorganic film 41 so as to surround the inner portion of the first main surface 3 in a plan view.

The semiconductor device 1A may include the mesa portion 11 defined in the first main surface 3. The mesa portion 11 is defined in the first main surface 3 by the active surface 8 (first surface portion) formed in the inner portion of the first main surface 3, the outer surface 9 (second surface portion) formed in the peripheral edge portion of the first main surface 3 so as to be recessed from the active surface 8 in the thickness direction of the chip 2, and the first to fourth connecting surfaces 10A to 10D (connecting surface portions) connecting the active surface 8 and the outer surface 9.

In this case, the first inorganic film 27 includes a portion covering the outer surface 9. The second inorganic film 41 includes a portion covering the first inorganic film 27 on the outer surface 9 side. The through hole 55 includes a portion covering the second inorganic film 41 on the outer surface 9 side. The organic film 60 is embedded in the through holes 55 on the outer surface 9 side and covers the second inorganic film 41. According to this structure, the connection strength of the organic film 60 to the second inorganic film 41 can be improved at the outer surface 9 recessed in the thickness direction from the active surface 8, and at the same time, the intrusion path of moisture can be extended.

The semiconductor device 1A may include the sidewall structure 26 that covers at least one of the first to fourth connecting surfaces 10A to 10D. In this case, the first inorganic film 27 may cover the sidewall structure 26. On the other hand, the second inorganic film 41 (outer covering portion 44) is preferably formed at an interval from the sidewall structure 26. The organic film 60 may cover the sidewall structure 26 with the first inorganic film 27 sandwiched therebetween.

The second inorganic film 41 preferably contains an insulator different from that of the first inorganic film 27. The first inorganic film 27 preferably includes an oxide film. The second inorganic film 41 preferably includes a nitride film. The organic film 60 preferably includes a photosensitive resin film.

The chip 2 preferably includes a single crystal of a wide bandgap semiconductor. The single crystal of the wide bandgap semiconductor is effective in improving electrical characteristics. Also, the wide bandgap semiconductor single crystal has a relatively high hardness that suppresses deformation of the chip 2, while allowing the chip 2 to be thinned and have an increased planar area. Reducing the thickness of the chip 2 and increasing the planar area of the chip 2 are also effective in improving electrical characteristics.

For example, the chip 2 may include the first main surface 3 having an area of 1 mm square or more in a plan view. The chip 2 may have a thickness of 200 μm or less. The chip 2 preferably has a thickness of 150 μm or less in a cross-sectional view. The relatively thin chip 2 having a thickness of 200 μm or less is easily deformed by stress. In this regard, the structure of the semiconductor device 1A can suppress peeling of the organic film 60 from the second inorganic film 41 even when the chip 2 is deformed due to stress.

The semiconductor device 1A preferably includes the drain electrode 68 (third main surface electrode) covering the second main surface 4 of the chip 2. The drain electrode 68 forms a potential difference (for example, 500 V or more and 3000 V or less) between the drain electrode 68 and the source electrode 32 via the chip 2.

In the case of a relatively thin chip 2, the distance between the source electrode 32 and the drain electrode 68 is reduced, increasing the risk of discharge phenomena between the peripheral edge of the first main surface 3 and the source electrode 32. In this regard, according to the second inorganic film 41 including the through holes 55, the distance between the source electrode 32 and the drain electrode 68 can be increased by the through holes 55. Therefore, the insulation between the source electrode 32 and the drain electrode 68 can be improved, and the discharge phenomenon can be suppressed.

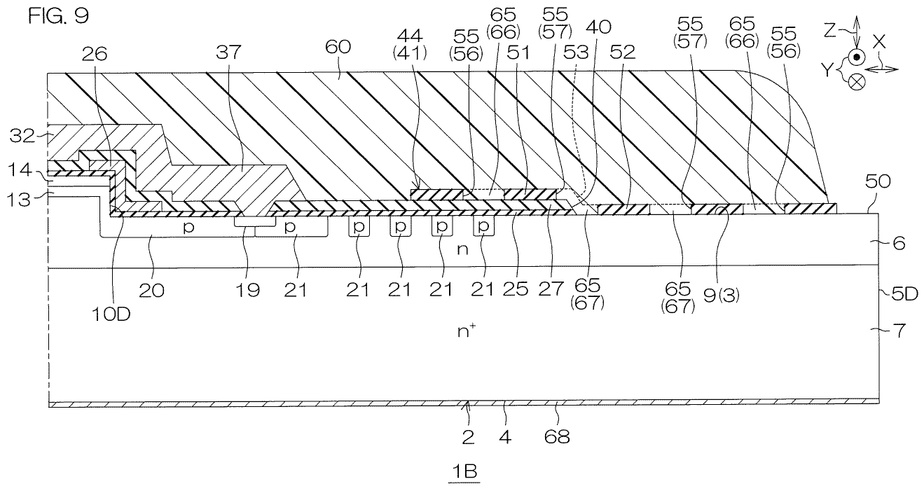

FIG. 9 corresponds to FIG. 7 and illustrates a semiconductor device 1B according to a second embodiment. With reference to FIG. 9, the semiconductor device 1B has a configuration obtained by modifying the semiconductor device 1A. Specifically, the semiconductor device 1B includes the base through hole 40 formed in the first inorganic film 27 so as to be continuous with the peripheral edge of the outer surface 9 (first to fourth side surfaces 5A to 5D).

As in the first embodiment, the base through holes 40 are formed closer to the peripheral edge side of the outer surface 9 than the plurality of field regions 21. Each base through hole 40 is formed in a ring shape (specifically, a quadrangular ring shape) extending along the peripheral edge of the outer surface 9 (the first to fourth side surfaces 5A to 5D), and exposes the peripheral edge portion of the outer surface 9.

In this embodiment, the outer covering portion 44 of the second inorganic film 41 is drawn out from above the first inorganic film 27 into the base through hole 40 and covers the peripheral edge portion of the outer surface 9 within the base through hole 40. That is, the second inorganic film 41 includes the first portion 51 that covers the first inorganic film 27 and the second portion 52 that covers the outer surface 9, similar to the first embodiment. The outer covering portion 44 is formed within the base through hole 40 at an interval inward from the peripheral edge of the outer surface 9 (first to fourth side surfaces 5A to 5D), and defines the dicing street 50 that exposes the peripheral edge portion of the outer surface 9.

The single or the plurality of through holes 55 may be formed in either or both of the first portion 51 of the second inorganic film 41 and the second portion 52 of the second inorganic film 41. That is, the single or the plurality of through holes 55 may have either or both of a first-type through hole 56 and a second-type through hole 57 in a cross-sectional view.

As a matter of course, the single or the plurality of through holes 55 may be formed only in the first portion 51 and may not be formed in the second portion 52. Also, the single or the plurality of through holes 55 may be formed only in the second portion 52 and may not be formed in the first portion 51. Besides, the layout of the single or the plurality of through holes 55 is similar to that of the first embodiment, and therefore a description of the layout will be omitted.

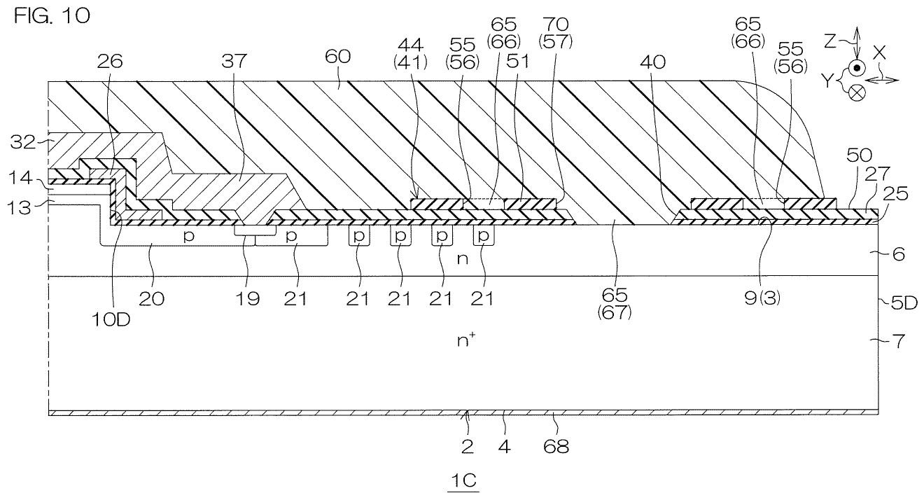

FIG. 10 corresponds to FIG. 7 and illustrates a semiconductor device 1C according to a third embodiment. With reference to FIG. 10, the semiconductor device 1C has a configuration obtained by modifying the semiconductor device 1A. Specifically, the semiconductor device 1C includes an upper through hole 70 that exposes the entire area of the base through hole 40 of the first inorganic film 27 in a plan view and cross-sectional view. The upper through hole 70 forms the second-type through hole 57 in a cross-sectional view.

The upper through hole 70 is formed by removing the second portion 52 of the outer covering portion 44 in the semiconductor device 1A. Therefore, the outer covering portion 44 includes only the first portion 51 that covers the first inorganic film 27, and does not include the second portion 52 that is located within the base through hole 40. The upper through hole 70 may be formed in a ring shape (specifically, a quadrangular ring shape) surrounding the active surface 8 in a plan view.

The semiconductor device 1C may include the single through hole 55 consisting of the upper through hole 70 (second-type through hole 57). As a matter of course, the semiconductor device 1C may include the single or the plurality of through holes 55 including the first-type through hole 56 in addition to the upper through hole 70 (second-type through hole 57). In this case, the layout of the through holes 55 other than the upper through holes 70 is determined in an arbitrary manner. For example, at least one of the plurality of layouts (for example, first to twentieth layout examples) of the through holes 55 described in the first embodiment may be applied as the layout of the through holes 55 other than the upper through holes 70.

In this embodiment, the organic film 60 enters the first-type through hole 56 from above the second inorganic film 41 and contacts the first inorganic film 27 inside the first-type through hole 56. The organic film 60 enters from above the second inorganic film 41 into the upper through hole 70 (second-type through hole 57), and within the upper through hole 70, enters from above the first inorganic film 27 into the base through hole 40. The organic film 60 is in contact with the outer surface 9 and the first inorganic film 27 within the base through hole 40. The upper through hole 70 exposing the entire area of the base through hole 40 may be applied to the semiconductor device 1B according to the second embodiment.

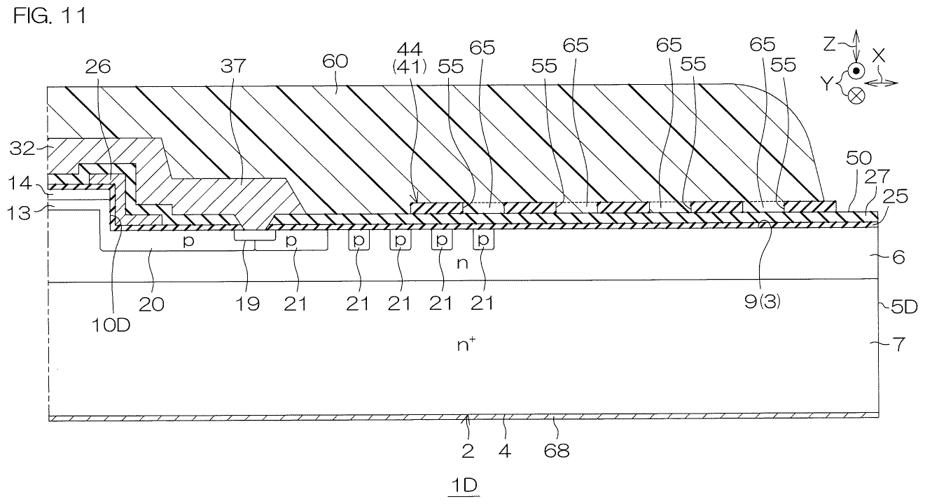

FIG. 11 corresponds to FIG. 7 and illustrates a semiconductor device 1D according to a fourth embodiment. With reference to FIG. 11, the semiconductor device 1D has a configuration obtained by modifying the semiconductor device 1A. Specifically, the semiconductor device 1D does not include the base through hole 40 in the first inorganic film 27.

The single or the plurality of through holes 55 expose only the first inorganic film 27 and do not expose the outer surface 9. Also, the single or the plurality of through holes 55 only include the first-type through hole 56 that exposes the first inorganic film 27 in a cross-sectional view, and do not include the second-type through hole 57 that exposes the outer surface 9. The layout of the single or the plurality of through holes 55 is similar to that of the first embodiment, and therefore a description of the layout will be omitted.

The organic film 60 enters into the single or the plurality of through holes 55 (first-type through holes 56) from above the second inorganic film 41. In this embodiment, the organic film 60 is in contact only with the first inorganic film 27 and the second inorganic film 41 within the single or the plurality of through holes 55, and is not in contact with the outer surface 9.

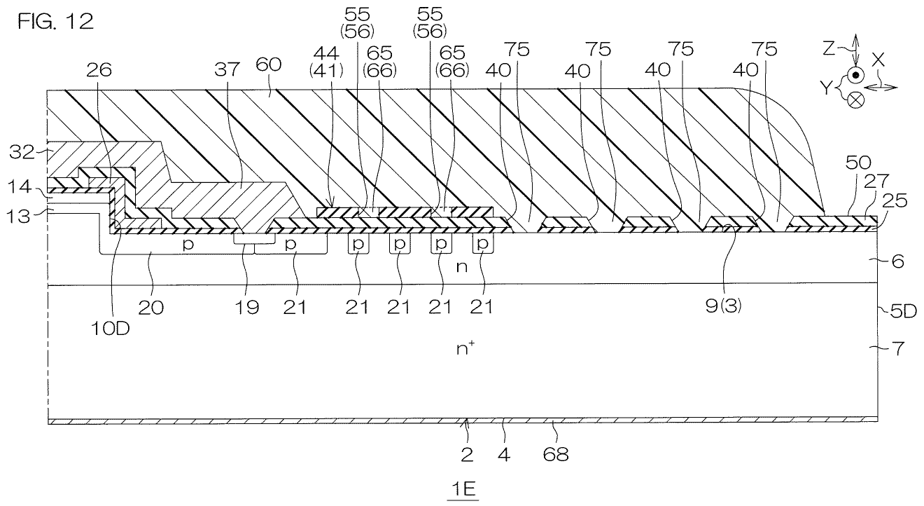

FIG. 12 corresponds to FIG. 7 and illustrates a semiconductor device 1E according to a fifth embodiment. With reference to FIG. 12, the semiconductor device 1E has a configuration obtained by modifying the semiconductor device 1A. The semiconductor device 1E includes the single or the plurality of base through holes 40, similar to the first embodiment. FIG. 12 illustrates, as an example, an example in which the plurality of base through holes 40 are formed.

In this embodiment, the outer covering portion 44 is formed at an interval from the base through hole 40 toward the active surface 8 so as to expose the base through hole 40. In this embodiment, the outer covering portion 44 is arranged in a region between the source wiring 37 and the base through holes 40, and overlaps a plurality of field regions 21 with the first inorganic film 27 interposed therebetween.

In this embodiment, the single or the plurality of through holes 55 expose only the first inorganic film 27 and do not expose the outer surface 9. That is, the single or the plurality of through holes 55 include only the first-type through holes 56 that expose the first inorganic film 27 in a cross-sectional view, and do not include the second-type through holes 57 that expose the outer surface 9. The layout of the single or the plurality of through holes 55 is similar to that of the first embodiment, and therefore a description of the layout will be omitted.

In this embodiment, the organic film 60 is embedded in all the base through holes 40 on the outer surface 9 side (peripheral edge side of the first main surface 3) and covers the first inorganic film 27. As a result, the organic film 60 includes the single or the plurality of base anchor portions 75 located in the single or the plurality of base through holes 40. The plurality of base anchor portions 75 have a layout that matches the layout of the single or the plurality of base through holes 40. The connection area of the organic film 60 to the first inorganic film 27 is increased by the base anchor portion 75.

Also, the organic film 60 is embedded in all the through holes 55 (single or the plurality of through holes 55) on the outer surface 9 side (peripheral edge side of the first main surface 3) and covers the second inorganic film 41. As a result, the organic film 60 has the single or the plurality of anchor portions 65 located in the single or the plurality of through holes 55. The single or the plurality of anchor portions 65 have a layout that matches the layout of the single or the plurality of through holes 55. The connection area of the organic film 60 to the second inorganic film 41 is increased by the anchor portions 65.

As described above, the semiconductor device 1E includes the chip 2, the first inorganic film 27 (inorganic film), the base through hole 40 (through hole 55), and the organic film 60. The chip 2 includes the first main surface 3. The first inorganic film 27 includes an insulator and covers the first main surface 3. The base through hole 40 is formed in the first inorganic film 27. The organic film 60 is embedded in the base through hole 40 and covers the first inorganic film 27.

According to this structure, an adhesion region having an unevenness due to the through holes 55 is formed between the first inorganic film 27 and the organic film 60. This can improve the connection strength of the organic film 60 to the first inorganic film 27. As a result, even if stress occurs in the first inorganic film 27 or the organic film 60, peeling of the organic film 60 from the first inorganic film 27 can be suppressed.

Also, the uneven adhesion region can extend the intrusion path of moisture (water). As a result, it is possible to suppress the intrusion of moisture starting from the region between the first inorganic film 27 and the organic film 60, and therefore it is possible to suppress deterioration (including corrosion) caused by moisture. Therefore, it is possible to provide the semiconductor device 1E with improved reliability.

It is preferable that the first main surface 3 is exposed through the base through hole 40. According to this structure, it is possible to form the organic film 60 having a portion in contact with the first main surface 3 inside the base through hole 40 and a portion in contact with the first inorganic film 27 outside the base through hole 40.

Therefore, by utilizing the base through hole 40 that exposes the first main surface 3, the connection strength of the organic film 60 to the first inorganic film 27 can be improved and at the same time, the intrusion path of moisture can be extended. The first inorganic film 27 preferably includes a silicon oxide film (oxide film). This structure can provide the effect of improving the connection strength between the silicon oxide film and the organic film 60 and the effect of preventing the intrusion of moisture.

The semiconductor device 1E may include the plurality of base through holes 40. According to this structure, the organic film 60 having a plurality of portions located within a plurality of base through holes 40 can be formed. Therefore, the connection strength of the organic film 60 to the first inorganic film 27 can be improved by using the plurality of base through holes 40, and at the same time, the intrusion path of moisture can be extended.

The plurality of base through holes 40 may be formed in a stripe pattern in a plan view. According to this structure, the organic film 60 having portions that mesh with the first inorganic film 27 in a striped pattern can be formed via the plurality of base through holes 40. The plurality of base through holes 40 may be arranged in a matrix or staggered pattern at intervals in the first direction X and the second direction Y. According to this structure, the organic film 60 having portions that mesh with the first inorganic film 27 in a matrix or staggered pattern can be formed via the plurality of base through holes 40.

The semiconductor device 1E may include the base through hole 40 having a portion extending in the first direction X and a portion extending in the second direction Y. According to this structure, the organic film 60 having a portion extending in the first direction X and a portion extending in the second direction Y in the base through hole 40 can be formed.

The semiconductor device 1E may include the base through hole 40 extending in the first direction X and the base through hole 40 extending in the second direction Y. According to this structure, it is possible to form the organic film 60 having a portion extending in the first direction X within the base through hole 40 extending in the first direction X, and a portion extending in the second direction Y within the base through hole 40 extending in the second direction Y.

The semiconductor device 1E may include the base through hole 40 extending in a direction intersecting the first direction X and the second direction Y. According to this structure, the organic film 60 having a portion extending in a direction intersecting the first direction X and the second direction Y in the base through hole 40 can be formed.

The first direction X and the second direction Y may be defined by the extending directions of the first to fourth side surfaces 5A to 5D of the chip 2. The first direction X and the second direction Y may be defined by a crystallographic direction of the SiC single crystal. For example, the first direction X may be the a-axis direction of the SiC single crystal, and the second direction Y may be the m-axis direction of the SiC single crystal. As a matter of course, the first direction X may be the m-axis direction of the SiC single crystal, and the second direction Y may be the a-axis direction of the SiC single crystal.

The semiconductor device 1E preferably includes the second inorganic film 41 arranged on the first inorganic film 27 so as to expose the base through hole 40. In this case, it is preferable that the organic film 60 covers the second inorganic film 41. According to this structure, peeling of the organic film 60 from the first inorganic film 27 can be suppressed, and therefore peeling of the organic film 60 from the second inorganic film 41 can also be suppressed. As a result, the first inorganic film 27, the second inorganic film 41, and the organic film 60 can suppress the intrusion of moisture.

The second inorganic film 41 preferably contains an insulator different from that of the first inorganic film 27. The second inorganic film 41 preferably includes a silicon nitride film (nitride film). The second inorganic film 41 may be arranged on the inner portion side of the first main surface 3 with respect to the base through hole 40 so as to expose the base through hole 40.

The semiconductor device 1E may include the through hole 55 formed in the second inorganic film 41. In this case, it is preferable that the organic film 60 is embedded in the through holes 55 and covers the second inorganic film 41. According to this structure, an adhesion region having an unevenness due to the through holes 55 is also formed between the second inorganic film 41 and the organic film 60. Therefore, by utilizing the base through hole 40 and the through hole 55, the connection strength of the organic film 60 to the first inorganic film 27 and the second inorganic film 41 can be improved, and at the same time, the intrusion path of moisture can be extended.

The through holes 55 preferably expose the first inorganic film 27. According to this structure, it is possible to form the organic film 60 having a portion in contact with the first inorganic film 27 inside the through hole 55 and a portion in contact with the second inorganic film 41 outside the through hole 55. Therefore, by utilizing the through holes 55 that expose the first inorganic film 27, the connection strength of the organic film 60 to the second inorganic film 41 can be improved, and at the same time, the intrusion path of moisture can be extended.

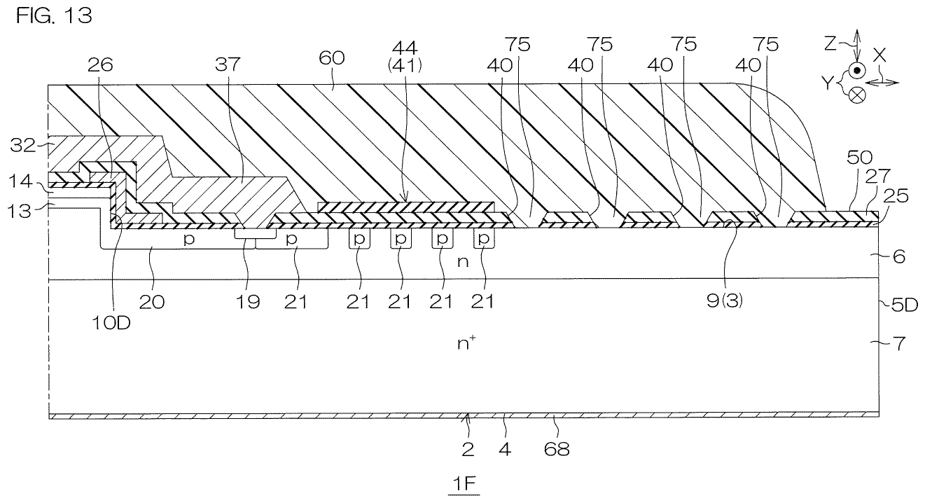

FIG. 13 corresponds to FIG. 7 and illustrates a semiconductor device 1F according to a sixth embodiment. With reference to FIG. 13, the semiconductor device 1F has a configuration obtained by modifying the semiconductor device 1E. Specifically, the semiconductor device 1F does not have a through hole 55 in the second inorganic film 41.

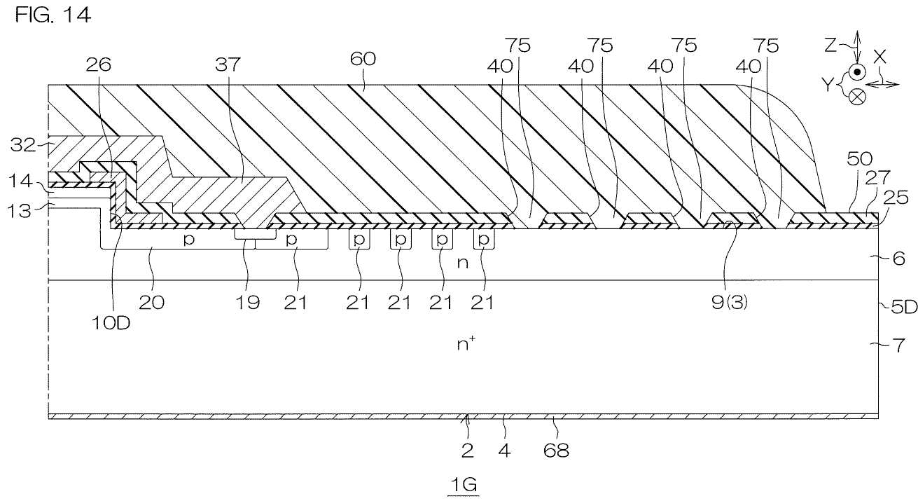

FIG. 14 corresponds to FIG. 7 and is a diagram illustrating a semiconductor device 1G according to the seventh embodiment. With reference to FIG. 14, the semiconductor device 1G has a configuration obtained by modifying the semiconductor device 1E. Specifically, the semiconductor device 1G includes the second inorganic film 41 that has the gate covering portion 42 and the source covering portion 43, but does not have the outer covering portion 44. As a matter of course, the semiconductor device 1G may not necessarily include the second inorganic film 41.

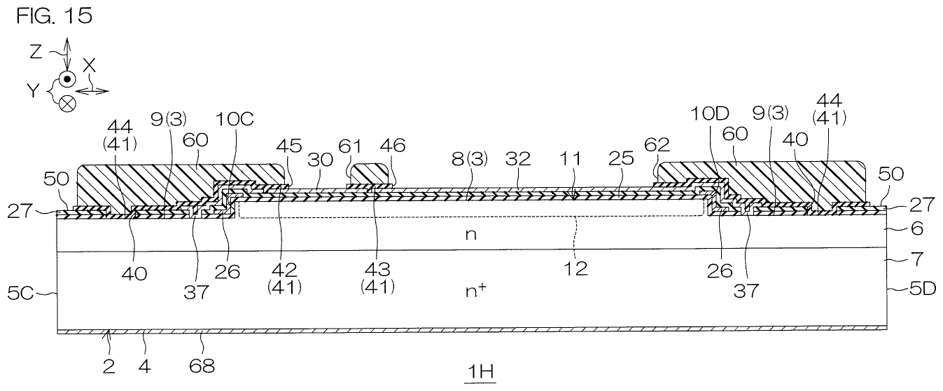

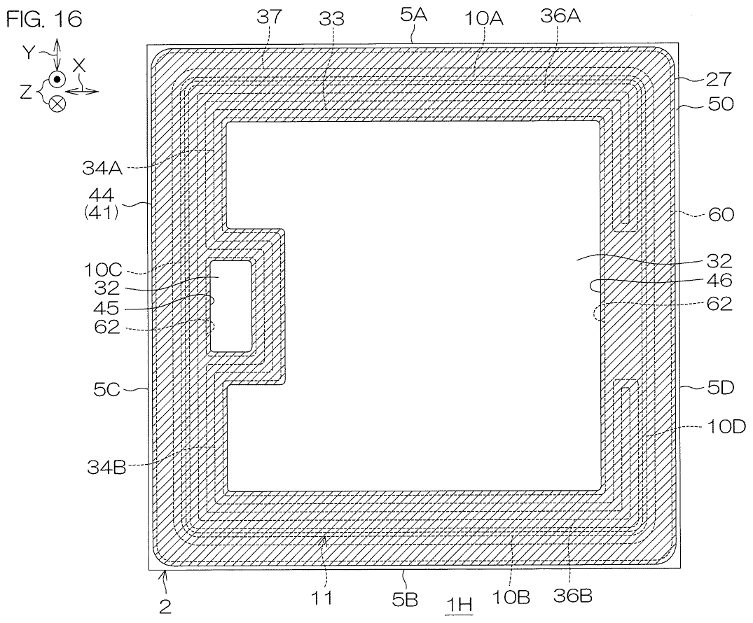

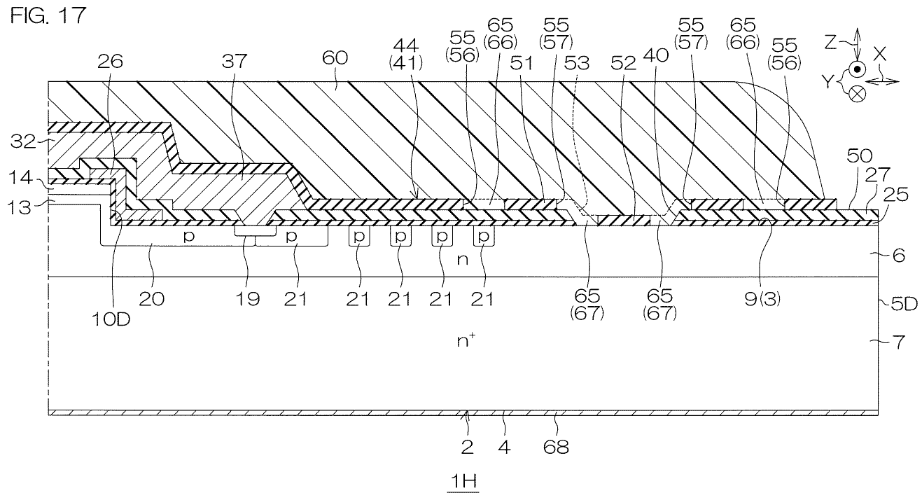

FIG. 15 corresponds to FIG. 2 and illustrates a semiconductor device 1H according to an eighth embodiment. FIG. 16 is a plan view illustrating a layout example of the second inorganic film 41 illustrated in FIG. 15. FIG. 17 is an enlarged cross-sectional view illustrating the peripheral edge portion of the chip 2 illustrated in FIG. 15. With reference to FIG. 15 to FIG. 17, the semiconductor device 1H has a configuration obtained by modifying the semiconductor device 1A. Specifically, the semiconductor device 1H includes the second inorganic film 41 integrally having the gate covering portion 42, the source covering portion 43, and the outer covering portion 44.

That is, in this embodiment, the second inorganic film 41 covers the peripheral edge portion (electrode sidewall) of the gate electrode 30, the peripheral edge portion (electrode sidewall) of the source electrode 32, the entire areas of the plurality of gate wirings 36A, 36B, and the entire area of the source wiring 37. The second inorganic film 41 includes a gate opening 45 exposing the inner portion of the gate electrode 30 and a source opening 46 exposing the inner portion of the source electrode 32, similarly to the first embodiment.

The outer covering portion 44 is a portion of the second inorganic film 41 that is located directly above the outer surface 9. More specifically, the outer covering portion 44 is a portion of the second inorganic film 41 that covers the peripheral edge of the outer surface 9 and the region between the source wirings 37. The single or the plurality of through holes 55 are formed in the outer covering portion 44, similar to the first embodiment. That is, the single or the plurality of through holes 55 are formed only in the region on the outer surface 9 side, and are not formed in the region on the active surface 8 side. The layout of the single or the plurality of through holes 55 is similar to that of the first embodiment, and therefore a description of the layout will be omitted.

In this embodiment, the organic film 60 covers the peripheral edge portion (electrode sidewall) of the gate electrode 30, the peripheral edge portion (electrode sidewall) of the source electrode 32, the entire areas of the plurality of gate wirings 36A, 36B, and the entire area of the source wiring 37, with the second inorganic film 41 sandwiched therebetween. The other structure of the organic film 60 is similar to that of the first embodiment, and therefore a description of the other structure of the organic film 60 will be omitted. The second inorganic film 41 integrally including the gate covering portion 42, the source covering portion 43, and the outer covering portion 44 may be applied to the semiconductor devices 1B to 1G according to the second to seventh embodiments.

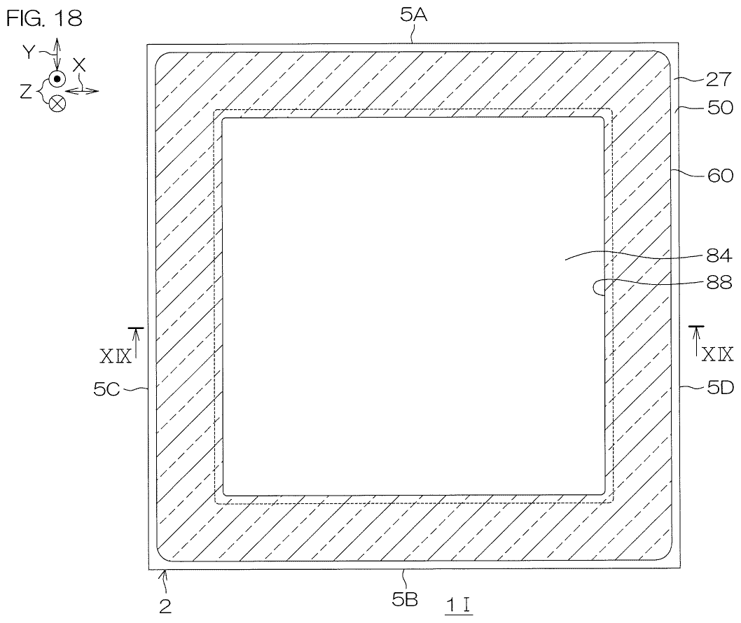

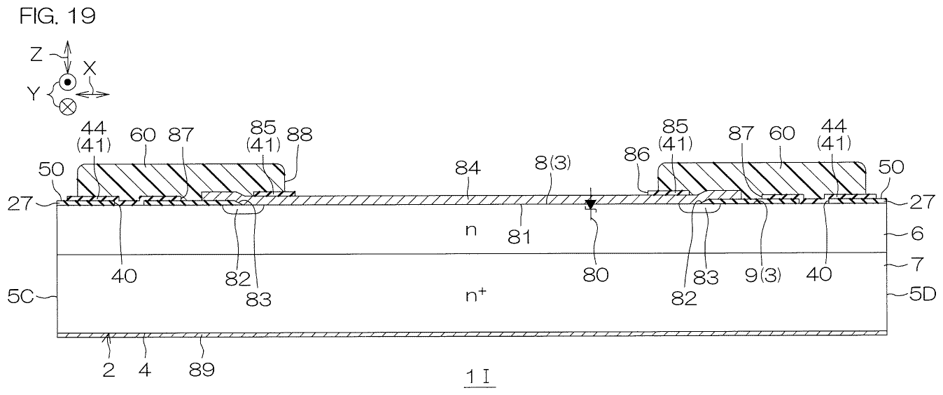

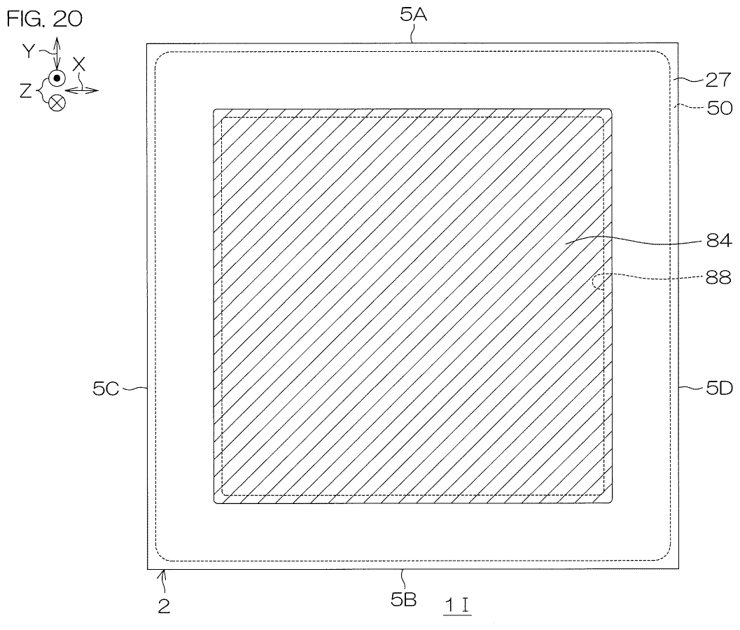

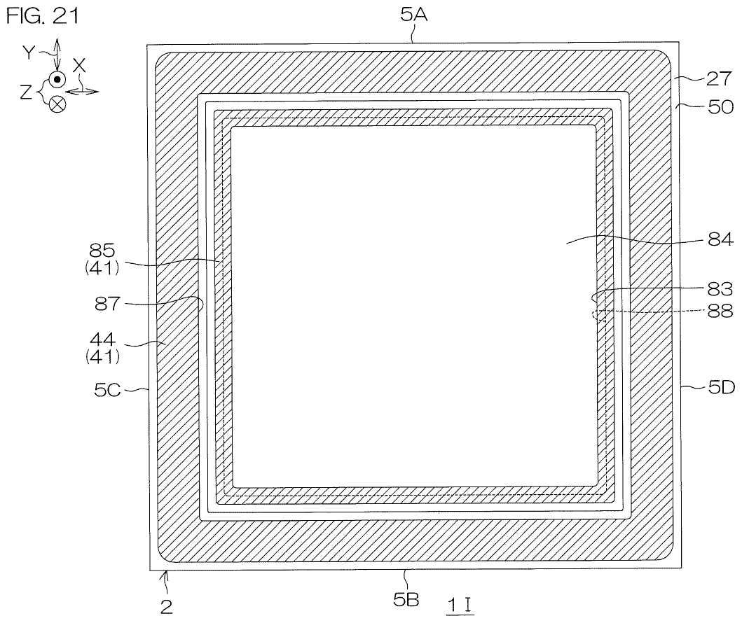

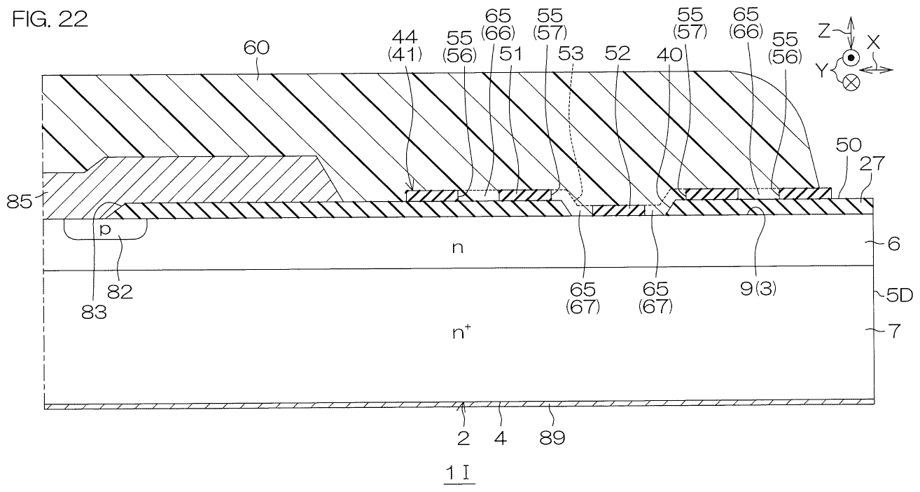

FIG. 18 is a plan view illustrating a semiconductor device 1I according to a ninth embodiment. FIG. 19 is a cross-sectional view taken along line XIX-XIX illustrated in FIG. 18. FIG. 20 is a plan view illustrating a layout example of a first polarity electrode 84. FIG. 21 is a plan view illustrating a layout example of the second inorganic film 41. FIG. 22 is an enlarged cross-sectional view illustrating the peripheral edge portion of the chip 2.

With reference to FIG. 18 to FIG. 22, the semiconductor device 1I includes the above-mentioned chip 2. The chip 2, in this embodiment, does not include the mesa portion 11 and includes the flat first main surface 3. That is, the semiconductor device 1I does not include the first to fourth connecting surfaces 10A to 10D, and includes the outer surface 9 located on the same plane as the active surface 8. The semiconductor device 1I includes an SBD (Schottky Barrier Diode) structure 80 as an example of a device structure formed in the active surface 8.

The semiconductor device 1I includes an n-type diode region 81 formed in the active surface 8. In this embodiment, the diode region 81 is formed by utilizing a part of the first semiconductor region 6.

The semiconductor device 1I includes a p-type guard region 82 on the first main surface 3 that defines the active surface 8 from the outer surface 9. The guard region 82 is formed in a surface layer portion of the first semiconductor region 6 at an interval inward from the peripheral edge of the first main surface 3, and defines the diode region 81 from the outer surface 9. In this embodiment, the guard region 82 is formed in a ring shape (quadrangular ring shape in this embodiment) surrounding the diode region 81 in a plan view. The guard region 82 has an inner edge portion on the diode region 81 side and an outer edge portion on the peripheral end side of the first main surface 3.

The semiconductor device 1I includes the above-mentioned first inorganic film 27 that selectively covers the first main surface 3. The first inorganic film 27 has an opening 83 that exposes the inner edge portions of the diode region 81 and the guard region 82 on the active surface 8 side. The first inorganic film 27 covers the outer surface 9 (peripheral edge portion of the first main surface 3). In this embodiment, the first inorganic film 27 is continuous with the first to fourth side surfaces 5A to 5D.

An outer wall of the first inorganic film 27 may include a ground surface having grinding marks. The outer wall of the first inorganic film 27 may form one ground surface together with the first to fourth side surfaces 5A to 5D. As a matter of course, the outer wall of the first inorganic film 27 may include a smooth surface without grinding marks. The outer wall of the first inorganic film 27 may be formed at an interval inward from the peripheral edge of the first main surface 3, and expose the first semiconductor region 6 from the outer surface 9.

The semiconductor device 1I includes the first polarity electrode 84 (main surface electrode) arranged on the first main surface 3. The first polarity electrode 84 is the “anode electrode” in this embodiment. The first polarity electrode 84 is arranged at an interval inward from the peripheral edge of the first main surface 3. In this embodiment, the first polarity electrode 84 is formed in a quadrangular shape along the peripheral edge of the first main surface 3 in a plan view. The first polarity electrode 84 enters into the opening 83 from above the first inorganic film 27, and is electrically connected to the first main surface 3 and the inner edge portion of the guard region 82.

The first polarity electrode 84 forms a Schottky junction with the diode region 81 (first semiconductor region 6). As a result, the SBD structure 80 is formed. The planar area of the first polarity electrode 84 is preferably 50% or more of the first main surface 3. It is particularly preferable that the planar area of the first polarity electrode 84 be 75% or more of the first main surface 3. The first polarity electrode 84 may have a thickness of 0.5 μm or more and 15 μm or less. The first polarity electrode 84 is preferably thicker than the first inorganic film 27.

The first polarity electrode 84 may have a laminated structure including a Ti—based metal film and an A1—based metal film. The Ti—based metal film may have a single-layer structure including a Ti film or a TiN film. The Ti—based metal film may have a laminated structure including a Ti film and a TiN film in any order. The A1 —based metal film is preferably thicker than the Ti-based metal film. The A1—based metal film may include at least one of a pure A1 film (A1 film having a purity of 99% or more), an AlCu alloy film, an AlSi alloy film, and an AlSiCu alloy film.

The semiconductor device 1I includes at least one (single or the plurality of) base through hole 40 described above formed in the portion of the first inorganic film 27 that covers the outer surface 9 (the peripheral edge portion of the first main surface 3). The single or the plurality of base through holes 40 are formed at intervals from the guard region 82 and the peripheral edge of the outer surface 9 in a plan view, and expose the outer surface 9.

In this embodiment, the base through hole 40 is formed at an interval from the peripheral edge of the first polarity electrode 84 and the peripheral edge of the first main surface 3 in a plan view. That is, the single or the plurality of base through holes 40 are formed around the first polarity electrode 84. The opening edge portion of the base through hole 40 is preferably formed in a curved shape. The layout of the single or the plurality of base through holes 40 is similar to that of the first embodiment, and therefore a description of the layout will be omitted.

The semiconductor device 1I includes the above-mentioned second inorganic film 41 that selectively covers the first inorganic film 27 and the first polarity electrode 84. In this embodiment, the second inorganic film 41 includes an electrode covering portion 85 and the outer covering portion 44. The electrode covering portion 85 covers only the first polarity electrode 84, and exposes the first inorganic film 27. The electrode covering portion 85 is arranged on the first polarity electrode 84 at an interval inward from the peripheral edge of the first polarity electrode 84, and exposes the peripheral edge portion of the first polarity electrode 84.

Specifically, the electrode covering portion 85 exposes the electrode side wall of the first polarity electrode 84. The electrode covering portion 85 is formed in a strip shape extending along the peripheral edge portion of the first polarity electrode 84 in a plan view, and defines a contact opening 86 that exposes the inner portion of the first polarity electrode 84. In this embodiment, the contact opening 86 is formed in a quadrangular shape in a plan view.

The outer covering portion 44 covers the first inorganic film 27 on the outer surface 9 (the peripheral edge portion of the first main surface 3). In this embodiment, the outer covering portion 44 covers the first inorganic film 27 at an interval from the peripheral edge of the first main surface 3 (first to fourth connecting surfaces 10A to 10D) and the peripheral edge of the first polarity electrode 84. That is, the outer covering portion 44 does not cover the metal (electrode).

The outer covering portion 44 defines an exposed portion 87 (removed portion) that exposes the peripheral edge portion (electrode side wall) of the first polarity electrode 84 in the region between the electrode covering portion 85 and the outer covering portion 44. The outer covering portion 44 is formed in a strip shape extending along the peripheral edge of the first main surface 3 in a plan view. In this embodiment, the outer covering portion 44 is formed in a ring shape (specifically, a quadrangular ring shape) surrounding the active surface 8 (specifically, the first polarity electrode 84) in a plan view. The outer covering portion 44 has an inner edge portion on the active surface 8 side and an outer edge portion on the peripheral edge side of the outer surface 9.

The inner edge portion of the outer covering portion 44 is located closer to the peripheral edge side of the first main surface 3 than the peripheral edge of the first polarity electrode 84, and exposes the first inorganic film 27 from between the inner edge portion of the outer covering portion 44 and the first polarity electrode 84. The outer edge portion of the outer covering portion 44 is formed at an interval inward from the peripheral edge of the first main surface 3, and defines the dicing street 50 between the outer edge portion of the outer covering portion 44 and the peripheral edge of the first main surface 3.

The outer covering portion 44 enters the base through hole 40 from above the first inorganic film 27 and is directly connected to the outer surface 9 (peripheral edge portion of the first main surface 3) within the base through hole 40. The outer covering portion 44 has a width greater than the width of the base through hole 40. The outer covering portion 44 enters the base through hole 40 from above the first inorganic film 27 via the inner wall portion of the base through hole 40 and is drawn out onto the first inorganic film 27 via the outer wall portion of the base through hole 40. As a result, the outer covering portion 44 covers both the inner wall portion and the outer wall portion of the base through hole 40.

In this embodiment, the outer covering portion 44 includes the first portion 51 and the second portion 52. The first portion 51 is a portion that covers the first inorganic film 27 outside the base through hole 40. The first portion 51 has a front surface located on the outer surface 9 side with respect to the active surface 8. The second portion 52 is a portion that covers the outer surface 9 inside the base through hole 40. The second portion 52 has a front surface located on the outer surface 9 side with respect to the front surface of the first portion 51. That is, the second portion 52 defines the recessed portion 53 (stepped portion) recessed toward the outer surface 9 between the second portion 52 and the first portion 51.

The semiconductor device 1I includes at least one (that is, the single or the plurality of) through hole 55 formed in the outer covering portion 44 (second inorganic film 41). In this embodiment, the single or the plurality of through holes 55 are formed at intervals from the peripheral edge of the first polarity electrode 84 and the peripheral edge of the first main surface 3 in a plan view. Besides, the layout of the single or the plurality of through holes 55 is similar to that of the first embodiment, and therefore a description of the layout will be omitted.

The semiconductor device 1I includes the aforementioned organic film 60 that covers the second inorganic film 41. The organic film 60 is embedded in the exposed portion 87 of the second inorganic film 41 and covers the electrode covering portion 85 and the outer covering portion 44 of the second inorganic film 41. The organic film 60 covers the peripheral edge portion (electrode sidewall) of the first polarity electrode 84 in the exposed portion 87.

The portion of the organic film 60 that covers the first polarity electrode 84 defines a pad opening 88 that exposes the inner portion of the first polarity electrode 84. In this embodiment, the pad opening 88 is formed in a quadrangular shape in a plan view, and communicates with the contact opening 86. The pad opening 88 may expose the inner edge portion of the electrode covering portion 85. As a matter of course, the organic film 60 may cover the entire area of the electrode covering portion 85.

The organic film 60 is embedded in all the through holes 55 (single or the plurality of through holes 55) on the outer surface 9 side (peripheral edge side of the first main surface 3) and covers the outer covering portion 44 of the second inorganic film 41. As a result, the organic film 60 has the single or the plurality of anchor portions 65 located in the single or the plurality of through holes 55. The single or the plurality of anchor portions 65 have a layout that matches the layout of the single or the plurality of through holes 55. The connection area of the organic film 60 to the second inorganic film 41 (outer covering portion 44) is increased by the anchor portion 65.

When the first-type through hole 56 exposing the first inorganic film 27 in a cross-sectional view is formed in the outer covering portion 44, the organic film 60 has a first-type anchor portion 66 that contacts the first inorganic film 27 and the outer covering portion 44 within the first-type through hole 56. When the second-type through hole 57 exposing the outer surface 9 (first main surface 3) in a cross-sectional view is formed in the outer covering portion 44, the organic film 60 has a second-type anchor portion 67 within the second-type through hole 57 that contacts the outer surface 9 (first main surface 3) and the outer covering portion 44.

When the second-type through hole 57 exposes the outer surface 9 (first main surface 3), the wall portion of the base through hole 40, and the first inorganic film 27, the second-type anchor portion 67 contacts the outer surface 9 (first main surface 3), the wall portion of the base through hole 40, the first inorganic film 27, and the outer covering portion 44 within the second-type through hole 57. When the second-type through hole 57 exposes the inner wall portion, the outer surface 9 (first main surface 3) and the outer wall portion of the base through hole 40, the second-type anchor portion 67 contacts the inner wall portion, the outer surface 9 (first main surface 3) and the outer wall portion of the base through hole 40. The second-type anchor portion 67 is connected to the outer surface 9 inside the base through hole 40 and simultaneously engages with the stepped portion between the outer surface 9 (first main surface 3) and the first inorganic film 27.

In this embodiment, the organic film 60 covers the first portion 51 and the second portion 52 of the outer covering portion 44, and also covers the recessed portion 53 defined by the first portion 51 and the second portion 52. That is, the organic film 60 enters the first-type through hole 56 from above the first portion 51 and covers the first inorganic film 27 inside the first-type through hole 56. The organic film 60 enters from above the first portion 51 into the recessed portion 53 and covers the second portion 52 within the recessed portion 53.

The organic film 60 enters into the base through hole 40 (second-type through hole 57) from above the second portion 52 within the recessed portion 53, and covers the outer surface 9 and the first inorganic film 27 within the base through hole 40 (second-type through hole 57). The connection area of the organic film 60 to the second inorganic film 41 (outer covering portion 44) is also increased by the recessed portion 53. In this embodiment, the connection area is increased by the step structure formed by the base through hole 40, the recessed portion 53, and the second-type through hole 57.

The outer edge portion of the organic film 60 is formed at an interval inward from the peripheral edge of the outer surface 9, and defines the dicing street 50 between the outer edge portion and the peripheral edge of the outer surface 9. In this embodiment, the outer edge portion of the organic film 60 exposes the outer edge portion of the second inorganic film 41. That is, the organic film 60 defines the dicing street 50 together with the second inorganic film 41. As a matter of course, the organic film 60 may cover the entire outer edge portion of the second inorganic film 41.

The semiconductor device 1I includes a second polarity electrode 89 (second main surface electrode) covering the second main surface 4. The second polarity electrode 89 is a “cathode electrode” in this embodiment. The second polarity electrode 89 is electrically connected to the second main surface 4. The second polarity electrode 89 forms an ohmic contact with the second semiconductor region 7 exposed from the second main surface 4. The second polarity electrode 89 may cover the entire second main surface 4 so as to be continuous with the peripheral edge of the chip 2 (first to fourth side surfaces 5A to 5D).

The second polarity electrode 89 may cover the second main surface 4 at an interval inward from the peripheral edge of the chip 2. The second polarity electrode 89 is configured so that a voltage of 500 V or more and 3000 V or less is applied between the second polarity electrode 89 and the first polarity electrode 84. That is, the chip 2 is formed so that a voltage of 500 V or more and 3000 V or less is applied between the first main surface 3 and the second main surface 4.

As described above, the semiconductor device 1I includes the chip 2, the second inorganic film 41 (inorganic film), the through hole 55, and the organic film 60. The chip 2 includes the first main surface 3. The second inorganic film 41 contains an insulator and covers the peripheral edge portion of the first main surface 3. The through hole 55 is formed in the second inorganic film 41. The organic film 60 is embedded in the through holes 55 and covers the second inorganic film 41.

According to this structure, an adhesion region having an unevenness due to the through holes 55 is formed between the second inorganic film 41 and the organic film 60. This can improve the connection strength of the organic film 60 to the second inorganic film 41. As a result, even if stress occurs in the second inorganic film 41 or the organic film 60, peeling of the organic film 60 from the second inorganic film 41 can be suppressed.

Also, the uneven adhesion region can extend the intrusion path of moisture (water). As a result, it is possible to suppress the intrusion of moisture starting from the region between the second inorganic film 41 and the organic film 60, and therefore it is possible to suppress deterioration (including corrosion) caused by moisture. Therefore, it is possible to provide the semiconductor device 1I with improved reliability.

From another perspective, the semiconductor device 1I includes the chip 2, the first inorganic film 27, the second inorganic film 41, at least one through hole 55, and the organic film 60. The chip 2 includes the first main surface 3. The first inorganic film 27 includes an insulator and covers the first main surface 3. The second inorganic film 41 includes an insulator and covers the first inorganic film 27. The through hole 55 is formed in the second inorganic film 41. The organic film 60 is embedded in the through holes 55 and covers the second inorganic film 41.

According to this structure, an adhesion region having an unevenness due to the through holes 55 is also formed between the second inorganic film 41 and the organic film 60. This can improve the connection strength of the organic film 60 to the second inorganic film 41. As a result, even if stress occurs in the second inorganic film 41 or the organic film 60, peeling of the organic film 60 from the second inorganic film 41 can be suppressed.

The uneven adhesion region also provides an extended intrusion path of moisture. As a result, it is possible to suppress the intrusion of moisture starting from the region between the second inorganic film 41 and the organic film 60, and therefore it is possible to suppress deterioration caused by moisture. Therefore, it is possible to provide the semiconductor device 1A with improved reliability. In this way, the semiconductor device 1I provides the same effects as the semiconductor device 1A according to the first embodiment.

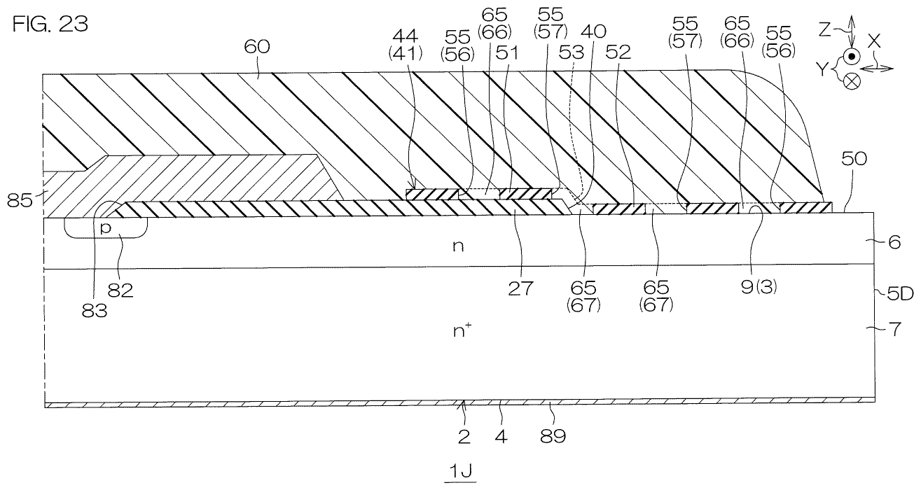

FIG. 23 corresponds to FIG. 22 and illustrates a semiconductor device 1J according to a tenth embodiment. With reference to FIG. 23, the semiconductor device 1J has a configuration obtained by modifying the semiconductor device 1I. Specifically, the semiconductor device 1J includes the base through hole 40 formed in the first inorganic film 27 so as to be continuous with the peripheral edge of the outer surface 9 (first to fourth side surfaces 5A to 5D).

As in the ninth embodiment, the base through holes 40 are formed closer to the peripheral edge side of the outer surface 9 than the guard region 82 (first polarity electrode 84). Each base through hole 40 is formed in a ring shape (specifically, a quadrangular ring shape) extending along the peripheral edge of the outer surface 9 (the first to fourth side surfaces 5A to 5D), and exposes the peripheral edge portion of the outer surface 9.

In this embodiment, the outer covering portion 44 of the second inorganic film 41 is drawn out from above the first inorganic film 27 into the base through hole 40 and covers the peripheral edge portion of the outer surface 9 within the base through hole 40. That is, the second inorganic film 41 includes the first portion 51 that covers the first inorganic film 27 and the second portion 52 that covers the outer surface 9, similar to the ninth embodiment. The outer covering portion 44 is formed within the base through hole 40 at an interval inward from the peripheral edge of the outer surface 9 (first to fourth side surfaces 5A to 5D), and defines the dicing street 50 that exposes the peripheral edge portion of the outer surface 9.

The single or the plurality of through holes 55 may be formed in either or both of the first portion 51 of the second inorganic film 41 and the second portion 52 of the second inorganic film 41. That is, the single or the plurality of through holes 55 may have either or both of a first-type through hole 56 and a second-type through hole 57 in a cross-sectional view.

As a matter of course, the single or the plurality of through holes 55 may be formed only in the first portion 51 and may not be formed in the second portion 52. Also, the single or the plurality of through holes 55 may be formed only in the second portion 52 and may not be formed in the first portion 51. The layout of the single or the plurality of through holes 55 is similar to that of the ninth embodiment (first embodiment), and therefore a description of the layout will be omitted.

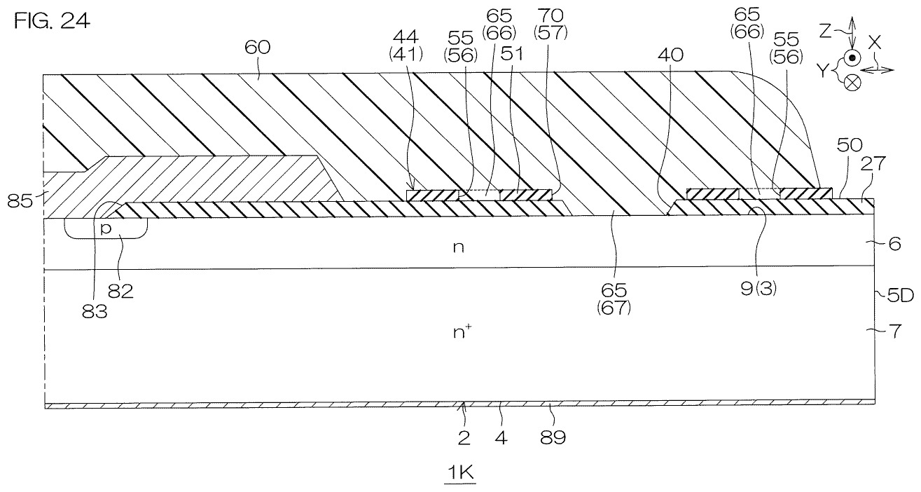

FIG. 24 corresponds to FIG. 22 and illustrates a semiconductor device 1K according to an eleventh embodiment. With reference to FIG. 24, the semiconductor device 1K has a configuration obtained by modifying the semiconductor device 1I. Specifically, the semiconductor device 1K includes an upper through hole 70 (second-type through hole 57) that exposes the entire area of the base through hole 40 of the first inorganic film 27 in a plan view and cross-sectional view.

The upper through hole 70 is formed by removing the second portion 52 of the outer covering portion 44 in the semiconductor device 1I. Therefore, the side covering portion includes only the first portion 51 that covers the first inorganic film 27, and does not include the second portion 52 that is located within the base through hole 40. The upper through hole 70 may be formed in a ring shape (specifically, a quadrangular ring shape) surrounding the active surface 8 in a plan view.

The semiconductor device 1K may include the single through hole 55 consisting of the upper through hole 70 (second-type through hole 57). As a matter of course, the semiconductor device 1K may include the single or the plurality of through holes 55 including the first-type through hole 56 in addition to the upper through hole 70 (the second-type through hole 57). In this case, the layout of the through holes 55 other than the upper through holes 70 is determined in an arbitrary manner. For example, at least one of the plurality of layouts (for example, a first to twentieth layout examples) of the through holes 55 described in the ninth embodiment (first embodiment) may be applied as the layout of the through holes 55 other than the upper through holes 70.

In this embodiment, the organic film 60 enters the first-type through hole 56 from above the second inorganic film 41 and contacts the first inorganic film 27 inside the first-type through hole 56. The organic film 60 enters from above the second inorganic film 41 into the upper through hole 70 (second-type through hole 57), and within the upper through hole 70, enters from above the first inorganic film 27 into the base through hole 40. The organic film 60 is in contact with the outer surface 9 and the first inorganic film 27 within the base through hole 40. The upper through hole 70 exposing the entire area of the base through hole 40 may be applied to the semiconductor device 1J according to the tenth embodiment.

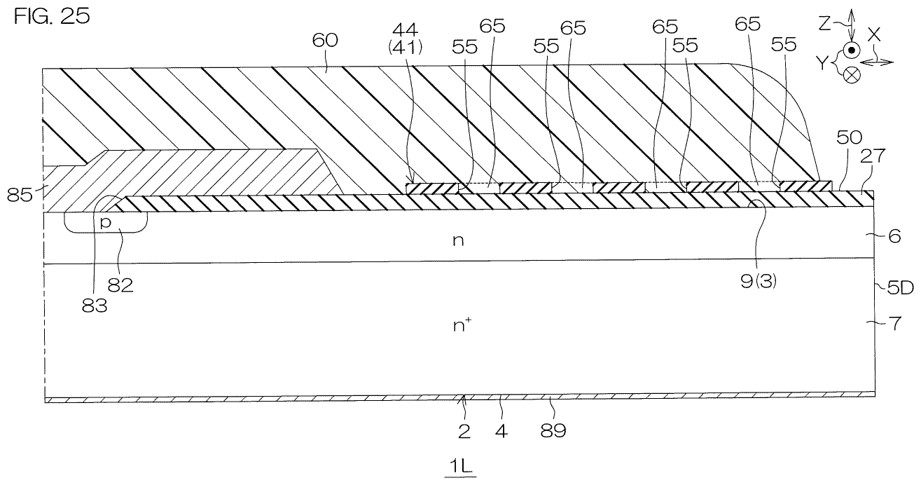

FIG. 25 corresponds to FIG. 22 and illustrates a semiconductor device 1L according to a twelfth embodiment. With reference to FIG. 25, the semiconductor device 1L has a configuration obtained by modifying the semiconductor device 1I. Specifically, the semiconductor device 1L does not include the base through hole 40 in the first inorganic film 27.

The single or the plurality of through holes 55 expose only the first inorganic film 27 and do not expose the outer surface 9. Also, the single or the plurality of through holes 55 only include the first-type through hole 56 that exposes the first inorganic film 27 in a cross-sectional view, and do not include the second-type through hole 57 that exposes the outer surface 9. The layout of the single or the plurality of through holes 55 is similar to that of the ninth embodiment (first embodiment), and therefore a description of the layout will be omitted.

The organic film 60 enters into the single or the plurality of through holes 55 (first-type through holes 56) from above the second inorganic film 41. In this embodiment, the organic film 60 is in contact only with the first inorganic film 27 and the second inorganic film 41 within the single or the plurality of through holes 55, and is not in contact with the outer surface 9.

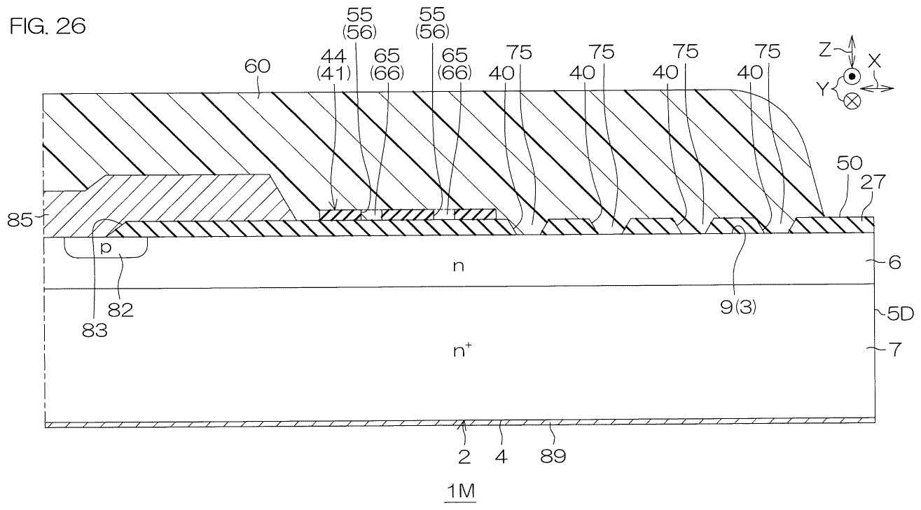

FIG. 26 corresponds to FIG. 22 and illustrates a semiconductor device 1M according to a thirteenth embodiment. With reference to FIG. 26, the semiconductor device 1M has a configuration obtained by modifying the semiconductor device 1I. The semiconductor device 1M includes the single or the plurality of base through holes 40, similar to the ninth embodiment (first embodiment). FIG. 26 illustrates, as an example, an example in which the plurality of base through holes 40 are formed.

In this embodiment, the outer covering portion 44 is formed at an interval from the base through hole 40 toward the active surface 8 so as to expose the base through hole 40. In this embodiment, the outer covering portion 44 is arranged in the region between the guard region 82 (specifically, the first polarity electrode 84) and the base through hole 40.

In this embodiment, the single or the plurality of through holes 55 expose only the first inorganic film 27 and do not expose the outer surface 9. Also, the single or the plurality of through holes 55 only include the first-type through hole 56 that exposes the first inorganic film 27 in a cross-sectional view, and do not include the second-type through hole 57 that exposes the outer surface 9. The layout of the single or the plurality of through holes 55 is similar to that of the ninth embodiment (first embodiment), and therefore a description of the layout will be omitted.

In this embodiment, the organic film 60 is embedded in all the base through holes 40 on the outer surface 9 side (peripheral edge side of the first main surface 3) and covers the first inorganic film 27. As a result, the organic film 60 includes the single or the plurality of base anchor portions 75 located in the single or the plurality of base through holes 40. The plurality of base anchor portions 75 have a layout that matches the layout of the single or the plurality of base through holes 40. The connection area of the organic film 60 to the first inorganic film 27 is increased by the base anchor portion 75.

Also, the organic film 60 is embedded in all the through holes 55 (single or the plurality of through holes 55) on the outer surface 9 side (peripheral edge side of the first main surface 3) and covers the second inorganic film 41. As a result, the organic film 60 has the single or the plurality of anchor portions 65 located in the single or the plurality of through holes 55. The single or the plurality of anchor portions 65 have a layout that matches the layout of the single or the plurality of through holes 55. The connection area of the organic film 60 to the second inorganic film 41 is increased by the anchor portions 65.

As described above, the semiconductor device 1M includes the chip 2, the first inorganic film 27 (inorganic film), the base through hole 40 (through hole 55), and the organic film 60. The chip 2 includes the first main surface 3. The first inorganic film 27 includes an insulator and covers the first main surface 3. The base through hole 40 is formed in the first inorganic film 27. The organic film 60 is embedded in the base through hole 40 and covers the first inorganic film 27.

This structure can improve the connection strength of the organic film 60 to the first inorganic film 27. This makes it possible to suppress peeling of the organic film 60 from the first inorganic film 27 when stress is generated in the first inorganic film 27 or the organic film 60. Therefore, since the intrusion of moisture starting from the peeled portion can be suppressed, deterioration caused by moisture can be suppressed. Therefore, it is possible to provide the semiconductor device 1M with improved reliability. In this way, the semiconductor device 1M has the same effects as those of the semiconductor device 1E according to the fifth embodiment.

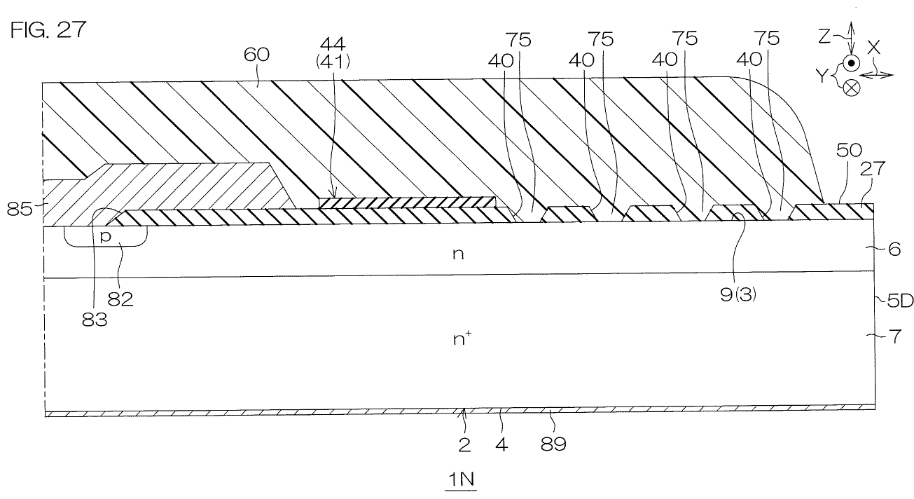

FIG. 27 corresponds to FIG. 22 and illustrates a semiconductor device 1N according to a fourteenth embodiment. With reference to FIG. 27, the semiconductor device 1N has a configuration obtained by modifying the semiconductor device 1M. Specifically, the semiconductor device 1N does not include the through hole 55 in the second inorganic film 41.

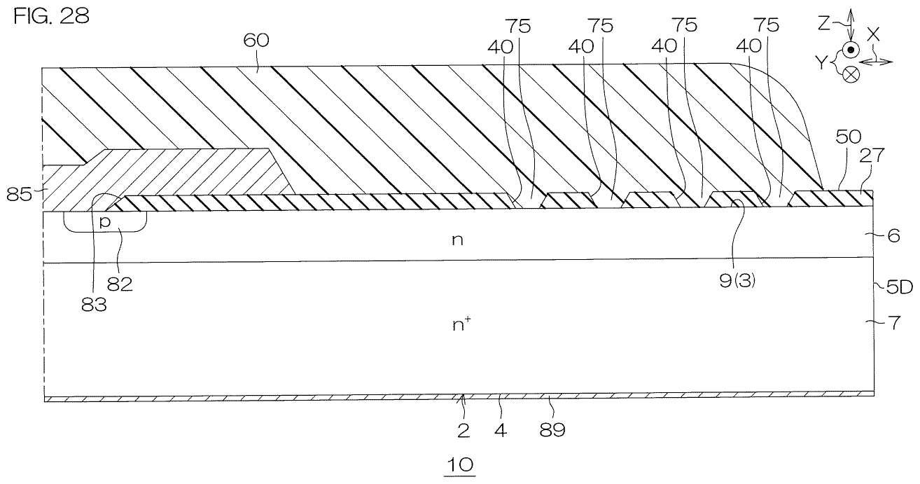

FIG. 28 corresponds to FIG. 22 and illustrates a semiconductor device 10 according to a fifteenth embodiment. With reference to FIG. 28, the semiconductor device 10 has a configuration obtained by modifying the semiconductor device 1M. Specifically, the semiconductor device 10 includes the second inorganic film 41 that has the gate covering portion 42 and the source covering portion 43, but does not include the outer covering portion 44. As a matter of course, the semiconductor device 10 may not necessarily include the second inorganic film 41.

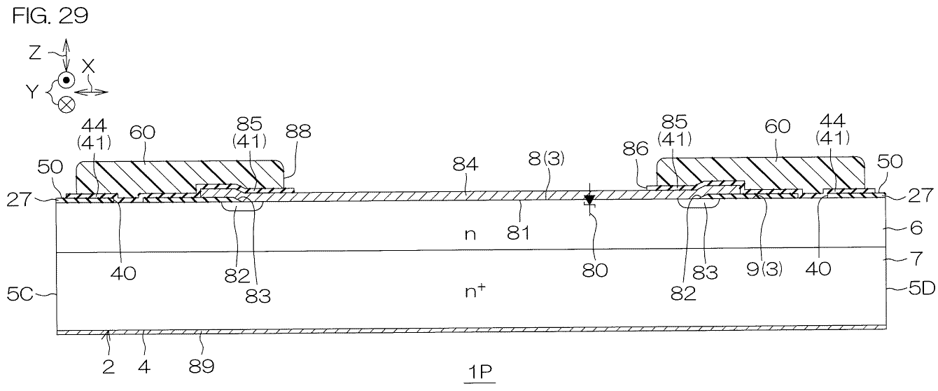

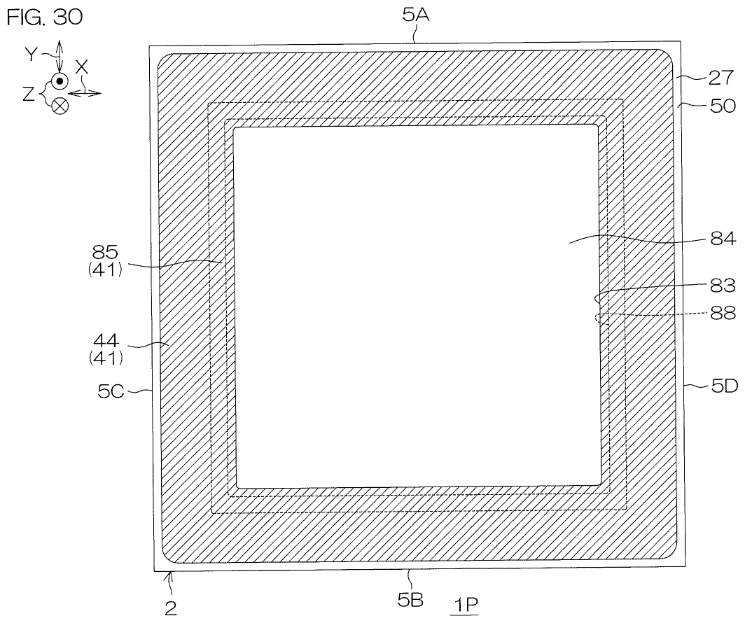

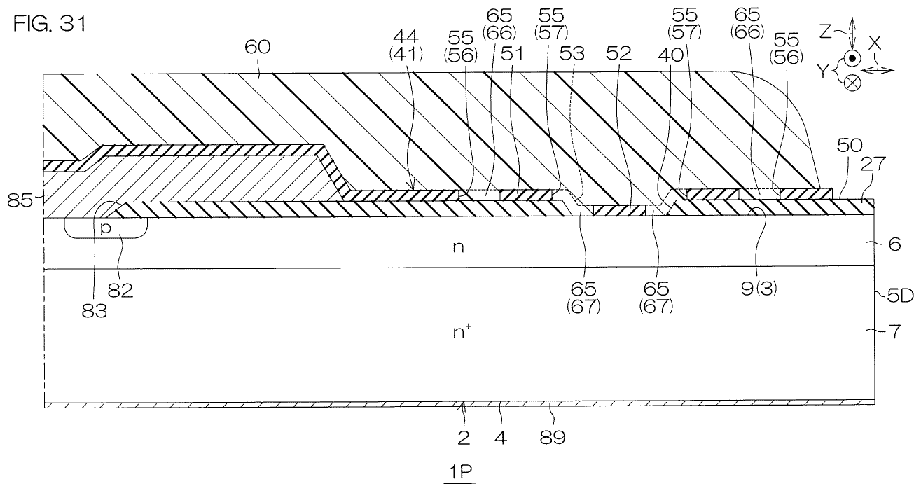

FIG. 29 corresponds to FIG. 19 and illustrates a semiconductor device 1P according to a sixteenth embodiment. FIG. 30 is a plan view illustrating a layout example of the second inorganic film 41 illustrated in FIG. 29. FIG. 31 is an enlarged cross-sectional view illustrating the peripheral edge portion of the chip 2 illustrated in FIG. 29. With reference to FIG. 29 to FIG. 31, the semiconductor device 1P has a configuration obtained by modifying semiconductor device 1I. Specifically, the semiconductor device 1P includes the second inorganic film 41 that integrally includes the electrode covering portion 85 and the outer covering portion 44.

That is, in this embodiment, the second inorganic film 41 covers the peripheral edge portion (electrode side wall) of the first polarity electrode 84. The second inorganic film 41 includes the contact opening 86 that exposes the inner portion of the first polarity electrode 84, as in the ninth embodiment. The outer covering portion 44 is a portion of the second inorganic film 41 that is located directly above the outer surface 9. More specifically, the outer covering portion 44 is a portion of the second inorganic film 41 that covers the peripheral edge of the outer surface 9 and the region between the first polarity electrodes 84.

The single or the plurality of through holes 55 are formed in the outer covering portion 44, similar to the ninth embodiment. That is, the single or the plurality of through holes 55 are formed only in the region on the outer surface 9 side, and are not formed in the region on the active surface 8 side. The layout of the single or the plurality of through holes 55 is similar to that of the ninth embodiment (first embodiment), and therefore a description of the layout will be omitted.

In this embodiment, the organic film 60 covers the peripheral edge portion (electrode sidewall) of the first polarity electrode 84 with the second inorganic film 41 sandwiched therebetween. The other structures of the organic film 60 are similar to those of the ninth embodiment, and therefore a description of the other structures of the organic film 60 will be omitted. The second inorganic film 41 integrally including the electrode covering portion 85 and the outer covering portion 44 may be applied to the semiconductor devices 1J to 1O according to the tenth to fifteenth embodiments.

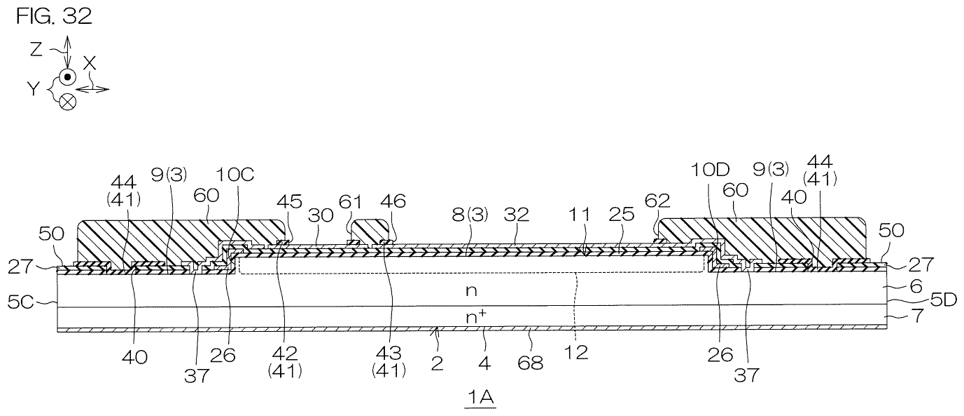

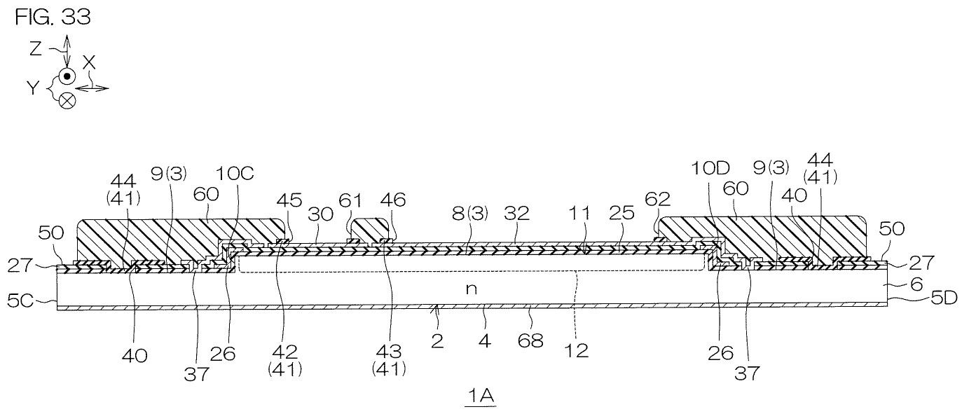

Hereinafter, with reference to FIG. 32 and FIG. 33, modified examples of the chip 2 applied to each embodiment will be illustrated. FIG. 32 and FIG. 33 show an embodiment in which the chip 2 according to the modified example is applied to the semiconductor device 1A. However, the chip 2 according to the modified example may be applied to the second to sixteenth embodiments.

With reference to FIG. 32, the semiconductor device 1A may include the second semiconductor region 7 thinner than the first semiconductor region 6 inside the chip 2. That is, the chip 2 may include an epitaxial layer that is thicker than the semiconductor substrate. The first semiconductor region 6 may have a thickness of 1 μm or more and 50 μm or less (preferably 5 μm or more and 25 μm or less). The second semiconductor region 7 may have a thickness of 0.1 μm or more and less than 50 μm. The second semiconductor region 7 may have a thickness of 5 μm or more (preferably 10 μm or more).

With reference to FIG. 33, the semiconductor device 1A may not include the second semiconductor region 7 inside the chip 2 and may include only the first semiconductor region 6. In this case, the first semiconductor region 6 is exposed from the first main surface 3, the second main surface 4, and the first to fourth side surfaces 5A to 5D of the chip 2. That is, in this embodiment, the chip 2 does not include the semiconductor substrate, but has a single-layer structure including an epitaxial layer. The first semiconductor region 6 may have a thickness of 1 μm or more and 50 μm or less (preferably 5 μm or more and 25 μm or less).

The above-described embodiments can be further implemented in another embodiment. For example, the features disclosed in each of the above-described embodiments can be combined as appropriate. In other words, an embodiment may be adopted that simultaneously includes at least two of the features disclosed in the first to sixteenth embodiments described above.

In the above-described first to eighth embodiments, the chip 2 including the mesa portion 11 is illustrated. However, the chip 2 including the first main surface 3 extending flatly without the mesa portion 11 may be used. In this case, the sidewall structure 26 is eliminated.

In the above-described first to eighth embodiments, the embodiment having the source wiring 37 has been illustrated. However, an embodiment not including the source wiring 37 may be adopted. In the above-described first to eighth embodiments, the trench gate type gate structure 15 that controls the channel inside the chip 2 has been illustrated. However, the planar gate type gate structure 15 that controls the channel from above the first main surface 3 may be employed.

In the above-described ninth to sixteenth embodiments, the chip 2 does not include the mesa portion 11. However, the chip 2 including the mesa portion 11 may be employed. In the above-described ninth to sixteenth embodiments, an example in which one guard region 82 is formed in the surface layer portion of the first main surface 3 has been illustrated. However, the plurality of guard regions 82 may be formed at intervals on the surface layer portion of the first main surface 3. In this case, the outer covering portion 44 may face one or more guard regions 82 with the first inorganic film 27 interposed therebetween.

In each of the above-described embodiments, the MISFET structure 12 and the SBD structure 80 are formed in different chips 2. However, the MISFET structure 12 and the SBD structure 80 may be formed in different regions of the first main surface 3 of the same chip 2. In this case, the SBD structure 80 may be formed as a freewheeling diode for the MISFET structure 12. In this case, the source electrode 32 may also serve as the first polarity electrode 84, and the drain electrode 68 may also serve as the second polarity electrode 89.

In each of the above-described embodiments, the “first conductivity type” is the “n-type” and the “second conductivity type” is the “p-type.” However, in each of the above-described embodiments, a configuration may be adopted in which the “first conductivity type” is the “p-type” and the “second conductivity type” is the “n-type.” A specific configuration in this case can be obtained by replacing “n-type” with “p-type” and by replacing “p-type” with “n-type” in the above description and accompanying drawings.

In the above-described first to eighth embodiments, the n-type second semiconductor region 7 is illustrated. However, the p-type second semiconductor region 7 may also be employed. In this case, an IGBT (Insulated Gate Bipolar Transistor) structure is formed in place of the MISFET structure 12. In this case, in the above description, the “source” of the MISFET structure 12 is replaced with the “emitter” of the IGBT structure, and the “drain” of the MISFET structure 12 is replaced with the “collector” of the IGBT structure. The p-type second semiconductor region 7 may be an impurity region containing p-type impurities introduced into the surface layer portion of the second main surface 4 of the chip 2 by ion implantation.

Hereinafter, examples of features extracted from this specification and the drawings are presented. Hereinafter, alphanumeric characters in parentheses represent corresponding components in the above-mentioned embodiments, but are not intended to limit the scope of each clause to the embodiments. The “semiconductor device” in the following items may be replaced with a “wide bandgap semiconductor device,” an “SiC semiconductor device,” a “semiconductor switching device,” a “semiconductor rectifier device,” and the like, as necessary.

[A1] A semiconductor device (1A to 1P) comprising: a chip (2) having a main surface (3); a first inorganic film (27) including an insulator and covering the main surface (3); a second inorganic film (41) including an insulator and covering the first inorganic film (27); at least one through hole (55) formed in the second inorganic film (41); and an organic film (60) embedded in the through hole (55) and covering the second inorganic film (41).

[A2] The semiconductor device (1A to 1P) according to A1, wherein the at least one through hole (55) includes a film-side through hole (56) that exposes the first inorganic film (27) in a cross-sectional view, and the organic film (60) includes a portion (66) in contact with the first inorganic film (27) within the film-side through hole (56).

[A3] The semiconductor device (1A to 1P) according to A1 or A2, wherein the at least one through hole (55) includes a surface-side through hole (57) that exposes the main surface (3) in a cross-sectional view, and the organic film (60) includes a portion (67) in contact with the main surface (3) within the surface-side through hole (57).

[A4] The semiconductor device (1A to 1P) according to A3, wherein the surface-side through hole (57) exposes the main surface (3) and the first inorganic film (27) in a cross-sectional view, and the organic film (60) is in contact with both the main surface (3) and the first inorganic film (27) within the surface-side through hole (57).

[A5] The semiconductor device (1A to 1P) according to any one of A1 to A4, wherein the first inorganic film (27) includes a base through hole (40) that exposes the main surface (3), the second inorganic film (41) includes a first portion (51) covering the first inorganic film (27) outside the base through hole (40) and a second portion (52) covering the main surface (3) inside the base through hole (40), and the organic film (60) includes a portion covering the first portion (51) and a portion covering the second portion (52).

[A6] The semiconductor device (1A to 1P) according to A5, wherein the second portion (52) includes a front surface located on the main surface (3) side with respect to a height position of the front surface of the first portion (51), and forms a stepped portion (53) between the second portion (52) and the first portion (51).

[A7] The semiconductor device (1A to 1P) according to A5 or A6, wherein the second inorganic film (41) has a thickness less than ½ the width of the base through hole (40).

[A8] The semiconductor device (1A to 1P) according to any one of A5 to A7, wherein the at least one through hole (55) includes a wall-side through hole (57) that exposes a wall portion of the base through hole (40) in a cross-sectional view, and the organic film (60) includes a portion (67) within the wall-side through hole (57) that contacts the wall portion of the base through hole (40).

[A9] The semiconductor device (1A to 1P) according to any one of A1 to A8, further comprising: an electrode (30, 32, 84) arranged in an inner portion of the main surface (3); wherein the at least one through hole (55) is formed around the electrode (30, 32, 84).

[A10] The semiconductor device (1A to 1P) according to A9, wherein the electrodes (30, 32, 84) are arranged at intervals in the inner portion of the main surface (3), and the at least one through hole (55) is formed around the electrodes (30, 32, 84).

[A11] The semiconductor device (1A to 1P) according to any one of A1 to A10, further comprising: a mesa portion (11) defined in the main surface (3) by a first surface portion (8) formed in the inner portion of the main surface (3), a second surface portion (9) formed in a peripheral edge portion of the main surface (3) so as to be recessed from the first surface portion (8) in a thickness direction of the chip (2), and a connecting surface portion (10A to 10D) connecting the first surface portion (8) and the second surface portion (9); wherein the first inorganic film (27) covers the second surface portion (9), the second inorganic film (41) covers the first inorganic film (27) on the second surface portion (9) side, the through hole (55) is formed in the second inorganic film (41) on the second surface portion (9) side, and the inorganic film (60) is embedded in the through hole (55) and covers the second inorganic film (41) on the second surface portion (9) side.

[A12] The semiconductor device (1A to 1P) according to A11, wherein the second inorganic film (41) is formed at an interval from the first surface portion (8) on the second surface portion (9) side.

[A13] The semiconductor device (1A to 1P) according to A11 or A12, wherein the second inorganic film (41) does not cover a metal on the second surface portion (9) side.

[A14] The semiconductor device (1A to 1P) according to any one of A1 to A13, wherein the second inorganic film (41) includes an insulator different from the first inorganic film (27).

[A15] The semiconductor device (1A to 1P) according to any one of A1 to A14, wherein the first inorganic film (27) includes an oxide film.

[A16] The semiconductor device (1A to 1P) according to any one of A1 to A15, wherein the second inorganic film (41) includes a nitride film.

[A17] The semiconductor device (1A to 1P) according to any one of A1 to A16, wherein the organic film (60) includes a photosensitive resin film.

[A18] The semiconductor device (1A to 1P) according to any one of A1 to A17, wherein the chip (2) includes a single crystal of a wide bandgap semiconductor.

[A19] The semiconductor device (1A to 1P) according to any one of A1 to A18, wherein the chip (2) includes an SiC single crystal.

[A20] The semiconductor device (1A to 1P) according to any one of A1 to A19, wherein the chip (2) has a thickness of 200 μm or less.

[A21] The semiconductor device (1A to 1P) according to any one of A1 to A20, wherein the chip (2) has a thickness of 100 μm or less.

[A22] The semiconductor device (1A to 1P) according to any one of A1 to A21, wherein the chip (2) has a thickness of 80 μm or less.

[A23] The semiconductor device (1A to 1P) according to any one of A1 to A22, wherein the chip (2) has a thickness of 50 μm or less.

[A24] The semiconductor device (1A to 1P) according to any one of A1 to A23, wherein the chip (2) includes a layered structure including a substrate (7) and an epitaxial layer (6), and includes the main surface (3) formed by the epitaxial layer (6).

[A25] The semiconductor device (1A to 1P) according to A24, wherein the epitaxial layer (6) is thinner than the substrate (7).

[A26] The semiconductor device (1A to 1P) according to A24, wherein the epitaxial layer (6) is thicker than the substrate (7).

[A27] The semiconductor device (1A to 1P) according to any one of A1 to A23, wherein the chip (2) includes a single-layer structure consisting of the epitaxial layer (6).

[A28] The semiconductor device (1A to 1P) according to any one of A1 to A27, further comprising: a device structure (12, 80) formed in an inner portion of the main surface (3); wherein the at least one through hole (55) is formed around the device structure (12, 80).

[A29] The semiconductor device (1A to 1P) according to A28, wherein the device structure (12, 80) includes at least one of a MISFET (Metal Insulator Semiconductor Field Effect Transistor) structure (12) and an SBD (Schottky Barrier Diode) structure (80).

[B1] A semiconductor device (1A to 1P), comprising: a chip (2) having a main surface (3); an inorganic film (27/41) including an insulator and covering the main surface (3); at least one through hole (40/55) formed in the inorganic film (27/41); and an organic film (60) embedded in the through hole (40/55) and covering the inorganic film (27/41).

[B2] The semiconductor device (1A to 1P) according to B1, wherein the through hole (40/55) exposes the main surface (3), and the organic film (60) contacts the main surface (3) within the through hole (40/55).

[B3] The semiconductor device according to B1 or B2, wherein the inorganic film (27/41) covers a peripheral edge portion of the main surface, the through hole (40/55) exposes the peripheral edge portion of the main surface (3), and the organic film (60) is embedded in the through hole (40/55) and covers the inorganic film (27/41) on a peripheral edge portion side of the main surface (3).

[B4] The semiconductor device (1A to 1P) according to any one of B1 to B3, wherein the inorganic film (27/41) is formed of an oxide film.

[B5] The semiconductor device (1A to 1P) according to any one of B1 to B3, wherein the inorganic film (27/41) is formed of a nitride film.

[B6] The semiconductor device (1A to 1P) according to any one of B1 to B5, wherein the organic film (60) is formed of a photosensitive resin film.

[B7] The semiconductor device (1A to 1P) according to any one of B1 to B6, wherein the organic film (60) is thicker than the inorganic film (27/41).

[B8] The semiconductor device (1A to 1P) according to any one of B1 to B7, further comprising: an electrode (30/32/84) arranged in an inner portion of the main surface (3); wherein the through hole (40/55) is formed in a region between a peripheral edge of the main surface (3) and a peripheral edge of the electrode (30/32/84).

[B9] The semiconductor device (1A to 1P) according to B8, wherein the organic film (60) includes a portion covering the peripheral edge portion of the electrode (30/32/84) and has an opening (61/62/88) exposing the inner portion of the electrode (30/32/84).

[B10] The semiconductor device (1A to 1P) according to B8 or B9, wherein a single through hole or a plurality of through holes (40/55) is/are formed around the electrode (30/32/84) so as to encircle the electrode (30/32/84) in a plan view.

[B11] The semiconductor device (1A to 1P) according to any one of B8 to B10, wherein the organic film (60) is thicker than the electrode (30/32/84).

[B12] The semiconductor device (1A to 1P) according to any one of B1 to B11, wherein the through holes (40/55) are formed at intervals in the inorganic film (27/41), and the organic film (60) is embedded in the through holes (40/55).

[B13] The semiconductor device (1A to 1P) according to any one of B1 to B12, further comprising: a first conductive type semiconductor region (6) formed in a surface layer portion of the main surface (3); and a second conductive type impurity region (21/82) formed in a surface layer portion of the semiconductor region (6) in a peripheral edge portion of the main surface (3), wherein the through hole (40/55) is formed at an interval from the impurity region (21/82) to a peripheral side of the main surface (3) in a planar direction of the main surface (3).

[B14] The semiconductor device (1A to 1P) according to B13, wherein the through hole (40/55) exposes the semiconductor region (6).

[B15] The semiconductor device (1A to 1P) according to any one of B1 to B14, further comprising: a mesa portion (11) defined in the main surface (3) by a first surface portion (8) formed in the inner portion of the main surface (3), a second surface portion (9) formed in a peripheral edge portion of the main surface (3) so as to be recessed from the first surface portion (8) in a thickness direction of the chip (2), and a connecting surface portion (10A to 10D) connecting the first surface portion (8) and the second surface portion (9); wherein the inorganic film (27/41) covers the second surface portion (9), the through hole (40/55) is formed in the inorganic film (27/41) on the second surface portion (9) side, and the inorganic film (60) is embedded in the through hole (40/55) and covers the inorganic film (27/41) on the second surface portion (9) side.

[B16] The semiconductor device (1A to 1P) according to B15, wherein the organic film (60) includes a portion located directly above the first surface portion (8).

[B17] The semiconductor device (1A to 1P) according to any one of B1 to B16, wherein the chip (2) has a thickness of 200 μm or less.

[B18] The semiconductor device (1A to 1P) according to any one of B1 to B17, wherein the chip (2) includes a single crystal of a wide bandgap semiconductor.

[B19] The semiconductor device (1A to 1P) according to any one of B1 to B18, wherein the chip (2) includes an SiC single crystal.

[B20] The semiconductor device (1A to 1P) according to any one of B1 to B19, further comprising: a device structure (12, 80) formed in an inner portion of the main surface (3); wherein the at least one through hole (55) is formed in a peripheral edge portion of the main surface (3).

[C1] A semiconductor device (1A to 1P) comprising: a chip (2) having a main surface (3); a first inorganic film (27) covering the main surface (3); a first-side through hole (40) formed in the first inorganic film (27) so as to expose the main surface (3); a second inorganic film (41) covering the first inorganic film (27); a second-side through hole (55) formed in the second inorganic film (41) so as to expose the first inorganic film (27); and an organic film (60) covering the first inorganic film (27) and the second inorganic film (41), and including a portion in contact with the main surface (3) within the first-side through hole (40) and a portion in contact with the first inorganic film (27) within the second-side through hole (55).

[C2] The semiconductor device (1A to 1P) according to C1, wherein the second inorganic film (41) includes a first portion (51) covering the first inorganic film (27) outside the first-side through hole (40) and a second portion (52) covering the main surface (3) within the first-side through hole (40), and the organic film (60) covers the first portion (51) and the second portion (52) of the second inorganic film (41).

[C3] The semiconductor device (1A to 1P) according to C2, wherein the second portion (52) includes a front surface located on the main surface (3) side with respect to a height position of the front surface of the first portion (51), and forms a step between the second portion (52) and the first portion (51).

[C4] The semiconductor device (1A to 1P) according to any one of C1 to C3, wherein the at least one second-side through hole is formed at a position overlapping with the first-side through hole.

[C5] The semiconductor device (1A to 1P) according to any one of C1 to C4, wherein the at least one second-side through hole is formed at a position that does not overlap with the first-side through hole.

Although the embodiments have been described in detail as above, these are merely concrete examples that specify technical contents. Various technical ideas extracted from this description can be appropriately combined together without being limited to the sequential descriptive order in this description, the sequential order of the embodiments, or the like.

What is claimed is:

1. A semiconductor device, comprising:
a chip having a main surface;
a first inorganic film including an insulator and covering the main surface;
a second inorganic film including an insulator and covering the first inorganic film;
at least one through hole formed in the second inorganic film; and
an organic film embedded in the through hole and covering the second inorganic film.

2. The semiconductor device according to claim 1,
wherein the at least one through hole includes a film-side through hole that exposes the first inorganic film in a cross-sectional view, and
the organic film includes a portion in contact with the first inorganic film within the film-side through hole.

3. The semiconductor device according to claim 1,
wherein the at least one through hole includes a surface-side through hole that exposes the main surface in a cross-sectional view, and
the organic film includes a portion in contact with the main surface within the surface-side through hole.

4. The semiconductor device according to claim 3,
wherein the surface-side through hole exposes the main surface and the first inorganic film in a cross-sectional view, and
the organic film is in contact with both the main surface and the first inorganic film within the surface-side through hole.

5. The semiconductor device according to claim 1,
wherein the first inorganic film includes a base through hole exposing the main surface,
the second inorganic film includes a first portion covering the first inorganic film outside the base through hole and a second portion covering the main surface within the base through hole, and
the organic film includes a portion covering the first portion and a portion covering the second portion.

6. The semiconductor device according to claim 5,
wherein the second portion includes a front surface located on the main surface side with respect to a height position of a front surface of the first portion, and forms a stepped portion between the second portion and the first portion.

7. The semiconductor device according to claim 5,
wherein the second inorganic film has a thickness less than half the width of the base through hole.

8. The semiconductor device according to claim 5,
wherein the at least one through hole includes a wall-side through hole that exposes a wall portion of the base through hole in a cross-sectional view, and
the organic film includes a portion within the wall-side through hole that contacts the wall portion of the base through hole.

9. The semiconductor device according to claim 1, further comprising:
an electrode arranged on an inner portion of the main surface;
wherein the at least one through hole is formed around the electrode.

10. The semiconductor device according to claim 1, further comprising:
a mesa portion defined in the main surface by a first surface portion formed in the inner portion of the main surface, a second surface portion formed in a peripheral edge portion of the main surface so as to be recessed from the first surface portion in a thickness direction of the chip, and a connecting surface portion connecting the first surface portion and the second surface portion;
wherein the first inorganic film covers the second surface portion,
the second inorganic film covers the first inorganic film on the second surface portion side,
the through hole is formed in the second inorganic film on the second surface portion side, and
the inorganic film is embedded in the through hole and covers the second inorganic film on the second surface portion side.

11. The semiconductor device according to claim 10,
wherein the second inorganic film is formed at an interval from the first surface portion on the second surface side.

12. The semiconductor device according to claim 10,
wherein the second inorganic film does not cover a metal on the second surface side.

13. The semiconductor device according to claim 1,
wherein the second inorganic film includes an insulator different from that of the first inorganic film.

14. The semiconductor device according to claim 1,
wherein the first inorganic film includes an oxide film.

15. The semiconductor device according to claim 1,
wherein the second inorganic film includes a nitride film.

16. The semiconductor device according to claim 1,
wherein the organic film includes a photosensitive resin film.

17. The semiconductor device according to claim 1,
wherein the chip includes a single crystal of a wide bandgap semiconductor.

18. A semiconductor device comprising:
a chip having a main surface;
an inorganic film including an insulator and covering the main surface;
at least one through hole formed in the inorganic film; and
an organic film embedded in the through hole and covering the inorganic film.

19. The semiconductor device according to claim 18,
wherein the through hole exposes the main surface, and
the organic film contacts the main surface within the through hole.

20. The semiconductor device according to claim 18,
wherein the inorganic film is formed of an oxide film or a nitride film.
